(19) United States
(12) Patent Application Publication
(10) Pub. No.: US 2026/0304767 A1
(43) Pub. Date: Oct. 1, 2026

(54) THREE-DIMENSIONAL MEMORY DEVICE WITH INTEGRATED WORD LINE AND CONTACT VIA STRUCTURES AND METHOD OF MAKING THEREOF

(71) Applicant: Sandisk Technologies, Inc., Milpitas, CA (US)

(72) Inventors: Atsushi SHIMIZU, Yokkaichi (JP); Yukihiro SAKOTSUBO, Yokkaichi (JP); Shinsuke YADA, Yokkaichi (JP); Koichi MATSUNO, Fremont, CA (US)

(21) Appl. No.: 19/233,908

(22) Filed: Jun. 10, 2025

Related U.S. Application Data
(63) Continuation-in-part of application No. 19/091,391, filed on Mar. 26, 2025.

(51) Int. Cl. H10B 43/27; H10B 43/10; H10B 43/35

(52) U.S. Cl. CPC H10B 43/27; H10B 43/10; H10B 43/35

(57) ABSTRACT

A memory device includes a vertically alternating sequence of insulating layers and electrically conductive layers; memory opening fill structures vertically extending through the vertically alternating sequence; and integrated plate-and-via structures including a respective electrically conductive plate and a respective vertically-extending portion extending upward from the respective electrically conductive plate. Each of the electrically conductive plates is in contact with a respective one of the electrically conductive layers.

Each of the electrically conductive layers includes an electrically conductive strip that contacts a respective electrically conductive plate.

### FIELD

This application is a continuation-in-part application of U.S. patent application Ser. No. 19/091,391 filed on Mar. 26, 2025, the entire contents of which are incorporated herein by reference.

### FIELD

The present disclosure relates generally to the field of semiconductor devices, and particularly to a three-dimensional memory device including lateral word line-via contact structures and methods for forming the same.

### BACKGROUND

A three-dimensional memory device including a three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device is provided, which comprises: a vertically alternating sequence of insulating layers and electrically conductive layers; memory openings vertically extending through the vertically alternating sequence; memory opening fill structures located in the memory openings, wherein each of the memory opening fill structures comprises a respective vertical stack of memory elements located at levels of the electrically conductive layers and a vertical semiconductor channel; and an integrated plate-and-via structure comprising an electrically conductive plate and a vertically-extending portion extending upward from the electrically conductive plate, wherein the electrically conductive plate is in contact with a sidewall of a first electrically conductive layer of the electrically conductive layers at an interface, and a first lateral distance between a bottom periphery of an outer sidewall of the vertically-extending portion and the interface is less than a second lateral distance between the bottom periphery and each electrically conductive layer that overlies the first electrically conductive layer.

According to another aspect of the present disclosure, a method of forming a memory device is provided, which comprises: forming an alternating stack of insulating layers and sacrificial material layers over a substrate; forming memory openings through the alternating stack; forming memory opening fill structures in the memory openings, wherein each of the memory opening fill structures comprises a respective vertical stack of memory elements and a vertical semiconductor channel; forming a sacrificial integrated plate-and-via structure through an upper portion of the alternating stack, wherein the sacrificial integrated plate-and-via structure comprises a sacrificial material plate and a sacrificial vertically-extending portion that vertically extends upward from the sacrificial material plate; forming at least one lateral isolation trench through the alternating stack; forming laterally-extending cavities by removing portions of the sacrificial material layers that are proximal to the at least one lateral isolation trench; locally expanding one of the laterally-extending cavities by laterally recessing the sacrificial material plate selectively to the sacrificial material layers and the insulating layers; forming electrically conductive layers in the laterally-extending cavities to form a vertically alternating sequence of the insulating layers and the electrically conductive layers; and replacing the sacrificial integrated plate-and-via structure with an integrated plate-and-via structure comprising at least one electrically conductive material.

According to yet another aspect of the present disclosure, a memory device is provided, which comprises: a vertically alternating sequence of insulating layers and electrically conductive layers; first memory openings located in a first memory array region and vertically extending through the vertically alternating sequence; first memory opening fill structures located in the first memory openings, wherein each of the first memory opening fill structures comprises a respective vertical stack of memory elements located at levels of the electrically conductive layers; and integrated plate-and-via structures located in a contact region and comprising a respective electrically conductive plate and a respective vertically-extending portion extending upward from the respective electrically conductive plate, wherein each of the electrically conductive plates is in contact with a respective one of the electrically conductive layers, and each of the electrically conductive layers comprises first electrically conductive strips that laterally extend along a first horizontal direction, second electrically conductive strips that laterally extend along a second horizontal direction and adjoined to a respective pair of first electrically conductive strips of the first electrically conductive strips, and at least one connection strip each laterally extending along the first horizontal direction and connecting a respective pair of second electrically conductive strips of the second electrically conductive strips.

According to still another aspect of the present disclosure, a method of forming a memory device is provided, which comprises: forming an alternating stack of insulating layers and sacrificial material layers over a substrate; forming memory openings through the alternating stack in a memory array region; forming memory opening fill structures in the memory openings, wherein each of the memory opening fill structures comprises a respective vertical stack of memory elements and a vertical semiconductor channel; forming lateral isolation trenches through the alternating stack, wherein each of the lateral isolation trenches comprises a respective longitudinal lateral isolation trench segment that laterally extends along a first horizontal direction and at least one transverse lateral isolation trench segment that laterally extends along a second horizontal direction different from the first horizontal direction and is formed in a contact region; forming strip-shaped cavities by laterally recessing the sacrificial material layers around the lateral isolation trenches in the contact region; forming laterally-extending cavities by laterally recessing the sacrificial material layers around the lateral isolation trenches in the memory array region; and forming electrically conductive layers in the laterally-extending cavities and the strip-shaped cavities.

According to another aspect of the present disclosure, a memory device is provided, which comprises: a vertically alternating sequence of insulating layers and electrically conductive layers, wherein each of the electrically conductive layers extends in a first horizontal direction in a first memory array region, and comprises first electrically conductive strips laterally extending along a first horizontal direction in a contact region, and second electrically conductive strips laterally extending along a second horizontal direction different from the first horizontal direction in the contact region; first memory openings located in the first memory array region and vertically extending through the vertically alternating sequence; first memory opening fill structures located in the first memory openings, wherein each of the first memory opening fill structures comprises a respective vertical stack of memory elements located at levels of the electrically conductive layers and a vertical semiconductor channel; and integrated plate-and-via structures located in the contact region and comprising a respective electrically conductive plate and a respective vertically-extending portion extending upward from the respective electrically conductive plate, wherein at least a portion of the electrically conductive plates is in contact with a respective one of the second electrically conductive strips.

According to another aspect of the present disclosure, a method of forming a memory device is provided, which comprises: forming an alternating stack of insulating layers and sacrificial material layers over a substrate; forming memory openings through the alternating stack in a memory array region; forming memory opening fill structures in the memory openings, wherein each of the memory opening fill structures comprises a respective vertical stack of memory elements and a vertical semiconductor channel; forming longitudinal lateral isolation trench segments and transverse lateral isolation trench segments through the alternating stack, wherein the longitudinal lateral isolation trench segments laterally extend along a first horizontal direction and the transverse lateral isolation trench segments laterally extend along a second horizontal direction different from the first horizontal direction; forming strip-shaped cavities by laterally recessing the sacrificial material layers around the lateral isolation trenches in the contact region, wherein neighboring pairs of a respective longitudinal lateral isolation trench segment and a respective transverse lateral isolation trench segment are interconnected by a respective subset of the strip-shaped cavities; forming laterally-extending cavities by laterally recessing the sacrificial material layers around the longitudinal lateral isolation trench segments in the memory array region; and forming electrically conductive layers in the laterally-extending cavities and the strip-shaped cavities.

### BRIEF DESCRIPTION OF THE DRAWINGS

FIG. 1 is a schematic vertical cross-sectional view of a first exemplary structure after formation of an alternating stack of insulating layers and sacrificial material layers over a substrate according to a first embodiment of the present disclosure.

FIG. 2A-2C are various views of the first exemplary structure after formation of memory openings according to the first embodiment of the present disclosure. FIG. 2C is a top-down view. FIG. 2A is a first vertical cross-sectional view along the vertical plane A-A′ in FIG. 2C. FIG. 2B is a second vertical cross-sectional view along the vertical plane B-B′ in FIG. 2C.

FIG. 3A-3F are sequential schematic vertical cross-sectional views of a memory opening within the first exemplary structure during formation of a memory opening fill structure therein according to the first embodiment of the present disclosure.

FIG. 4A-4C are various views of the first exemplary structure after formation of memory opening fill structures according to the first embodiment of the present disclosure. FIG. 4C is a top-down view. FIG. 4A is a first vertical cross-sectional view along the vertical plane A-A′ in FIG. 4C. FIG. 4B is a second vertical cross-sectional view along the vertical plane B-B′ in FIG. 4C.

FIG. 5A-5C are various views of the first exemplary structure after formation of dual-width lateral isolation trenches and access lateral isolation trenches according to the first embodiment of the present disclosure. FIG. 5C is a top-down view. FIG. 5A is a first vertical cross-sectional view along the vertical plane A-A′ in FIG. 5C. FIG. 5B is a second vertical cross-sectional view along the vertical plane B-B′ in FIG. 5C.

FIGS. 6A and 6B are vertical cross-sectional views of the first exemplary structure after formation of a sacrificial barrier liner and a sacrificial fill material layer according to the first embodiment of the present disclosure. FIG. 6A is a first vertical cross-sectional view along the vertical plane A-A′ in FIG. 5C. FIG. 6B is a second vertical cross-sectional view along the vertical plane B-B′ in FIG. 5C.

FIGS. 7A and 7B are vertical cross-sectional views of the first exemplary structure after isotropically recessing the sacrificial fill material layer and the sacrificial barrier liner according to the first embodiment of the present disclosure.

FIGS. 8A and 8B are vertical cross-sectional views of the first exemplary structure after formation of wide lateral isolation trench fill structures according to the first embodiment of the present disclosure.

FIG. 9A-9C are various views of the first exemplary structure after formation of contact via openings according to the first embodiment of the present disclosure. FIG. 9C is a top-down view. FIG. 9A is a first vertical cross-sectional view along the vertical plane A-A′ in FIG. 9C. FIG. 9B is a second vertical cross-sectional view along the vertical plane B-B′ in FIG. 9C.

FIGS. 10A and 10B are vertical cross-sectional views of the first exemplary structure after formation of tubular insulating spacers and vertical extension of contact via cavities according to the first embodiment of the present disclosure.

FIGS. 11A and 11B are vertical cross-sectional views of the first exemplary structure after removal of sacrificial isolation trench fill structures according to the first embodiment of the present disclosure.

FIGS. 12A and 12B are vertical cross-sectional views of the first exemplary structure after formation of a sacrificial barrier liner according to the first embodiment of the present disclosure.

FIGS. 13A and 13B are vertical cross-sectional views of the first exemplary structure after formation of a sacrificial dielectric liner according to the first embodiment of the present disclosure.

FIGS. 14A and 14B are vertical cross-sectional views of the first exemplary structure after patterning the sacrificial dielectric liner according to the first embodiment of the present disclosure.

FIGS. 15A and 15B are vertical cross-sectional views of the first exemplary structure after removal of a patterned photoresist layer according to the first embodiment of the present disclosure.

FIGS. 16A and 16B are vertical cross-sectional views of the first exemplary structure after removal of the sacrificial dielectric liner according to the first embodiment of the present disclosure.

FIG. 17A-17D are various views of the first exemplary structure after a first selective isotropic etch process that laterally recesses physically exposed portions of the sacrificial material layers by a first etch distance according to the first embodiment of the present disclosure. FIG. 17C is a top-down view. FIG. 17A is a first vertical cross-sectional view along the vertical plane A-A′ in FIG. 17C. FIG. 17B is a second vertical cross-sectional view along the vertical plane B-B′ in FIG. 17C. FIG. 17D is a horizontal cross-sectional view along the horizontal plane D-D′ of FIGS. 17A and 17B.

FIGS. 18A and 18B are vertical cross-sectional views of the first exemplary structure after removal of the sacrificial barrier liner according to the first embodiment of the present disclosure.

FIG. 19A-19E are various views of the first exemplary structure after a second selective isotropic etch process that laterally recesses physically exposed portions of the sacrificial material layers by a second etch distance according to the first embodiment of the present disclosure. FIG. 19C is a top-down view. FIG. 19A is a first vertical cross-sectional view along the vertical plane A-A′ in FIG. 19C. FIG. 19B is a second vertical cross-sectional view along the vertical plane B-B′ in FIG. 19C. FIG. 19D is a horizontal cross-sectional view along the horizontal plane D-D′ of FIGS. 19A and 19B. FIG. 19E is a horizontal cross-sectional view along the horizontal plane E-E′ of FIGS. 19A and 19B.

FIG. 20A-20E are various views of the first exemplary structure after formation of a continuous electrically conductive layer according to the first embodiment of the present disclosure. FIG. 20C is a top-down view. FIG. 20A is a first vertical cross-sectional view along the vertical plane A-A′ in FIG. 20C. FIG. 20B is a second vertical cross-sectional view along the vertical plane B-B′ in FIG. 20C. FIG. 20D is a horizontal cross-sectional view along the horizontal plane D-D′ of FIGS. 20A and 20B. FIG. 20E is a horizontal cross-sectional view along the horizontal plane E-E′ of FIGS. 20A and 20B.

FIG. 21A-21E are various views of the first exemplary structure after removing unmasked portions of the continuous electrically conductive layer according to the first embodiment of the present disclosure. FIG. 21C is a top-down view. FIG. 21A is a first vertical cross-sectional view along the vertical plane A-A′ in FIG. 21C. FIG. 21B is a second vertical cross-sectional view along the vertical plane B-B′ in FIG. 21C. FIG. 21D is a horizontal cross-sectional view along the horizontal plane D-D′ of FIGS. 21A and 21B. FIG. 21E is a horizontal cross-sectional view along the horizontal plane E-E′ of FIGS. 21A and 21B.

FIGS. 22A and 22B are vertical cross-sectional views of the first exemplary structure after formation of a continuous dielectric material portion including a contact-level dielectric layer and lateral isolation trench fill structures according to the first embodiment of the present disclosure.

FIG. 23A-23C are various views of the first exemplary structure after formation of drain contact via structures and connection via structures according to the first embodiment of the present disclosure. FIG. 23C is a top-down view. FIG. 23A is a first vertical cross-sectional view along the vertical plane A-A′ in FIG. 23C. FIG. 23B is a second vertical cross-sectional view along the vertical plane B-B′ in FIG. 23C.

FIG. 24A is a top-down view of an alternative configuration of the first exemplary structure according to the first embodiment of the present disclosure. FIG. 24B is a horizontal cross-sectional view of the alternative configuration of the first exemplary structure according to the first embodiment of the present disclosure.

FIG. 25A-25C are vertical cross-sectional views of a second exemplary structure after isotropically recessing the sacrificial fill material layer and the sacrificial barrier liner according to a second embodiment of the present disclosure. FIG. 25C is a top-down view. FIG. 25A is a first vertical cross-sectional view along the vertical plane A-A′ in FIG. 25C. FIG. 25B is a second vertical cross-sectional view along the vertical plane B-B′ in FIG. 25C.

FIG. 26 is a horizontal cross-sectional view of the second exemplary structure after conversion of surface portions of sacrificial narrow lateral isolation trench fill structures into dielectric liners according to the second embodiment of the present disclosure.

FIG. 27A-27C are vertical cross-sectional views of the second exemplary structure after formation of a first sacrificial trench liner, a second sacrificial trench liner, and wide sacrificial trench fill structures according to the second embodiment of the present disclosure. FIG. 27C is a top-down view. FIG. 27A is a first vertical cross-sectional view along the vertical plane A-A′ in FIG. 27C. FIG. 27B is a second vertical cross-sectional view along the vertical plane B-B′ in FIG. 27C.

FIG. 28A-28C are various views of the second exemplary structure after formation of contact via openings according to the second embodiment of the present disclosure. FIG. 28C is a top-down view. FIG. 28A is a first vertical cross-sectional view along the vertical plane A-A′ in FIG. 28C. FIG. 28B is a second vertical cross-sectional view along the vertical plane B-B′ in FIG. 28C.

FIGS. 29A and 29B are vertical cross-sectional views of the second exemplary structure after formation of tubular insulating spacers and vertical extension of contact via cavities according to the second embodiment of the present disclosure.

FIGS. 30A and 30B are vertical cross-sectional views of the second exemplary structure after formation of a sacrificial barrier liner and a sacrificial dielectric liner according to the second embodiment of the present disclosure.

FIGS. 31A and 31B are vertical cross-sectional views of the second exemplary structure after patterning the sacrificial dielectric liner according to the second embodiment of the present disclosure.

FIGS. 32A and 32B are vertical cross-sectional views of the second exemplary structure after removal of unmasked portions of the sacrificial barrier liner, narrow sacrificial lateral isolation trench fill structures, and wide sacrificial lateral isolation trench fill structures according to the second embodiment of the present disclosure.

FIGS. 33A and 33B are vertical cross-sectional views of the second exemplary structure after removal of a patterned photoresist layer, the sacrificial dielectric liner, and the second sacrificial trench liner according to the second embodiment of the present disclosure.

FIG. 34A-34D are various views of the second exemplary structure after a first selective isotropic etch process that laterally recesses physically exposed portions of the sacrificial material layers by a second etch distance according to the second embodiment of the present disclosure. FIG. 34C is a top-down view. FIG. 34A is a first vertical cross-sectional view along the vertical plane A-A′ in FIG. 34C. FIG. 34B is a second vertical cross-sectional view along the vertical plane B-B′ in FIG. 34C. FIG. 34D is a horizontal cross-sectional view along the horizontal plane D-D′ of FIGS. 34A and 34B.

FIGS. 35A and 35B are vertical cross-sectional views of the second exemplary structure after removal of the first sacrificial trench liner according to the second embodiment of the present disclosure.

FIG. 36A-36E are various views of the second exemplary structure after a second selective isotropic etch process that laterally recesses physically exposed portions of the sacrificial material layers by a second etch distance according to the second embodiment of the present disclosure. FIG. 36C is a top-down view. FIG. 36A is a first vertical cross-sectional view along the vertical plane A-A′ in FIG. 36C. FIG. 36B is a second vertical cross-sectional view along the vertical plane B-B′ in FIG. 36C. FIG. 36D is a horizontal cross-sectional view along the horizontal plane D-D′ of FIGS. 36A and 36B. FIG. 36E is a horizontal cross-sectional view along the horizontal plane E-E′ of FIGS. 36A and 36B.

FIG. 37A-37E are various views of the second exemplary structure after formation of integrated word line and contact via structures, a continuous dielectric material portion including a contact-level dielectric layer and lateral isolation trench fill structures, and drain contact via structures and connection via structures according to the second embodiment of the present disclosure. FIG. 37C is a top-down view. FIG. 37A is a first vertical cross-sectional view along the vertical plane A-A′ in FIG. 37C. FIG. 37B is a second vertical cross-sectional view along the vertical plane B-B′ in FIG. 37C. FIG. 37D is a horizontal cross-sectional view along the horizontal plane D-D′ of FIGS. 37A and 37B. FIG. 37E is a horizontal cross-sectional view along the horizontal plane E-E′ of FIGS. 37A and 37B.

FIG. 38A-38E are various views of a first alternative configuration of the second exemplary structure after formation of integrated word line and contact via structures, a continuous dielectric material portion including a contact-level dielectric layer and lateral isolation trench fill structures, and drain contact via structures and connection via structures according to the second embodiment of the present disclosure. FIG. 38C is a top-down view. FIG. 38A is a first vertical cross-sectional view along the vertical plane A-A′ in FIG. 38C. FIG. 38B is a second vertical cross-sectional view along the vertical plane B-B′ in FIG. 38C. FIG. 38D is a horizontal cross-sectional view along the horizontal plane D-D′ of FIGS. 38A and 38B. FIG. 38E is a horizontal cross-sectional view along the horizontal plane E-E′ of FIGS. 38A and 38B.

FIG. 39A-39E are various views of a second alternative configuration of the second exemplary structure after formation of integrated word line and contact via structures, a continuous dielectric material portion including a contact-level dielectric layer and lateral isolation trench fill structures, and drain contact via structures and connection via structures according to the second embodiment of the present disclosure. FIG. 39C is a top-down view. FIG. 39A is a first vertical cross-sectional view along the vertical plane A-A′ in FIG. 39C. FIG. 39B is a second vertical cross-sectional view along the vertical plane B-B′ in FIG. 39C. FIG. 39D is a horizontal cross-sectional view along the horizontal plane D-D′ of FIGS. 39A and 39B. FIG. 39E is a horizontal cross-sectional view along the horizontal plane E-E′ of FIGS. 39A and 39B.

FIGS. 40, 41, 42 and 43 are horizontal cross-sectional views of third, fourth, fifth and sixth alternative configurations of the second exemplary structure according to the second embodiment of the present disclosure.

FIGS. 44A and 44B are various views of a third exemplary structure after formation of lateral isolation trenches according to a third embodiment of the present disclosure. FIG. 44A is a horizontal cross-sectional view along the horizontal plane A-A′ shown in FIG. 44B. FIG. 44B is a vertical cross-sectional view along the vertical plane B-B′ shown in FIG. 44A.

FIGS. 45A and 45B are various views of the third exemplary structure after formation of a sacrificial barrier liner and a sacrificial fill material layer according to the third embodiment of the present disclosure. FIG. 45A is a horizontal cross-sectional view along the horizontal plane A-A′ shown in FIG. 45B. FIG. 45B is a vertical cross-sectional view along the vertical plane B-B′ shown in FIG. 45A.

FIGS. 46A and 46B are various views of the third exemplary structure after removal of portions of the sacrificial barrier liner and the sacrificial fill material layer from wide lateral isolation trench segments according to the third embodiment of the present disclosure. FIG. 46A is a horizontal cross-sectional view along the horizontal plane A-A′ shown in FIG. 46B. FIG. 46B is a vertical cross-sectional view along the vertical plane B-B′ shown in FIG. 46A.

FIGS. 47A and 47B are various views of the third exemplary structure after formation of wide lateral isolation trench fill structures according to the third embodiment of the present disclosure. FIG. 47A is a horizontal cross-sectional view along the horizontal plane A-A′ shown in FIG. 47B. FIG. 47B is a vertical cross-sectional view along the vertical plane B-B′ shown in FIG. 47A.

FIGS. 48A and 48B are various views of the third exemplary structure after formation of contact via openings according to the third embodiment of the present disclosure. FIG. 48A is a horizontal cross-sectional view along the horizontal plane A-A′ shown in FIG. 48B. FIG. 48B is a vertical cross-sectional view along the vertical plane B-B′ shown in FIG. 48A.

FIGS. 49A and 49B are various views of the third exemplary structure after formation of tubular insulating spacers according to the third embodiment of the present disclosure. FIG. 49A is a horizontal cross-sectional view along the horizontal plane A-A′ shown in FIG. 49B. FIG. 49B is a vertical cross-sectional view along the vertical plane B-B′ shown in FIG. 49A.

FIGS. 50A and 50B are various views of the third exemplary structure after formation of plate-shaped cavities according to the third embodiment of the present disclosure. FIG. 50A is a horizontal cross-sectional view along the horizontal plane A-A′ shown in FIG. 50B. FIG. 50B is a vertical cross-sectional view along the vertical plane B-B′ shown in FIG. 50A.

FIGS. 51A and 51B are various views of the third exemplary structure after formation of a sacrificial fill material layer according to the third embodiment of the present disclosure. FIG. 51A is a horizontal cross-sectional view along the horizontal plane A-A′ shown in FIG. 51B. FIG. 51B is a vertical cross-sectional view along the vertical plane B-B′ shown in FIG. 51A.

FIGS. 52A and 52B are various views of the third exemplary structure after formation of sacrificial plate-and-via structures according to the third embodiment of the present disclosure. FIG. 52A is a horizontal cross-sectional view along the horizontal plane A-A′ shown in FIG. 52B. FIG. 52B is a vertical cross-sectional view along the vertical plane B-B′ shown in FIG. 52A.

FIGS. 53A and 53B are various views of the third exemplary structure after formation of an insulating cover layer according to the third embodiment of the present disclosure. FIG. 53A is a horizontal cross-sectional view along the horizontal plane A-A′ shown in FIG. 53B. FIG. 53B is a vertical cross-sectional view along the vertical plane B-B′ shown in FIG. 53A.

FIGS. 54A and 54B are various views of the third exemplary structure after patterning the insulating cover layer according to the third embodiment of the present disclosure. FIG. 54A is a horizontal cross-sectional view along the horizontal plane A-A′ shown in FIG. 54B. FIG. 54B is a vertical cross-sectional view along the vertical plane B-B′ shown in FIG. 54A.

FIGS. 55A and 55B are various views of the third exemplary structure after removal of sacrificial lateral isolation trench fill structures according to the third embodiment of the present disclosure. FIG. 55A is a horizontal cross-sectional view along the horizontal plane A-A′ shown in FIG. 55B. FIG. 55B is a vertical cross-sectional view along the vertical plane B-B′ shown in FIG. 55A.

FIGS. 56A and 56B are various views of the third exemplary structure after formation of a sacrificial etch barrier layer according to the third embodiment of the present disclosure. FIG. 56A is a horizontal cross-sectional view along the horizontal plane A-A′ shown in FIG. 56B. FIG. 56B is a vertical cross-sectional view along the vertical plane B-B′ shown in FIG. 56A.

FIGS. 57A and 57B are various views of the third exemplary structure after removal of portions of the sacrificial etch barrier layer from outside areas of the contact-region lateral isolation trench segments according to the third embodiment of the present disclosure. FIG. 57A is a horizontal cross-sectional view along the horizontal plane A-A′ shown in FIG. 57B. FIG. 57B is a vertical cross-sectional view along the vertical plane B-B′ shown in FIG. 57A.

FIGS. 58A and 58B are various views of the third exemplary structure after formation of laterally-extending cavities according to the third embodiment of the present disclosure. FIG. 58A is a horizontal cross-sectional view along the horizontal plane A-A′ shown in FIG. 58B. FIG. 58B is a vertical cross-sectional view along the vertical plane B-B′ shown in FIG. 58A.

FIGS. 59A and 59B are various views of the third exemplary structure after formation of strip-shaped cavities according to the third embodiment of the present disclosure. FIG. 59A is a horizontal cross-sectional view along the horizontal plane A-A′ shown in FIG. 59B. FIG. 59B is a vertical cross-sectional view along the vertical plane B-B′ shown in FIG. 59A.

FIGS. 60A and 60B are various views of the third exemplary structure after laterally recessing physically exposed portions of the sacrificial plate-and-via structures according to the third embodiment of the present disclosure. FIG. 60A is a horizontal cross-sectional view along the horizontal plane A-A′ shown in FIG. 60B. FIG. 60B is a vertical cross-sectional view along the vertical plane B-B′ shown in FIG. 60A.

FIGS. 61A and 61B are various views of the third exemplary structure after formation of backside blocking dielectrics and electrically conductive layers according to the third embodiment of the present disclosure. FIG. 61A is a horizontal cross-sectional view along the horizontal plane A-A′ shown in FIG. 61B. FIG. 61B is a vertical cross-sectional view along the vertical plane B-B′ shown in FIG. 61A.

FIGS. 62A and 62B are various views of the third exemplary structure after formation of an insulating liner according to the third embodiment of the present disclosure. FIG. 62A is a horizontal cross-sectional view along the horizontal plane A-A′ shown in FIG. 62B. FIG. 62B is a vertical cross-sectional view along the vertical plane B-B′ shown in FIG. 62A.

FIGS. 63A and 63B are various views of the third exemplary structure after removal of the sacrificial plate-and-via structures according to the third embodiment of the present disclosure. FIG. 63A is a horizontal cross-sectional view along the horizontal plane A-A′ shown in FIG. 63B. FIG. 63B is a vertical cross-sectional view along the vertical plane B-B′ shown in FIG. 63A.

FIGS. 64A and 64B are various views of the third exemplary structure after formation of a conformal electrically conductive material layer according to the third embodiment of the present disclosure. FIG. 64A is a horizontal cross-sectional view along the horizontal plane A-A′ shown in FIG. 64B. FIG. 64B is a vertical cross-sectional view along the vertical plane B B′ shown in FIG. 64A.

FIGS. 65A and 65B are various views of the third exemplary structure after patterning the conformal electrically conductive material layer into integrated plate-and-via structures according to the third embodiment of the present disclosure. FIG. 65A is a horizontal cross-sectional view along the horizontal plane A-A′ shown in FIG. 65B. FIG. 65B is a vertical cross-sectional view along the vertical plane B-B′ shown in FIG. 65A.

FIGS. 66A and 66B are various views of the third exemplary structure after formation of a continuous dielectric material portion according to the third embodiment of the present disclosure. FIG. 66A is a horizontal cross-sectional view along the horizontal plane A-A′ shown in FIG. 66B. FIG. 66B is a vertical cross-sectional view along the vertical plane B-B′ shown in FIG. 66A.

FIGS. 67A, 67B, and 67C are various views of a fourth exemplary structure after formation of lateral isolation trenches according to a fourth embodiment of the present disclosure. FIG. 67A is a horizontal cross-sectional view along the horizontal plane A-A′ shown in FIGS. 67B and 67C. FIG. 67B is a vertical cross-sectional view along the vertical plane B-B′ shown in FIG. 67A. FIG. 67C is a vertical cross-sectional view along the vertical plane C-C′ shown in FIG. 67A.

FIGS. 68A, 68B, and 68C are various views of the fourth exemplary structure after formation of a sacrificial barrier liner and a sacrificial fill material layer according to the fourth embodiment of the present disclosure. FIG. 68A is a horizontal cross-sectional view along the horizontal plane A-A′ shown in FIGS. 68B and 68C. FIG. 68B is a vertical cross-sectional view along the vertical plane B-B′ shown in FIG. 68A. FIG. 68C is a vertical cross-sectional view along the vertical plane C-C′ shown in FIG. 68A.

FIGS. 69A, 69B, and 69C are various views of the fourth exemplary structure after formation of a sacrificial barrier liner and a sacrificial fill material layer according to the fourth embodiment of the present disclosure. FIG. 69A is a horizontal cross-sectional view along the horizontal plane A-A′ shown in FIGS. 69B and 69C. FIG. 69B is a vertical cross-sectional view along the vertical plane B-B′ shown in FIG. 69A. FIG. 69C is a vertical cross-sectional view along the vertical plane C-C′ shown in FIG. 69A.

FIGS. 70A, 70B, and 70C are various views of the fourth exemplary structure after formation of wide lateral isolation trench fill structures according to the fourth embodiment of the present disclosure. FIG. 70A is a horizontal cross-sectional view along the horizontal plane A-A′ shown in FIGS. 70B and 70C. FIG. 70B is a vertical cross-sectional view along the vertical plane B-B′ shown in FIG. 70A. FIG. 70C is a vertical cross-sectional view along the vertical plane C-C′ shown in FIG. 70A.

FIGS. 71A, 71B, and 71C are various views of the fourth exemplary structure after removal of sacrificial lateral isolation trench fill structures according to the fourth embodiment of the present disclosure. FIG. 71A is a horizontal cross-sectional view along the horizontal plane A-A′ shown in FIGS. 71B and 71C. FIG. 71B is a vertical cross-sectional view along the vertical plane B-B′ shown in FIG. 71A. FIG. 71C is a vertical cross-sectional view along the vertical plane C-C′ shown in FIG. 71A.

FIGS. 72A, 72B, and 72C are various views of the fourth exemplary structure after formation of a sacrificial etch barrier layer according to the fourth embodiment of the present disclosure. FIG. 72A is a horizontal cross-sectional view along the horizontal plane A-A′ shown in FIGS. 72B and 72C. FIG. 72B is a vertical cross-sectional view along the vertical plane B-B′ shown in FIG. 72A. FIG. 72C is a vertical cross-sectional view along the vertical plane C-C′ shown in FIG. 72A.

FIGS. 73A, 73B, and 73C are various views of the fourth exemplary structure after removal of portions of the sacrificial etch barrier layer from a memory array region according to the fourth embodiment of the present disclosure. FIG. 73A is a horizontal cross-sectional view along the horizontal plane A-A′ shown in FIGS. 73B and 73C. FIG. 73B is a vertical cross-sectional view along the vertical plane B-B′ shown in FIG. 73A. FIG. 73C is a vertical cross-sectional view along the vertical plane C-C′ shown in FIG. 73A.

FIGS. 74A, 74B, and 74C are various views of the fourth exemplary structure after formation of laterally-extending cavities according to the fourth embodiment of the present disclosure. FIG. 74A is a horizontal cross-sectional view along the horizontal plane A-A′ shown in FIGS. 74B and 74C. FIG. 74B is a vertical cross-sectional view along the vertical plane B-B′ shown in FIG. 74A. FIG. 74C is a vertical cross-sectional view along the vertical plane C-C′ shown in FIG. 74A.

FIGS. 75A, 75B, and 75C are various views of the fourth exemplary structure after complete removal of the sacrificial etch barrier layer and formation of strip-shaped cavities according to the fourth embodiment of the present disclosure. FIG. 75A is a horizontal cross-sectional view along the horizontal plane A-A′ shown in FIGS. 75B and 75C. FIG. 75B is a vertical cross-sectional view along the vertical plane B-B′ shown in FIG. 75A. FIG. 75C is a vertical cross-sectional view along the vertical plane C-C′ shown in FIG. 75A.

FIGS. 76A, 76B, and 76C are various views of the fourth exemplary structure after formation of electrically conductive layers according to the fourth embodiment of the present disclosure. FIG. 76A is a horizontal cross-sectional view along the horizontal plane A-A′ shown in FIGS. 76B and 76C. FIG. 76B is a vertical cross-sectional view along the vertical plane B-B′ shown in FIG. 76A. FIG. 76C is a vertical cross-sectional view along the vertical plane C-C′ shown in FIG. 76A.

FIGS. 77A, 77B, and 77C are various views of the fourth exemplary structure after formation of a continuous dielectric material portion according to the fourth embodiment of the present disclosure. FIG. 77A is a horizontal cross-sectional view along the horizontal plane A-A′ shown in FIGS. 77B and 77C. FIG. 77B is a vertical cross-sectional view along the vertical plane B-B′ shown in FIG. 77A. FIG. 77C is a vertical cross-sectional view along the vertical plane C-C′ shown in FIG. 77A.

FIGS. 78A, 78B, and 78C are various views of the fourth exemplary structure after formation of contact via openings and tubular insulating spacers according to the fourth embodiment of the present disclosure. FIG. 78A is a horizontal cross-sectional view along the horizontal plane A-A′ shown in FIGS. 78B and 78C. FIG. 78B is a vertical cross-sectional view along the vertical plane B-B′ shown in FIG. 78A. FIG. 78C is a vertical cross-sectional view along the vertical plane C-C′ shown in FIG. 78A.

FIGS. 79A, 79B, and 79C are various views of the fourth exemplary structure after formation of plate-shaped cavities according to the fourth embodiment of the present disclosure. FIG. 79A is a horizontal cross-sectional view along the horizontal plane A-A′ shown in FIGS. 79B and 79C. FIG. 79B is a vertical cross-sectional view along the vertical plane B-B′ shown in FIG. 79A. FIG. 79C is a vertical cross-sectional view along the vertical plane C-C′ shown in FIG. 79A.

FIGS. 80A, 80B, and 80C are various views of the fourth exemplary structure after formation of integrated plate-and-via structures according to the fourth embodiment of the present disclosure. FIG. 80A is a horizontal cross-sectional view along the horizontal plane A-A′ shown in FIGS. 80B and 80C. FIG. 80B is a vertical cross-sectional view along the vertical plane B-B′ shown in FIG. 80A. FIG. 80C is a vertical cross-sectional view along the vertical plane C-C′ shown in FIG. 80A.

FIG. 81 is a horizontal cross-sectional view of the fourth exemplary structure after filling cavities inside the integrated plate-and-via structures with dielectric cores according to the fourth embodiment of the present disclosure.

FIG. 82 is a horizontal cross-sectional view of a fifth exemplary structure at a level of a sacrificial material layer after formation of lateral isolation trenches according to a fifth embodiment of the present disclosure.

FIG. 83 is a horizontal cross-sectional view of the fifth exemplary structure at the level of the sacrificial material layer after formation of a sacrificial barrier liner and a sacrificial fill material layer according to the fifth embodiment of the present disclosure.

FIG. 84A is a horizontal cross-sectional view of the fifth exemplary structure at the level of the sacrificial material layer after removal of portions of the sacrificial barrier liner and the sacrificial fill material layer in a contact region according to the fifth embodiment of the present disclosure. FIG. 84A is a horizontal cross-sectional view along the horizontal plane A-A′ shown in FIG. 84B. FIG. 84B is a vertical cross-sectional view of the fifth exemplary structure along the vertical plane B-B′ of FIG. 84A.

FIG. 85A is a horizontal cross-sectional view of the fifth exemplary structure at the level of the sacrificial material layer after formation of strip-shaped cavities according to the fifth embodiment of the present disclosure. FIG. 85A is a horizontal cross-sectional view along the horizontal plane A-A′ shown in FIG. 85B. FIG. 85B is a vertical cross-sectional view of the fifth exemplary structure along the vertical plane B-B′ of FIG. 85A.

FIG. 86A is a horizontal cross-sectional view of the fifth exemplary structure at the level of the sacrificial material layer after formation of sacrificial edge fill structures according to the fifth embodiment of the present disclosure. FIG. 86A is a horizontal cross-sectional view along the horizontal plane A-A′ shown in FIG. 86B. FIG. 86B is a vertical cross-sectional view of the fifth exemplary structure along the vertical plane B-B′ of FIG. 86A.

FIG. 87 is a horizontal cross-sectional view of the fifth exemplary structure at the level of the sacrificial material layer after removal of the entirety of the sacrificial barrier liner and the sacrificial fill material layer according to the fifth embodiment of the present disclosure.

FIG. 88 is a horizontal cross-sectional view of the fifth exemplary structure at the level of the sacrificial material layer after formation of laterally-extending cavities according to the fifth embodiment of the present disclosure.

FIG. 89 is a horizontal cross-sectional view of the fifth exemplary structure at the level of a set of dielectric plates after removal of the sacrificial edge fill structures according to the fifth embodiment of the present disclosure.

FIG. 90 is a horizontal cross-sectional view of the fifth exemplary structure at the level of an electrically conductive layer after formation of electrically conductive layers according to the fifth embodiment of the present disclosure.

FIG. 91A is a horizontal cross-sectional view of the fifth exemplary structure at the level of the electrically conductive layer after formation of integrated plate-and-via structures and a continuous dielectric material portion according to the fifth embodiment of the present disclosure. FIG. 91A is a horizontal cross-sectional view along the horizontal plane A-A′ shown in FIG. 91B. FIG. 91B is a vertical cross-sectional view of the fifth exemplary structure along the vertical plane B-B′ of FIG. 91A.

FIG. 92 is another horizontal cross-sectional view of the fifth exemplary structure according to the fifth embodiment of the present disclosure.

FIG. 93 is a horizontal cross-sectional view of a first alternative configuration of the fifth exemplary structure according to the fifth embodiment of the present disclosure.

FIG. 94 is a horizontal cross-sectional view of a second alternative configuration of the fifth exemplary structure according to the fifth embodiment of the present disclosure.

### DETAILED DESCRIPTION

As discussed above, the embodiments of the present disclosure are directed to a three-dimensional memory device including integrated word line and via structures and methods for forming the same, the various aspects of which are described below. The embodiments of the present disclosure can be used to form various structures including a multilevel memory structure, non-limiting examples of which include semiconductor devices such as three-dimensional memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are used merely to identify similar elements, and different ordinals may be used across the specification and the claims of the instant disclosure. The same reference numerals refer to the same element or similar element. Unless otherwise indicated, elements having the same reference numerals are presumed to have the same composition. Unless otherwise indicated, a “contact” between elements refers to a direct contact between elements that provides an edge or a surface shared by the elements. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “prototype” structure or an “in-process” structure refers to a transient structure that is subsequently modified in the shape or composition of at least one component therein. As used herein, a first electrical component is electrically connected to a second electrical component if there exists an electrically conductive path between the first electrical component and the second electrical component.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that can be attached to a circuit board through a set of pins or solder balls. A semiconductor package may include a semiconductor chip (or a “chip”) or a plurality of semiconductor chips that are bonded thereamongst, for example, by flip-chip bonding or another chip-to-chip bonding. A package or a chip may include a single semiconductor die (or a “die”) or a plurality of semiconductor dies. A die is the smallest unit that can independently execute external commands or report status. Typically, a package or a chip with multiple dies is capable of simultaneously executing as many external commands as the total number of dies therein. Each die includes one or more planes. Identical concurrent operations can be executed in each plane within a same die, although there may be some restrictions. In case a die is a memory die, i.e., a die including memory elements, concurrent read operations, concurrent write operations, or concurrent erase operations can be performed in each plane within a same memory die. Each plane contains a number of memory blocks (or “blocks”), which are the smallest unit that can be erased by in a single erase operation. Each memory block contains a number of pages, which are the smallest units that can be selected for programming.

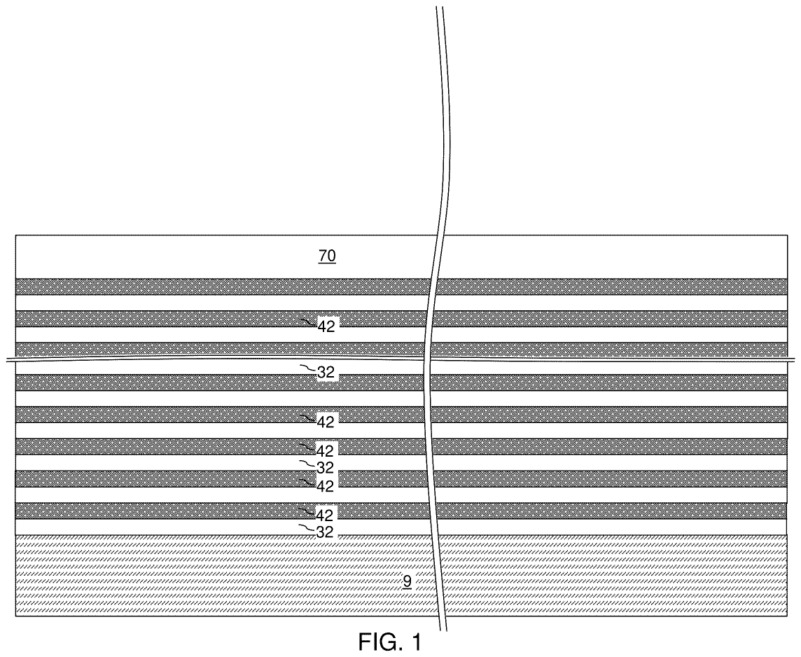

Referring to FIG. 1, a first exemplary structure according to the first embodiment of the present disclosure is illustrated, which can be used, for example, to fabricate a device structure containing vertical NAND memory devices. The first exemplary structure includes a substrate including a semiconductor material layer at least at an upper portion thereof. The semiconductor material layer 9 includes at least one elemental semiconductor material (e.g., a doped well in a single crystal silicon wafer or a deposited silicon layer), at least one III-V compound semiconductor material, at least one II-VI compound semiconductor material, at least one organic semiconductor material, or other semiconductor materials known in the art. In one embodiment, the semiconductor material layer may comprise a semiconductor material having a doping of a first conductivity type.

A stack of an alternating plurality of insulating layers 32 and sacrificial material layers 42 can be formed over the semiconductor material layer 9. The stack of the alternating plurality is herein referred to as an alternating stack (32, 42). In one embodiment, the alternating stack (32, 42) can include insulating layers 32 composed of the first material, and sacrificial material layers 42 composed of a second material different from that of insulating layers 32. The first material of the insulating layers 32 can be at least one insulating material. As such, each insulating layer 32 can be an insulating material layer. Insulating materials that can be used for the insulating layers 32 include, but are not limited to, silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 can be silicon oxide.

The second material of the sacrificial material layers 42 is a sacrificial material that can be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The sacrificial material layers 42 may comprise a dielectric material. In one embodiment, the sacrificial material layers 42 may comprise, and/or may consist essentially of, silicon nitride. The insulating layers 32 can be deposited, for example, by chemical vapor deposition (CVD). For example, if silicon oxide is used for the insulating layers 32, tetraethyl orthosilicate (TEOS) can be used as the precursor material for the CVD process. The sacrificial material layers 42 can be formed, for example, CVD or atomic layer deposition (ALD).

The thicknesses of the insulating layers 32 and the sacrificial material layers 42 can be in a range from 20 nm to 50 nm, although lesser and greater thicknesses can be used for each insulating layer 32 and for each sacrificial material layer 42. The number of repetitions of the pairs of an insulating layer 32 and a sacrificial material layer (e.g., a control gate electrode or a sacrificial material layer) 42 can be in a range from 2 to 1,024, and typically from 8 to 256 , although a greater number of repetitions can also be used. The top and bottom gate electrodes in the stack may function as the select gate electrodes. In one embodiment, each sacrificial material layer 42 in the alternating stack (32, 42) can have a uniform thickness that is substantially invariant within each respective sacrificial material layer 42.

Optionally, an insulating cap layer 70 can be formed over the alternating stack (32, 42). The insulating cap layer 70 includes a dielectric material that is different from the material of the sacrificial material layers 42. In one embodiment, the insulating cap layer 70 can include a dielectric material that can be used for the insulating layers 32 as described above. The insulating cap layer 70 can have a greater thickness than each of the insulating layers 32. The insulating cap layer 70 can be deposited, for example, by chemical vapor deposition. In one embodiment, the insulating cap layer 70 can be a silicon oxide layer.

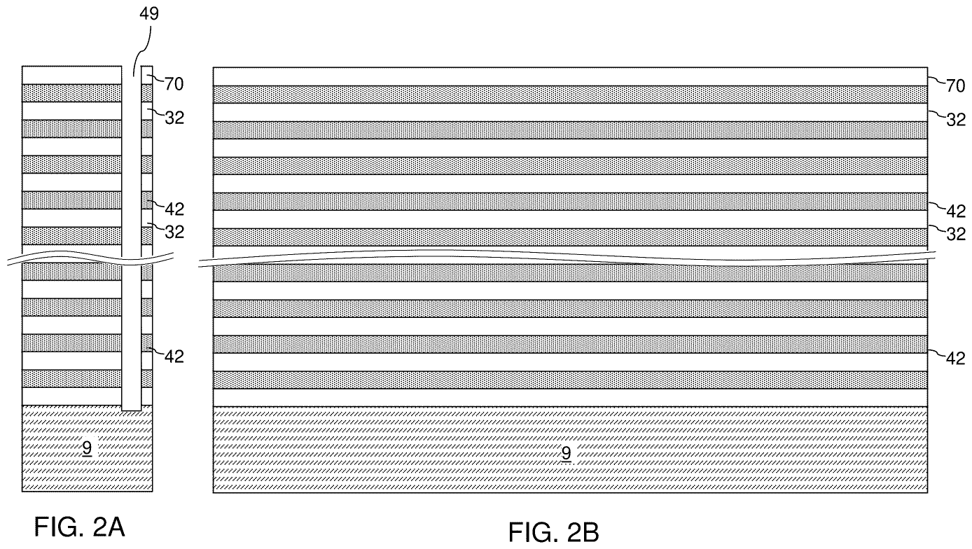

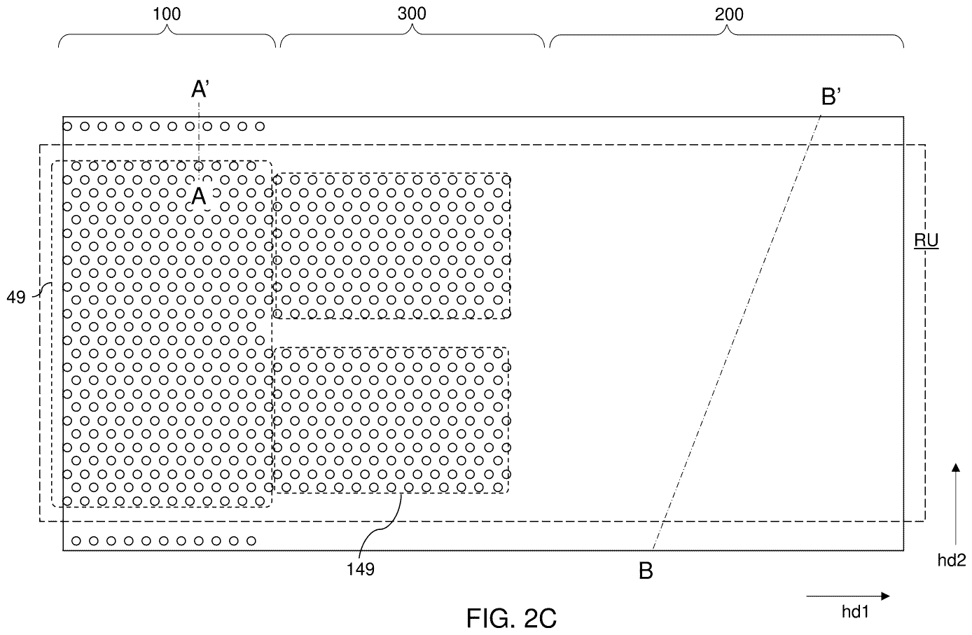

Referring to FIG. 2A-2C, a lithographic material stack (not shown) including at least a photoresist layer can be formed over the insulating cap layer 70, and can be lithographically patterned to form openings therein. The pattern in the lithographic material stack can be transferred through the insulating cap layer 70 and through the alternating stack (32, 42) by at least one anisotropic etch that uses the patterned lithographic material stack as an etch mask. Memory openings 49 are formed in a memory array region 100. As used herein, a “memory opening” refers to a structure in which memory elements, such as a memory stack structure, is subsequently formed. In one embodiment, the memory openings 49 may have a horizontal cross-sectional shape of a circle. In one embodiment, no openings are formed in a contact region 200, which is laterally spaced from the memory array region 100, and is subsequently employed to form contact via structures. The contact region 200 may be laterally spaced from the memory array region 100 along a first horizontal direction (e.g., word line direction) hd1. Dummy memory openings 149 can be formed in a connection region 300, which may be located between the memory array region 100 and the contact region 200.

In one embodiment, the pattern of the memory openings 49 and the dummy memory openings 149 may be a periodic pattern that is repeated along a second horizontal direction (e.g., bit line direction) hd2 that is perpendicular to the first horizontal direction hd1. The unit of repetition for the pattern of the memory openings 49 and the dummy memory openings 149 is herein referred to as a repetition unit RU. Each repetition unit RU may correspond to a memory block or to a portion of a memory block. Each repetition unit RU may comprise a two-dimensional array of memory openings 49 in the memory array region 100. The two-dimensional array of memory openings 49 may comprise a plurality of rows of memory openings 49, and each row of memory openings 49 may be arranged along the first horizontal direction hd2. Each repetition unit RU may comprise at least one two-dimensional array of dummy memory openings 149 in the connection region 300. In one embodiment, the number of rows of the memory openings 49 may be greater than the number of rows of dummy memory openings 149. In one embodiment, a width along the second horizontal direction hd2 of an area occupied by the memory openings 49 may be greater than the width along the second horizontal direction hd2 of an area occupied by the dummy memory openings 149.

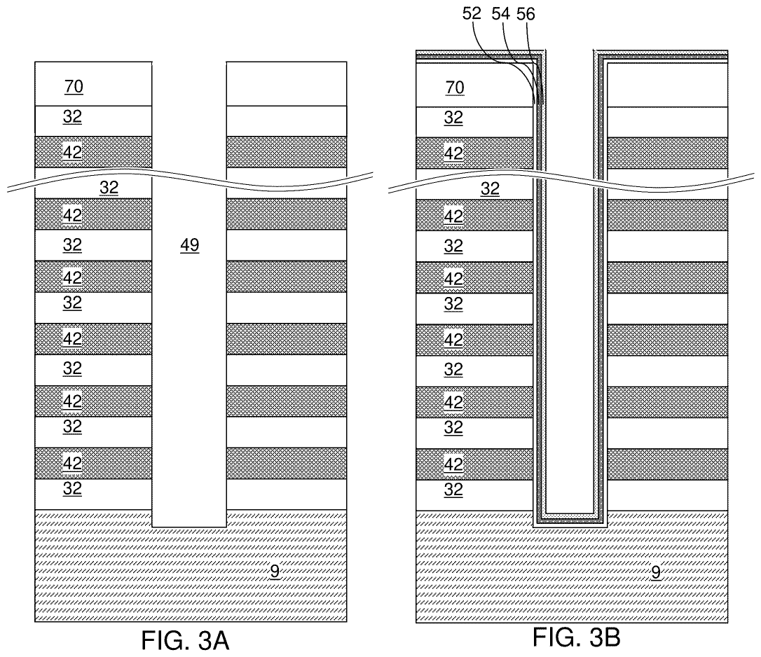

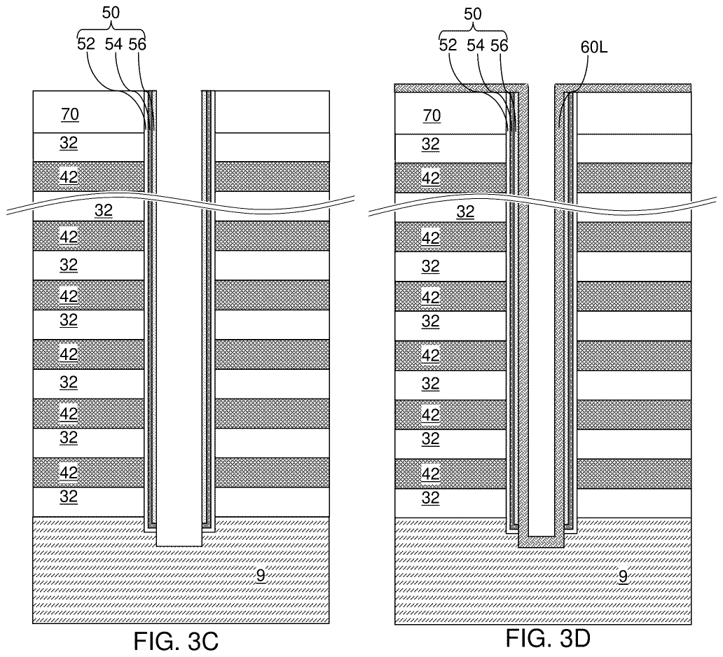

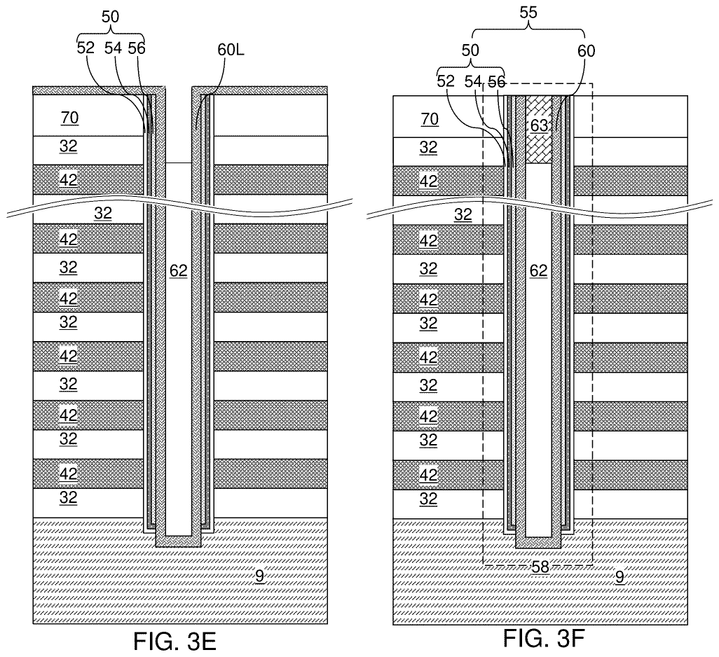

FIG. 3A-3F are sequential schematic vertical cross-sectional views of a memory opening 49 within the first exemplary structure during formation of a memory opening fill structure 58 therein according to the first embodiment of the present disclosure.

Referring to FIG. 3A, a memory opening 49 is illustrated after the processing steps described with reference to FIG. 2A-2C.

Referring to FIG. 3B, a set of material layers can be conformally deposited, which may include an optional blocking dielectric layer 52, a memory material layer 54, and an optional dielectric liner 56. The blocking dielectric layer 52 may comprise at least one blocking dielectric material such as silicon oxide and/or a dielectric metal oxide. The memory material layer 54 may comprise any memory material that can store memory bits therein. For example, the memory material layer 54 may comprise a charge storage layer, such as a silicon nitride layer. Alternatively, the memory material layer 54 may comprise a ferroelectric memory material, a resistive memory material, a phase change memory material, or any other memory material known in the art. In some embodiments, the memory material layer 54 may comprise a vertical stack of discrete memory material portions that are formed at levels of the electrically conductive layers 46. Generally, the memory material layer 54 may comprise a vertical stack of memory elements that are formed at the levels of the electrically conductive layers 46. In one embodiment, the vertical stack of memory elements comprises portions of the memory material layer 54 located at the levels of the electrically conductive layers 46. The optional dielectric liner 56, if present, can provide electrical isolation between the memory material layer 54 and a semiconductor channel to be subsequently formed. In case the memory material layer 54 comprises a charge storage material, the optional dielectric liner 56 may comprise a tunneling dielectric layer.

Referring to FIG. 3C, an anisotropic etch process may be performed to remove horizontally-extending portions of the optional blocking dielectric layer 52, the memory material layer 54, and the optional dielectric liner 56. The combination of vertically-extending portions of the optional blocking dielectric layer 52, the memory material layer 54, and the optional dielectric liner 56 that remain in a respective memory opening 49 constitutes a memory film 50.

Referring to FIG. 3D, a semiconductor channel layer 60L can be deposited over the memory films 50. The semiconductor channel layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel layer 60L includes amorphous silicon or polysilicon. The semiconductor channel layer 60L can be formed by a conformal deposition method such as low pressure chemical vapor deposition (LPCVD). In one embodiment, the semiconductor channel layer 60L can be deposited as an amorphous semiconductor material. The thickness of the semiconductor channel layer 60L can be in a range from 2 nm to 10 nm, although lesser and greater thicknesses can also be used. A memory cavity is formed in the volume of each memory opening 49 that is not filled with the deposited material layers (52, 54, 56, 60L).

Referring to FIG. 3E, a dielectric core layer can be deposited to fill any remaining portion of the memory cavity within each memory opening. The dielectric core layer includes a dielectric material, such as silicon oxide or organosilicate glass. The dielectric core layer can be deposited by a conformal deposition method such as low pressure chemical vapor deposition (LPCVD), or by a self-planarizing deposition process such as spin coating. The dielectric core layer can be subsequently recessed selective to the material of the semiconductor channel layer 60L, for example, by a recess etch. The material of the dielectric core layer is vertically recessed below the horizontal plane including the top surface of the insulating cap layer 70. Each remaining portion of the dielectric core layer constitutes a dielectric core 62.

Referring to FIG. 3F, a doped semiconductor material having a doping of a second conductivity type can be deposited within each recess cavity located above the dielectric cores 62. The second conductivity type is the opposite of the first conductivity type. For example, if the first conductivity type is p-type, the second conductivity type is n-type, and vice versa. In one embodiment, the doped semiconductor material may be deposited as an amorphous semiconductor material. The dopant concentration in the doped semiconductor material having a doping of the second conductivity type can be in a range from 5.0×10¹⁸/cm³ to 2.0×10²¹/cm³, although lesser and greater dopant concentrations can also be used.

A planarization process can be performed to remove portions of the doped semiconductor material having a doping of the second conductivity type and the semiconductor channel layer 60L from above the top surface of the insulating cap layer 70, for example, by chemical mechanical planarization (CMP) or a recess etch to form drain regions 63. Each remaining portion of the semiconductor material having a doping of the second conductivity type constitutes a drain region 63. Each remaining portion of the semiconductor channel layer 60L constitutes a vertical semiconductor channel 60. Electrical current can flow through each vertical semiconductor channel 60 when a vertical NAND device including the vertical semiconductor channel 60 is turned on. Within each memory opening 49, a dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which can store electrical charges with a macroscopic retention time. In some embodiments, a blocking dielectric layer 52 may not be present in the memory film 50 at this step, and a blocking dielectric layer may be subsequently formed after formation of laterally-extending cavities. As used herein, a macroscopic retention time refers to a retention time suitable for operation of a memory device as a permanent memory device such as a retention time in excess of 24 hours. Each combination of a memory film 50 and a vertical semiconductor channel 60 constitutes a memory stack structure 55.

Each contiguous combination of a vertical semiconductor channel 60 and a memory film 50 constitutes a memory stack structure 55. Thus, each memory stack structure 55 can include a vertical semiconductor channel 60, a dielectric liner 56, a plurality of memory elements comprising portions of the memory material layer 54, and an optional blocking dielectric layer 52. Each combination of a memory stack structure 55, a dielectric core 62, and a drain region 63 within a memory opening 49 is herein referred to as a memory opening fill structure 58.

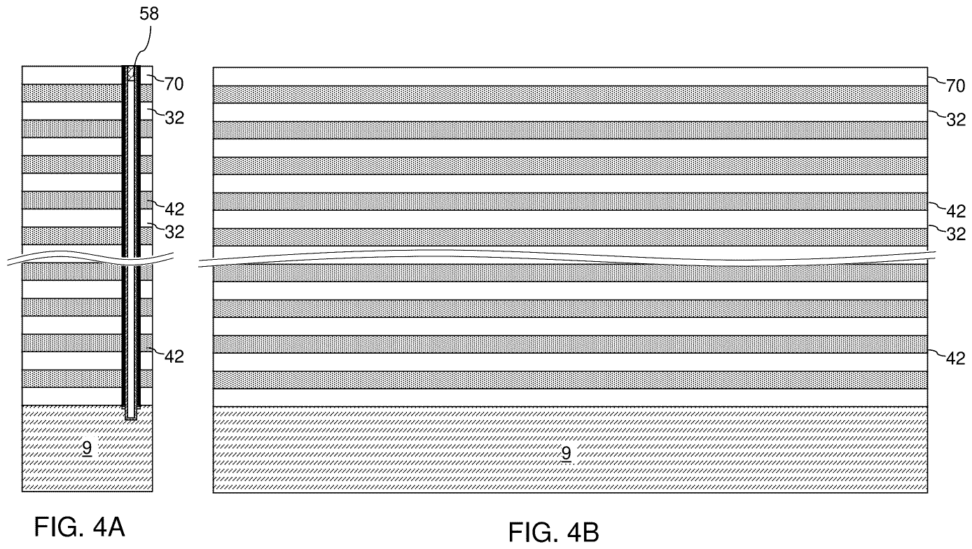

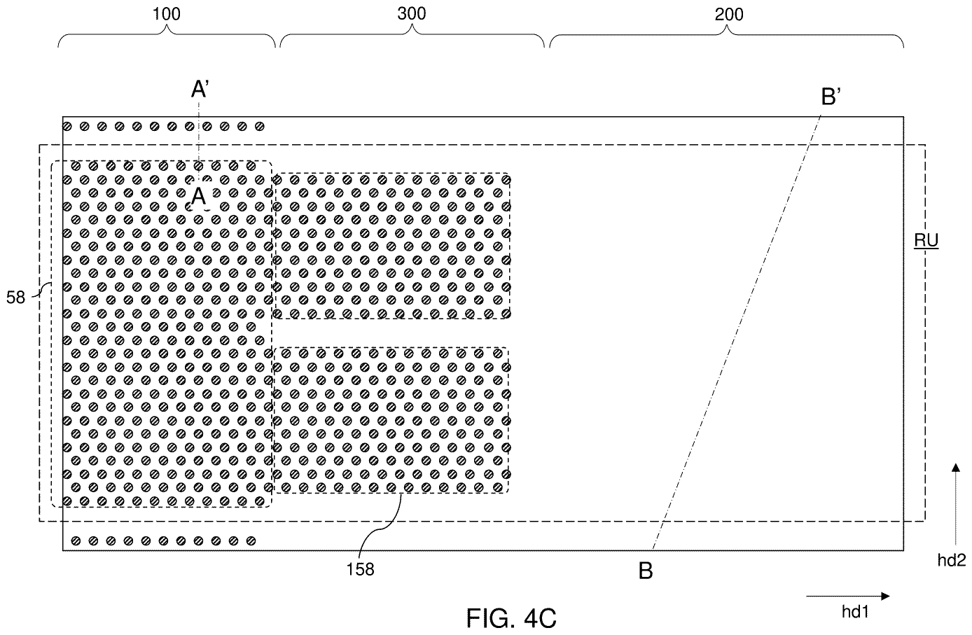

Referring to FIG. 4A-4C, the first exemplary structure is illustrated after the processing steps described with reference to FIG. 3F. Memory opening fill structures 58 are formed in the memory openings 49 in the memory array region 100. Generally, an alternating stack of insulating layers 32 and sacrificial material layers 42 is formed over a substrate, and memory openings 49 are formed through the alternating stack (32, 42). Memory opening fill structures 58 are formed in the memory openings 49. Each of the memory opening fill structures 58 comprises a respective vertical stack of memory elements (which may comprise portions of the respective memory material layer 54), a vertical semiconductor channel 60 and a drain region 63. Dummy memory opening fill structures 158 are formed in the dummy memory openings 149 in the connection region 300. Dummy memory opening fill structures 158 may have the same composition as the memory opening fill structures 58, except that the dummy drain regions of the dummy memory opening fill structures 158 are not electrically connected to subsequently formed bit lines, and therefore the dummy memory opening fill structures 158 do not store data during operation of the memory device. In one embodiment, the number of rows of the memory opening fill structures 58 may be greater than the number of rows of dummy memory opening fill structures 158. In one embodiment, a width along the second horizontal direction hd2 of an area occupied by the memory opening fill structures 58 may be greater than the width along the second horizontal direction hd2 of an area occupied by the dummy memory opening fill structures 158.

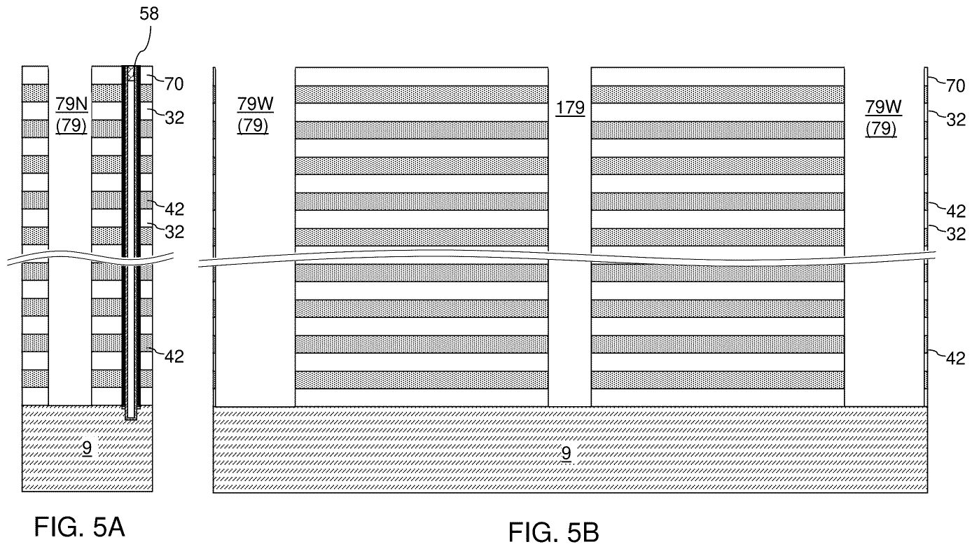

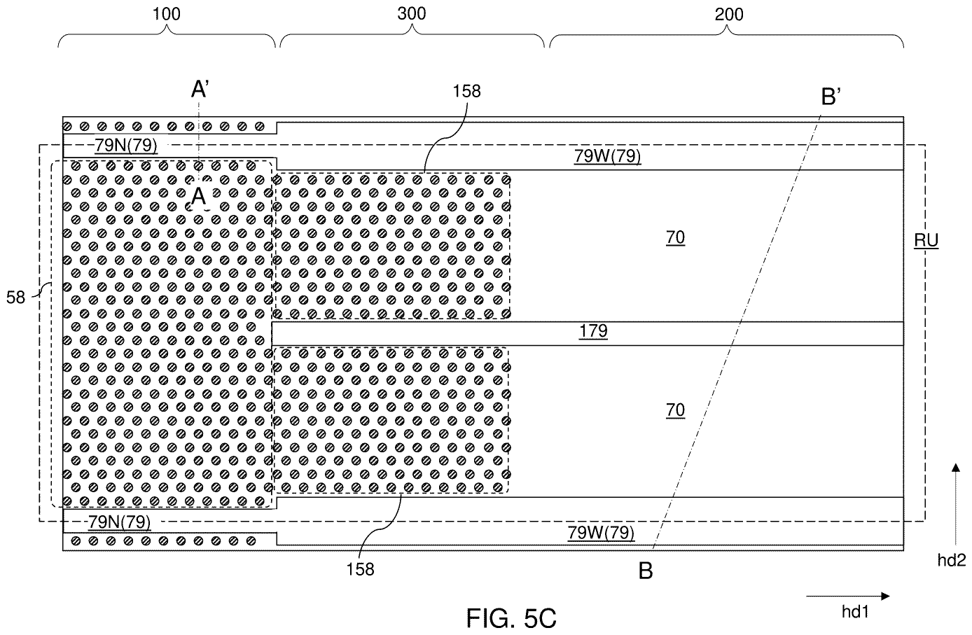

Referring to FIG. 5A-5C, a photoresist layer (not shown) can be applied over the insulating cap layer 70, and can be lithographically patterned to form elongated openings that laterally extend along the first horizontal direction hd1. An anisotropic etch process is performed to etch through unmasked portions of the insulating cap layer 70 and the alternating stack (32, 42) to form various trenches, which are herein referred to as lateral isolation trenches (79, 179). The photoresist layer can be subsequently removed, for example, by ashing.

According to an aspect of the present disclosure, the lateral isolation trenches (79, 179) include dual-width lateral isolation trenches 79 and access lateral isolation trenches 179 that are interlaced along the second horizontal direction hd2 with a uniform pitch along the second horizontal direction hd2. The uniform pitch may be the same as the width of each repetition unit RU (e.g., memory block width) along the second horizontal direction (e.g., bit line direction) hd2. Each dual-width lateral isolation trench 79 comprises a respective wide lateral isolation trench segment 79W having a first width and a narrow lateral isolation trench segment 79N having a second width. The first width is greater than the second width. In one embodiment, the second width is greater than the thickness of each sacrificial material layer 42. In one embodiment, the second width may be greater than the thickness of each sacrificial material layer 42 at least by a factor of 2, and preferably by a factor of 4, and more preferably by a factor of 10. The first width is greater than the second width at least by the thickness of each sacrificial material layer 42, and preferably by twice, and/or four times, and/or 8 times, the thickness of each sacrificial material layer 42. Each access lateral isolation trench 179 may have a uniform width that is the same as or about the same as the second width.

In one embodiment, each wide lateral isolation trench segment 79W and each access lateral isolation trench 179 laterally extend through the contact region 200 and the connection region 300, and do not extend into the memory array region 100. Each narrow lateral isolation trench segment 79N laterally extends through the memory array region 100. Each narrow lateral isolation trench segment 79N may be adjoined to a respective wide lateral isolation trench segment 79W at or adjacent to a boundary between the memory array region 100 and the connection region 300. Generally, the dual-width lateral isolation trenches 79 and the access lateral isolation trenches 179 may be formed simultaneously employing an anisotropic etch process. The dual-width lateral isolation trenches 79 and the access lateral isolation trenches 179 laterally extend along the first horizontal direction hd1, and are interlaced along the second horizontal direction hd2 such that the dual-width lateral isolation trenches 79 and the access lateral isolation trenches 179 alternate along the second horizontal direction hd2.

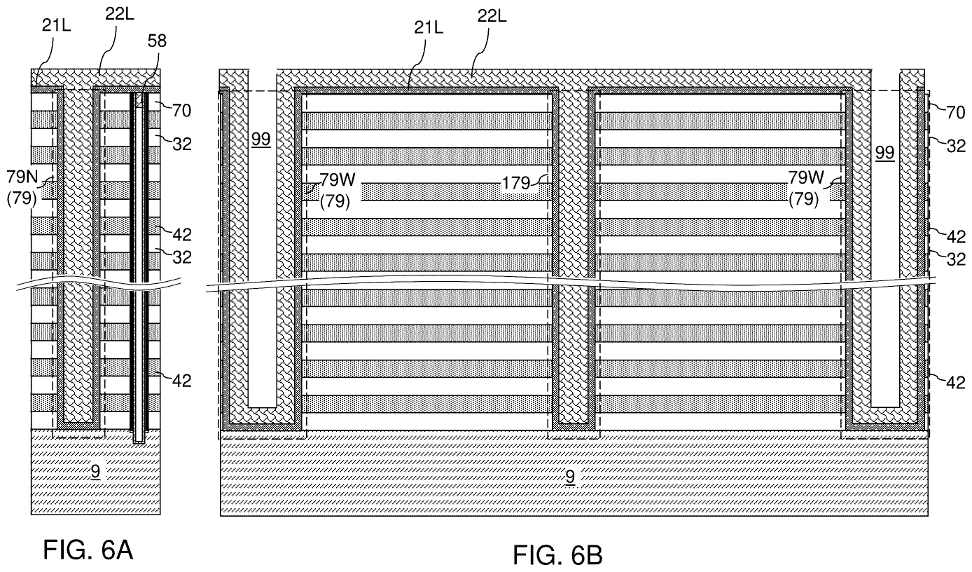

Referring to FIGS. 6A and 6B, a sacrificial barrier liner 21L may be conformally deposited on the first exemplary structure. The sacrificial barrier liner 21L may comprise a dielectric material, such as silicon nitride, and may have a thickness in a range from 5 nm to 30 nm, although lesser or greater thicknesses may also be employed.

A sacrificial fill material layer 22L can be conformally deposited over the sacrificial barrier liner 21L. The sacrificial fill material layer 22L comprises a sacrificial fill material that may be subsequently removed selectively to the material of the sacrificial barrier liner 21L. For example, the sacrificial fill material layer 22L may comprise amorphous silicon or polysilicon. The thickness of the sacrificial fill material layer 22L can be selected such that the sacrificial fill material layer 22L fills the volumes of the cavities in the narrow lateral isolation trench segments 79N and the access lateral isolation trenches 179 without completely filing the volumes of the cavities in the wide lateral isolation trench segments 79W. Thus, elongated wall-shaped voids 99 are present within the volumes of the wide lateral isolation trench segments 79W.

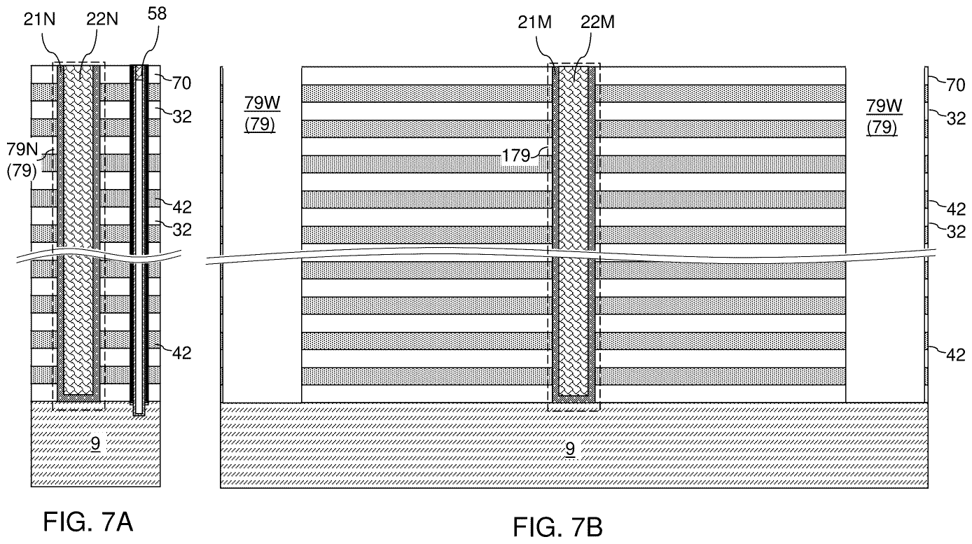

Referring to FIGS. 7A and 7B, a first isotropic etch process can be performed to isotropically etch back physically exposed portions of the sacrificial fill material layer 22L. The duration of the first isotropic etch back process can be selected such that the material of the sacrificial fill material layer 22L is completely removed from inside the wide lateral isolation trench segments 79W, while portions of the sacrificial fill material layer 22L located within the narrow lateral isolation trench segments 79N and the access lateral isolation trenches 179 are not removed. Each remaining portion of the sacrificial fill material layer 22L that remains in a narrow lateral isolation trench segment 79N is herein referred to as a sacrificial narrow isolation trench fill structure 22N. Each remaining portion of the sacrificial fill material layer 22L that remains in an access lateral isolation trench 179 is herein referred to as a sacrificial access lateral isolation trench fill structure 22M.

A second isotropic etch process can be performed to isotropically etch back physically exposed portions of the sacrificial barrier liner 21L. The duration of the second isotropic etch back process can be selected such that the material of the sacrificial barrier liner 21L is completely removed from inside the wide lateral isolation trench segments 79W, while the covered portions of the sacrificial barrier liner 21L located within the narrow lateral isolation trench segments 79N and the access lateral isolation trenches 179 are not removed. Each remaining portion of the sacrificial barrier liner 21L that remains in a narrow lateral isolation trench segment 79N is herein referred to as a sacrificial narrow trench liner 21N. Each remaining portion of the sacrificial barrier liner 21L that remains in an access lateral isolation trench 179 is herein referred to as a sacrificial access lateral isolation trench liner 21M.

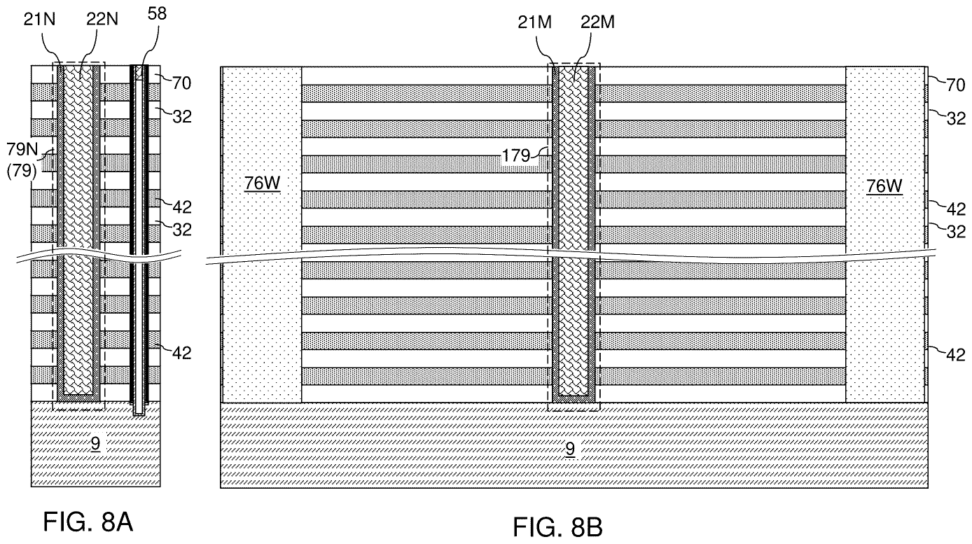

Referring to FIGS. 8A and 8B, a first dielectric fill material, such as undoped silicate glass (i.e., silicon oxide) or a doped silicate glass can be deposited in the volumes of the voids in the wide lateral isolation trench segments 79W. A planarization process, such as a chemical mechanical polishing process, can be performed to remove portions of the first dielectric fill material from above the horizontal plane including the top surface of the insulating cap layer 70. Each remaining portion of the first dielectric fill material that fills a respective wide lateral isolation trench segment 79W constitutes a wide lateral isolation trench fill structure 76W. Top surfaces of the lateral isolation trench fill structure 76W may be formed within the horizontal plane including the top surface of the insulating cap layer 70. Each wide lateral isolation trench fill structure 76W may have a uniform width along the second horizontal direction hd2, which may be the first width.

Generally, neighboring pairs of alternating stacks (32, 42) of insulating layers 32 and sacrificial material layers 42 may be laterally spaced apart from each other by a respective dual-width lateral isolation trench 79 having a wide lateral isolation trench segment 79W and a narrow lateral isolation trench segment 79N. The wide lateral isolation trench segment 79W is filled with a wide lateral isolation trench fill structure 76W that comprises the first dielectric fill material.

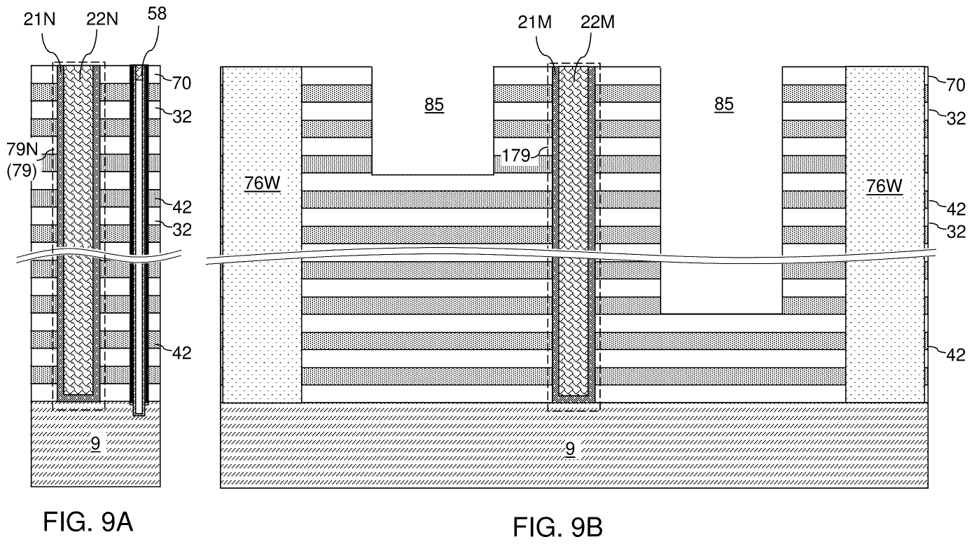

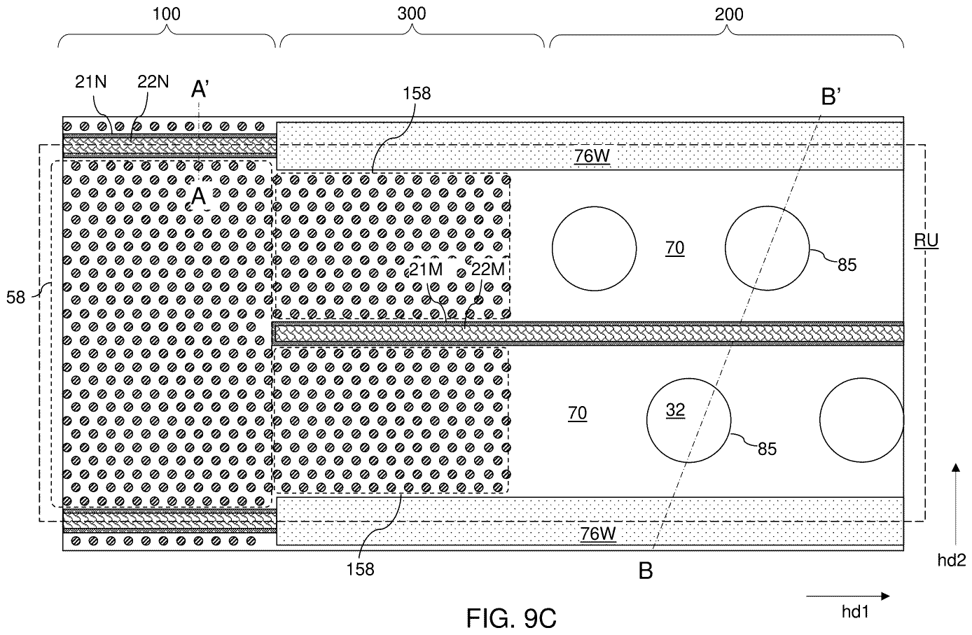

Referring to FIG. 9A-9C, contact via openings 85 are formed within the contact region 200. Each of the contact via openings 85 can vertically extend through the insulating cap layer 70 and optionally through a respective subset of the sacrificial material layers 42 and the insulating layers 32 such that a top surface of an insulating layer 32 is physically exposed at the bottom of each contact via opening 85. In one embodiment, the contact via openings 85 may have different depths from each other. In one embodiment, a contact via opening 85 may be provided for each insulating layer 32 such that a top surface segment of the insulating layer 32 is physically exposed underneath a respective one of the contact via openings 85.

The contact via openings 85 having different depths may be formed employing a plurality of masked anisotropic etch processes. In an illustrative example, a patterned hard mask layer (not shown) including openings therethrough may be formed over the insulating cap layer 70. The patterned hard mask layer may comprise a dielectric material such as silicon nitride, and/or a metallic material such as TiN. The openings in the patterned hard mask layer may have the pattern of all of the contact via openings 85 to be subsequently formed. An anisotropic etch process may be performed to transfer the pattern of the openings in the patterned hard mask layer through the insulating cap layer 70.

Subsequently, multiple iterations of a combination of a respective masking process and a respective anisotropic etch process may be performed to etch through a respective subset of the sacrificial material layers 42 and the insulating layers 32. Each masking process forms a respective patterned photoresist layer that masks a respective subset of the openings in the patterned hard mask layer without masking a respective complementary subset of the openings. Each anisotropic etch process etches a respective number of sacrificial material layers 42 and a respective number of insulating layers 32 underneath each opening in the pattered hard mask layer that is not masked by a respective patterned photoresist layer. In one embodiment, the number of etched sacrificial material layers 42 and etched insulating layers 32 underneath unmasked openings in the patterned hard mask layer may be a non-negative integer power of 2, i.e., 1, 2, 4, 8, 16, 32, 64, etc. By employing a combination of various masking patterns for the patterned photoresist layers, the total depths of the contact via openings 85 can be varied to enable physical exposure of the top surfaces of sacrificial material layers 42 at each level of the electrically conductive layers 46. The patterned hard mask layer can be subsequently removed. The lateral dimensions (such as diameters) of the contact via openings 85 may be in a range from 30 nm to 300 nm, although lesser and greater lateral dimensions may also be employed. Generally, a contact via opening 85 may vertically extend through an alternating stack of insulating layers 32 and sacrificial material layers 42.

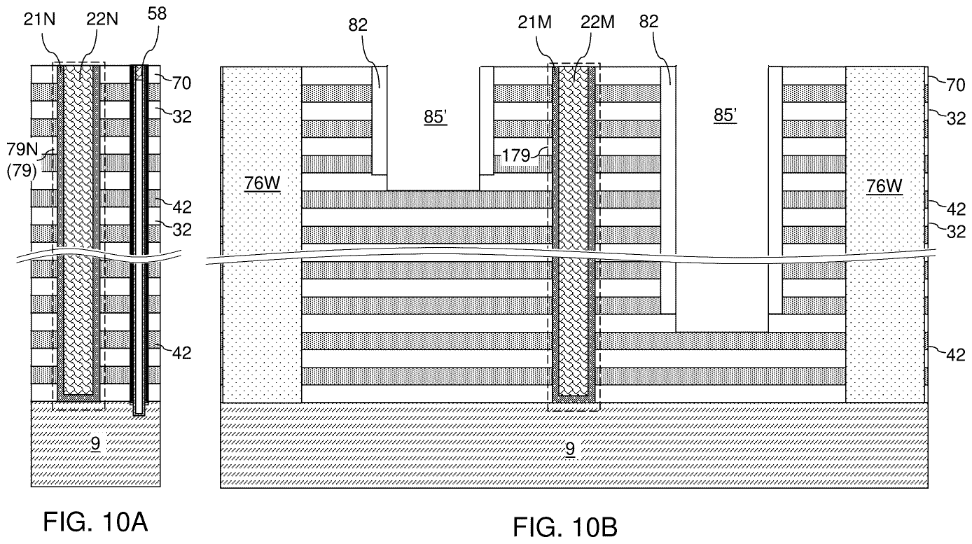

Referring to FIGS. 10A and 10B, tubular insulating spacers 82 may be formed in peripheral regions of the contact via openings 85 by depositing a conformal insulating material layer, such as a silicon oxide layer, and by performing an anisotropic etch process that etches horizontally-extending portions of the conformal insulating material layer. Remaining tubular portions of the conformal insulating material layer constitute the tubular insulating spacers 82. The anisotropic etch process can be prolonged to etch through unmasked portions of the insulating layers 32 such that contact via cavities 85′ laterally surrounded by the tubular insulating spacers 82 are vertically extended. A top surface segment of a respective underlying sacrificial material layer 42 may be physically exposed underneath each contact via cavity 85′.

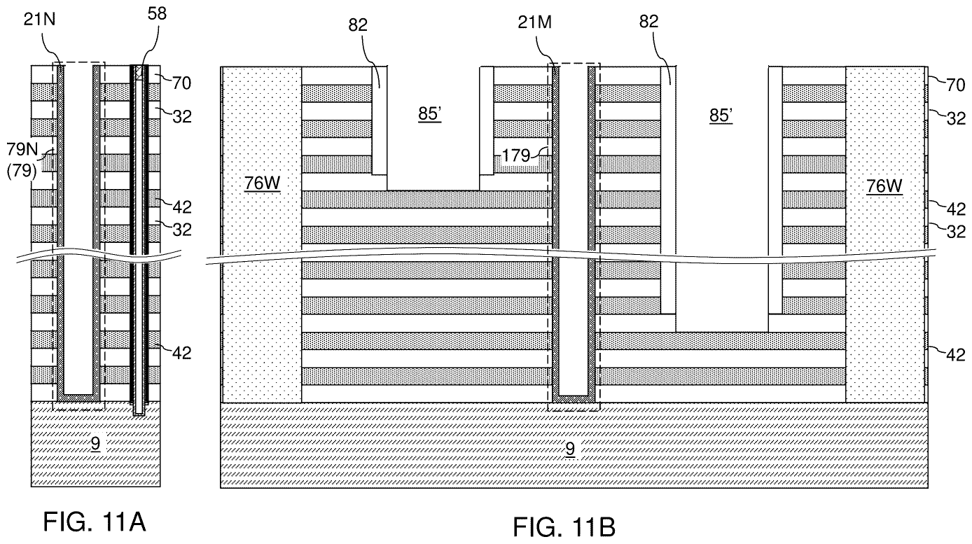

Referring to FIGS. 11A and 11B, a selective etch process can be performed to remove sacrificial narrow lateral isolation trench fill structures 22N and sacrificial access lateral isolation trench fill structures 22M. Voids are formed in the volumes from which the sacrificial narrow lateral isolation trench fill structures 22N and the sacrificial access lateral isolation trench fill structures 22M are removed.

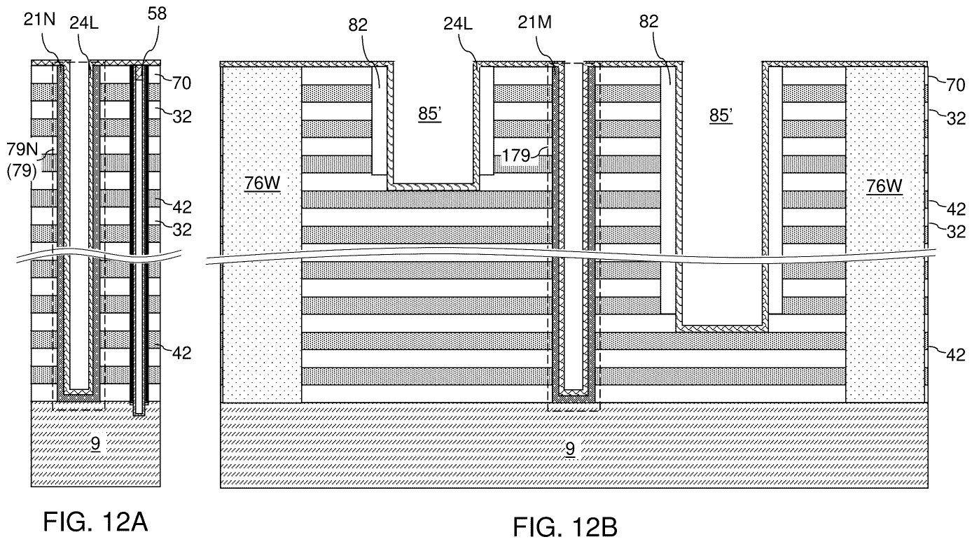

Referring to FIGS. 12A and 12B, a sacrificial barrier liner 24L can be deposited in the voids and over the insulating cap layer 70 by performing a first conformal deposition process. The sacrificial barrier liner 24L comprises a sacrificial barrier material that may be subsequently removed selectively to the material of the sacrificial narrow trench liners 21N and the sacrificial access lateral isolation trench liners 21M. For example, the sacrificial barrier liner 24L may comprise amorphous silicon or polysilicon having thickness in a range from 30 nm to 100 nm, although lesser or greater thicknesses may also be employed.

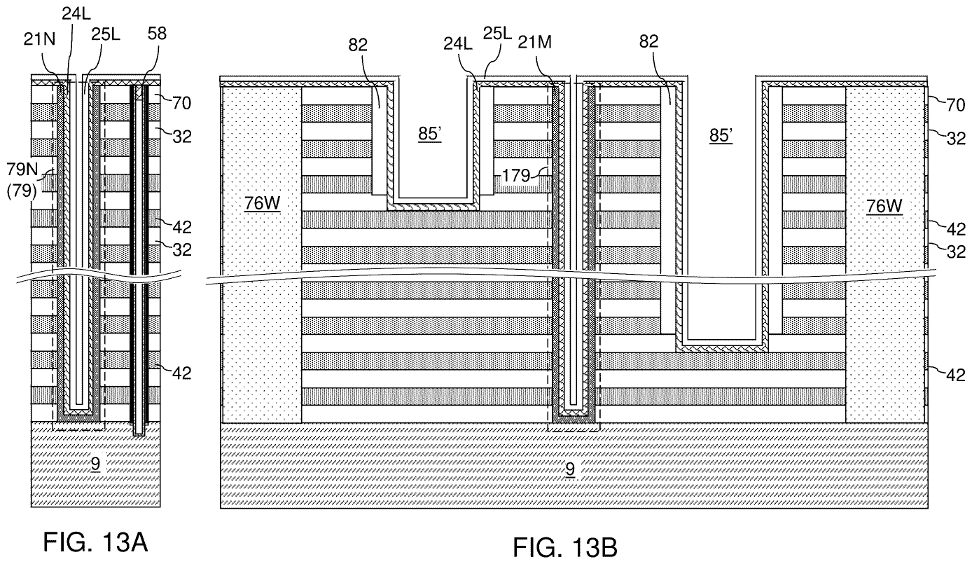

Referring to FIGS. 13A and 13B, a sacrificial dielectric liner 25L can be deposited by performing a second conformal deposition process. The sacrificial dielectric liner 25L comprises a sacrificial dielectric material that may be subsequently removed selectively to the material of the sacrificial barrier liner 24L. For example, the sacrificial dielectric liner 25L may comprise silicon oxide having thickness in a range from 5 nm to 30 nm, although lesser or greater thicknesses may also be employed.

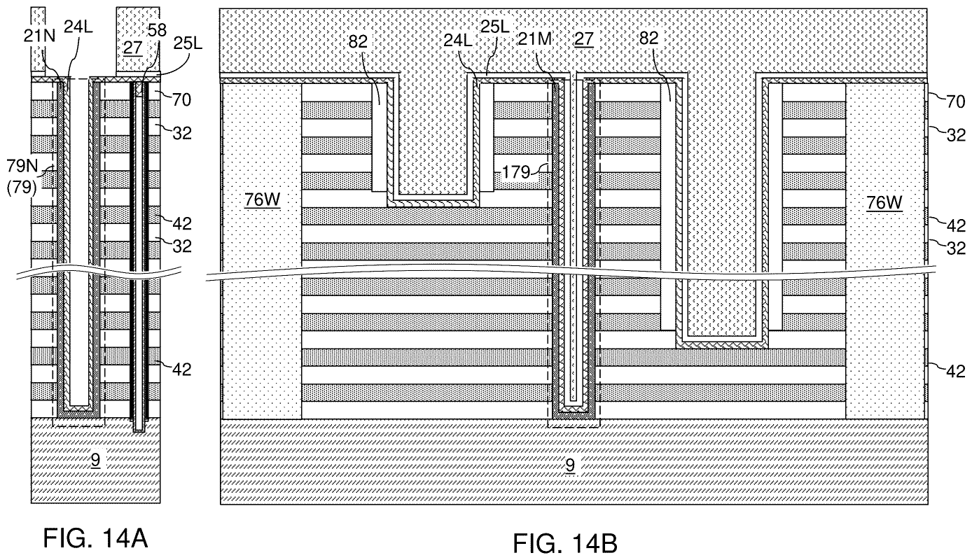

Referring to FIGS. 14A and 14B, a photoresist layer 27 can be applied over the first exemplary structure, and can be lithographically patterned to form openings over the areas of the narrow lateral isolation trench segments 79N while covering areas outside of the narrow lateral isolation trench segments 79N in a plan view. A first etch process can be performed to remove unmasked portions of the sacrificial dielectric liner 25L selectively to the material of the sacrificial barrier liner 24L. Each portion of the sacrificial dielectric liner 25L located within the narrow lateral isolation trench segments 79N may be removed, and surfaces of the sacrificial barrier liner 24L may be physically exposed around the wall-shaped cavities within the volumes of the narrow lateral isolation trench segments 79N.

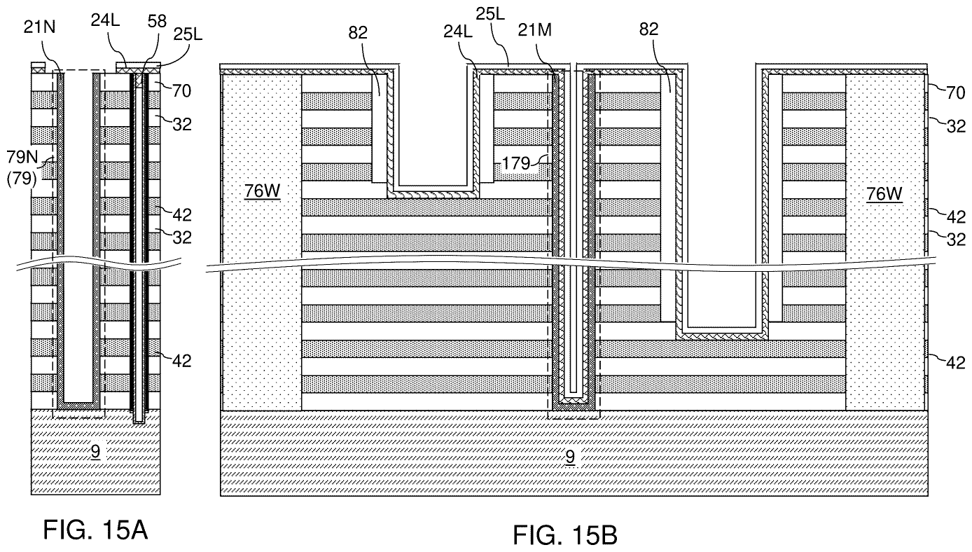

Referring to FIGS. 15A and 15B, a second etch process can be performed to remove unmasked portions of the sacrificial barrier liner 24L selectively to the materials of the sacrificial dielectric liner 25L and the sacrificial narrow trench liners 21N. Surfaces of the sacrificial narrow trench liners 21N are physically exposed in the narrow lateral isolation trench segments 79N. The photoresist layer 27 can be subsequently removed, for example, by ashing.

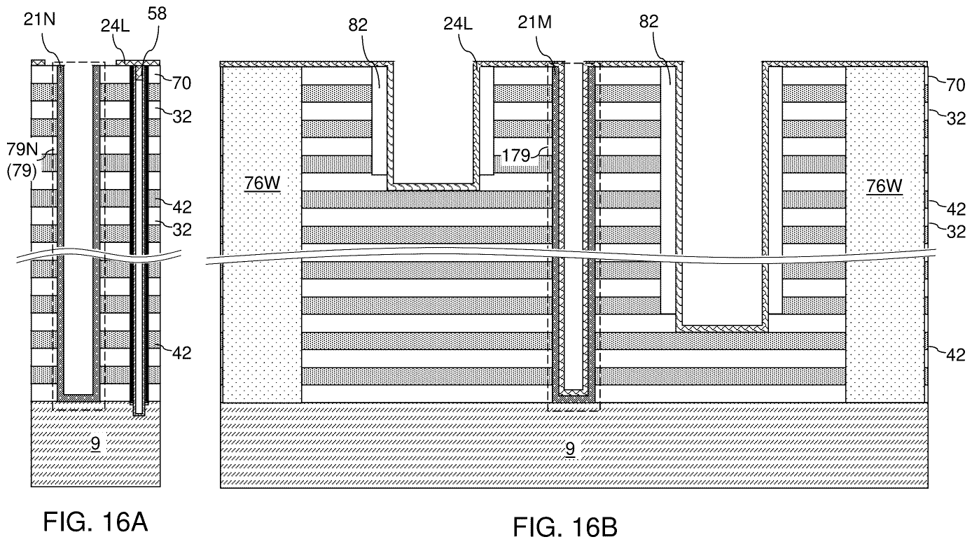

Referring to FIGS. 16A and 16B, remaining portions of the sacrificial dielectric liner 25L can be removed selectively to the material of the sacrificial barrier liner 24L. For example, if the sacrificial dielectric liner 25L comprises silicon oxide, a wet etch process employing dilute hydrofluoric acid may be performed to remove the sacrificial dielectric liner 25L.

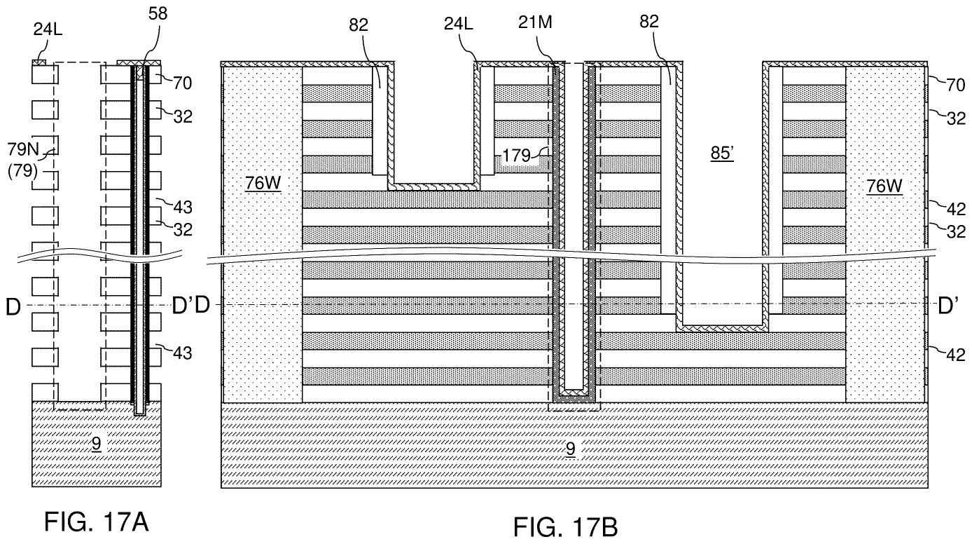

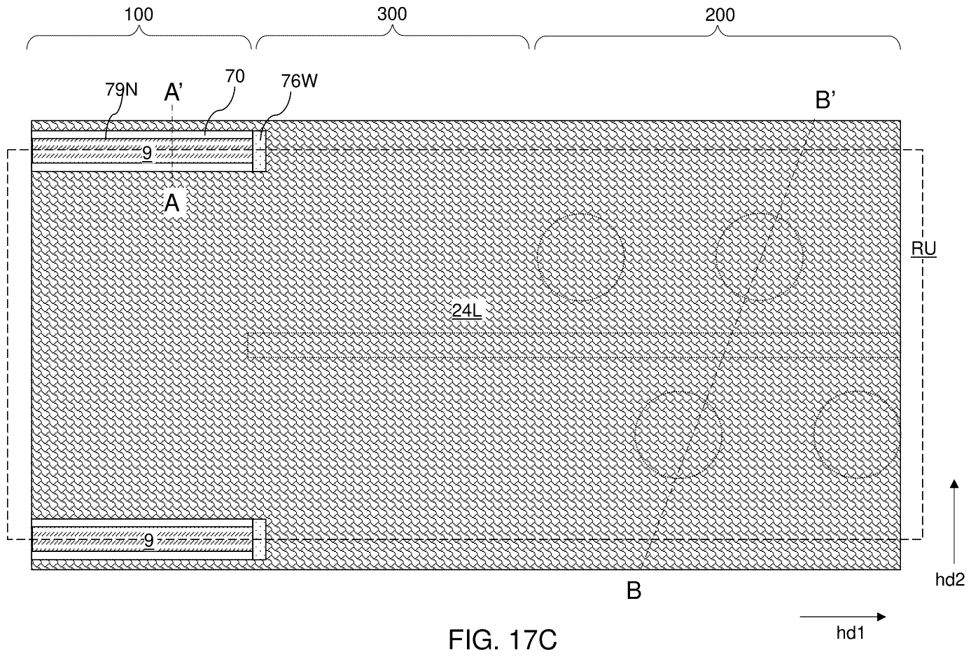

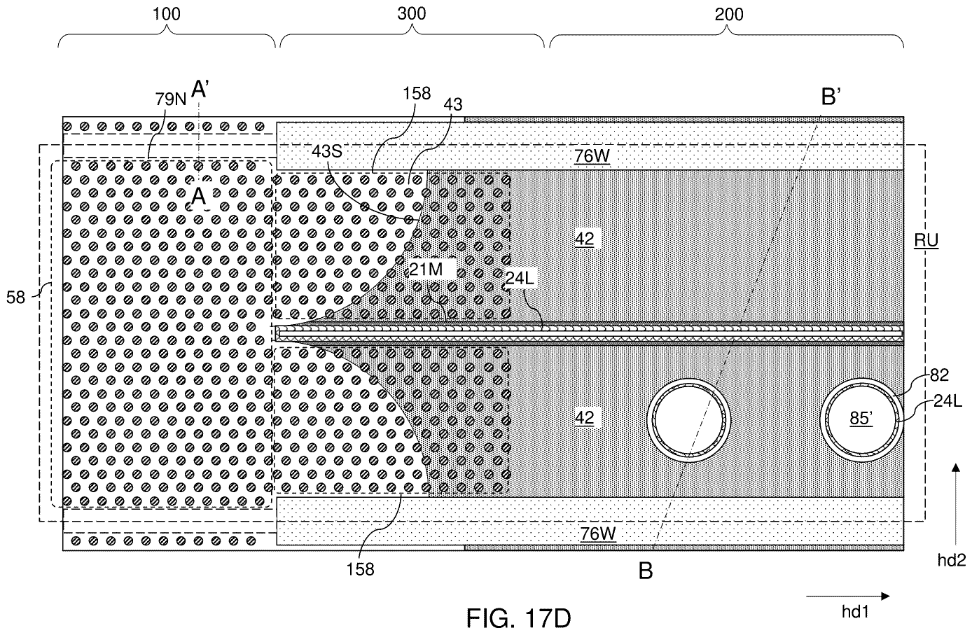

Referring to FIG. 17A-17D, a first selective isotropic etch process can be performed, which etches the materials of the sacrificial narrow trench liners 21N and the sacrificial material layers 42. In one embodiment, the sacrificial narrower trench liners 21N, the sacrificial access lateral isolation trench liners 21M, and the sacrificial material layers 42 may comprise the same material, such as silicon nitride. The first selective isotropic etch process removes the entirety of the sacrificial narrow trench liners 21N and laterally recesses physically exposed portions of the sacrificial material layers 42 by a first etch distance, but does not etch the sacrificial access lateral isolation trench liners 21M that are covered by the sacrificial barrier liner 24L.

Generally, the sacrificial material layers 42 are isotropically recessed from around the narrow lateral isolation trench segments 79N by the first lateral etch distance selectively to the materials of the insulating layers 32, the insulating cap layer 70, the tubular insulating spacers 82, the semiconductor material layer 9, and the material of the outermost layers of the memory films 50. Laterally-extending cavities 43 are formed in volumes from which the sacrificial material layers 42 are removed. The first lateral etch distance is greater than the lateral spacing between neighboring pairs of narrow lateral isolation trench segments 79N. Thus, a continuous void that laterally extends through all of the repetition units RU can be formed in the memory array region 100 at each level of the sacrificial material layers 42.

The first selective isotropic etch process may comprise a wet etch process employing a wet etch solution, and/or may comprise a gas phase (dry) etch process in which the etchant is introduced in a vapor phase into the narrow lateral isolation trench segments 79N. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. The memory opening fill structures 58 provide structural support while the laterally-extending cavities 43 are present within volumes previously occupied by the sacrificial material layers 42.

The laterally-extending cavities 43 expand laterally from around the narrow lateral isolation trench segments 79N until the laterally-extending cavities 43 merge into continuous laterally-extending void that continuously extend between neighboring pairs of narrow lateral isolation trench segments 79N within the areas of the memory array region 100. The first isotropic etch process isotropically recesses the sacrificial material layers 42 employing the narrow lateral isolation trench segments 79N as first conduits for a first isotropic etchant while the wide lateral isolation trench fill structures 76W prevent isotropic etchant access to the sacrificial material layers 42 through the wide lateral isolation trench segments 79W. In this case, the wide lateral isolation trench segments 79W are filled with the wide lateral isolation trench fill structures 76W during the first selective isotropic etch process.

In one embodiment shown in FIG. 17D, each of the laterally-extending cavities 43 may have a pair of laterally-convex sidewall sections 43S in a connection region 300 that is located between the memory array region 100 and the contact region 200. Each laterally-extending cavity 43 may have a portion located within the memory array region 100 and laterally extending between a respective pair of narrow lateral isolation trench segments 79N along the second horizontal direction hd2. The lateral extent of this portion along the second horizontal direction hd2 is herein referred to as a uniform word-line width, which is the width of a word line to be subsequently formed. In one embodiment, the uniform word-line width may correspond to a width of a memory block along the second horizontal direction hd2. In one embodiment, each of the laterally-extending cavities 43 has a variable width in the connection region 300 that changes from the uniform word-line width to zero with a lateral distance along the first horizontal direction hd1 from the memory array region 100 toward the contact region 200.

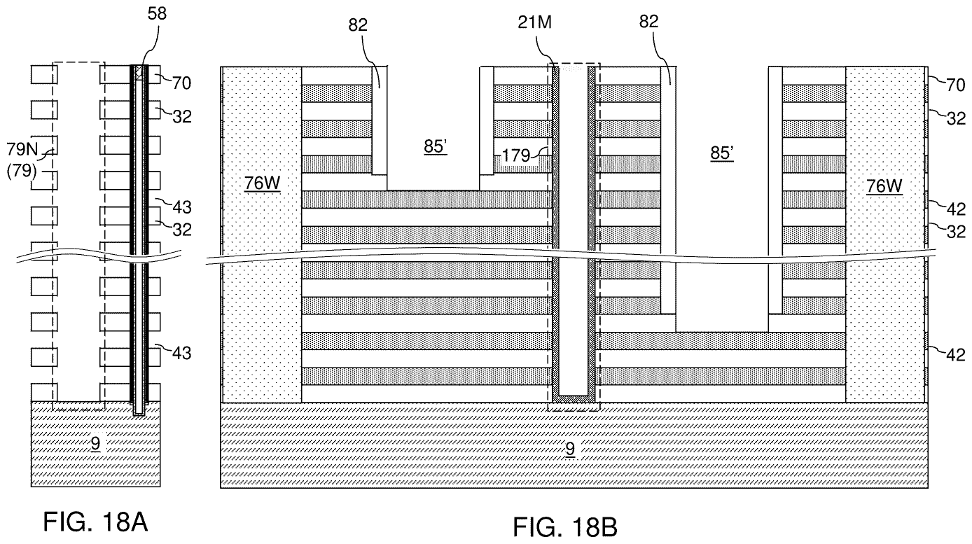

Referring to FIGS. 18A and 18B, an isotropic etch process can be performed to etch the sacrificial barrier liner 24L selectively to the material of the sacrificial access lateral isolation trench liners 21M. Sidewalls of the sacrificial access lateral isolation trench liners 21M can be physically exposed around the elongated voids within the access lateral isolation trenches 179. Further, top surface segments of the sacrificial material layers 42 may be exposed underneath the contact via cavities 85′.

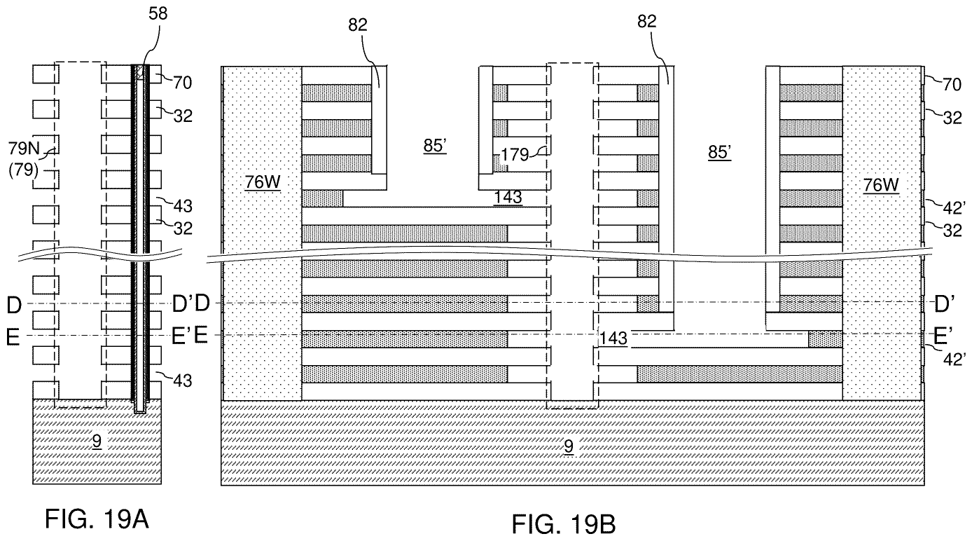

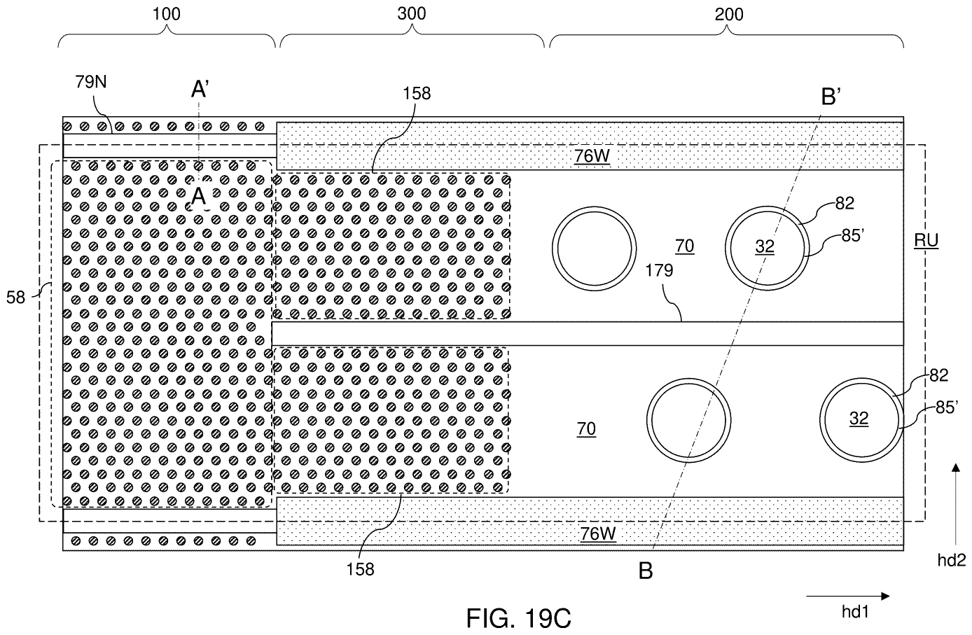

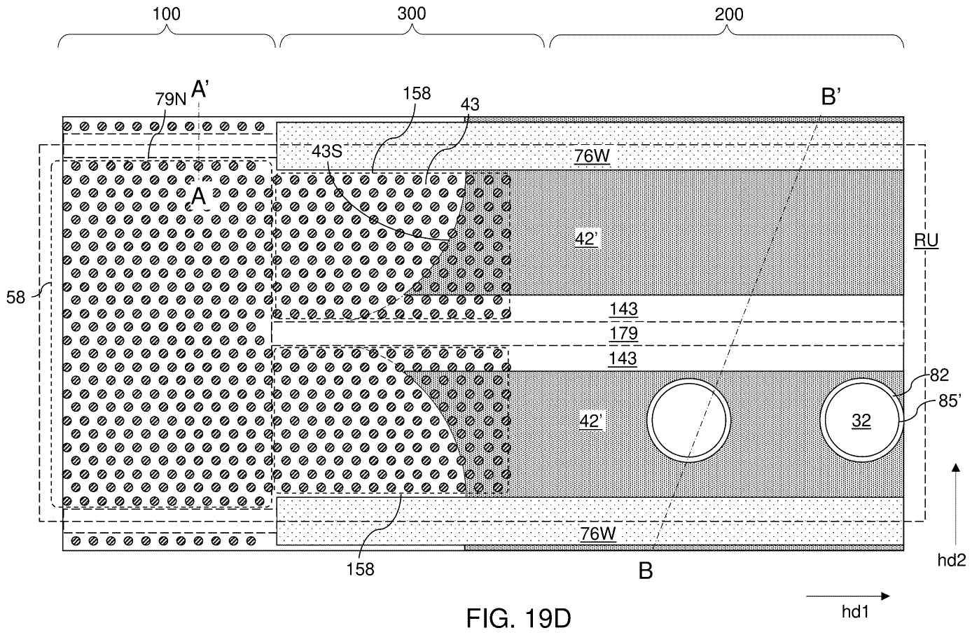

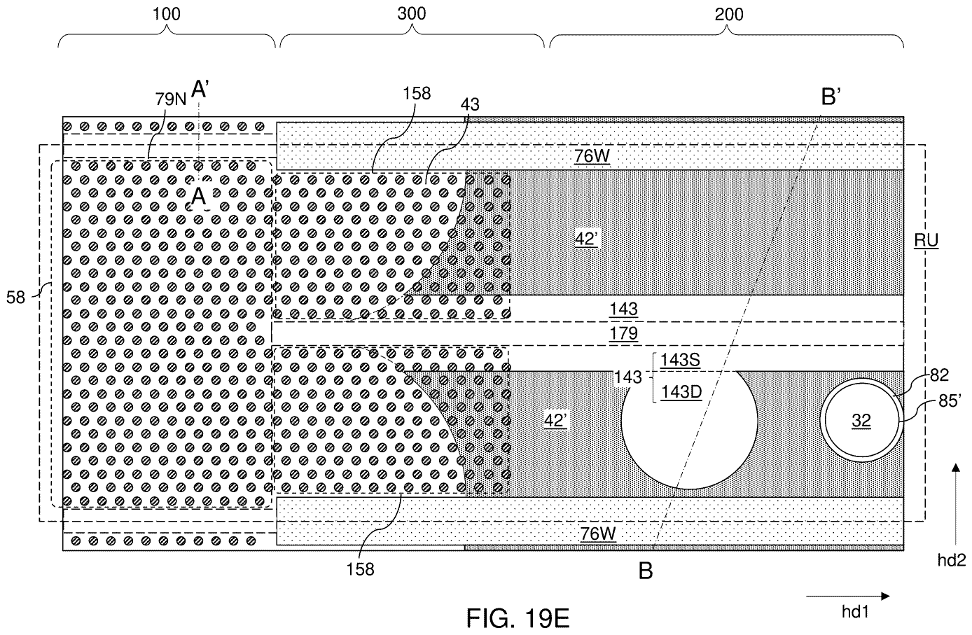

Referring to FIG. 19A-19E, a second selective isotropic etch process can be performed, which etches the materials of the sacrificial access lateral isolation trench liners 21M and the sacrificial material layers 42. The second selective isotropic etch process removes the entirety of the sacrificial access lateral isolation trench liners 21M, and laterally recesses physically exposed portions of the sacrificial material layers 42 by a second etch distance, which is less than the first etch distance and is less than the lateral distance between a neighboring pair of an access lateral isolation trench 179 and a wide lateral isolation trench fill structure 76W. Further, the second selective isotropic etch process etches portions of the sacrificial material layers 42 that are proximal to the contact via cavities 85′. Thus, the second selective isotropic etch process employs the access lateral isolation trenches 179 and the contact via cavities 85′ as conduits for an isotropic etchant that etches the materials of the sacrificial access lateral isolation trench liners 21M and the sacrificial material layers 42 in the contact region 200. The lateral recessing of the portions of the sacrificial material layers 42 from underneath the contact via cavities 85′ is isotropic. The duration of the second selective isotropic etch process is selected such that each of the cavities formed by removal of portions of the sacrificial material layers 42 from underneath the contact via cavities 85′ merges with a respective cavity that is formed by removal of a strip portion of a sacrificial material layer 42 around an access lateral isolation trench 179.

Generally, the sacrificial material layers 42 are isotropically recessed from around the access lateral isolation trenches 179 and the contact via cavities 85′ by the second lateral etch distance selectively to the materials of the insulating layers 32, the insulating cap layer 70, the tubular insulating spacers 82, the semiconductor material layer 9, and the material of the outermost layers of the memory films 50. Further, the laterally-extending cavities 43 can be laterally expanded during the second selective isotropic etch process. Connection cavities 143 are formed in volumes from which the sacrificial material layers 42 are removed around the access lateral isolation trenches 179 and the contact via cavities 85′. The second lateral etch distance is less than the lateral spacing between neighboring pairs of a respective access lateral isolation trench 179 and a wide lateral isolation trench fill structure 76W along the second horizontal direction hd2. Remaining portions of the sacrificial material layers 42 comprise dielectric material plates 42′.

The second selective isotropic etch process may comprise a wet etch process employing a wet etch solution, and/or may comprise a gas phase (dry) etch process in which the etchant is introduced in a vapor phase into the access lateral isolation trenches 179 and the contact via cavities 85′. For example, if the sacrificial material layers 42 include silicon nitride, the etch process can be a wet etch process in which the second exemplary structure is immersed within a wet etch tank including phosphoric acid, which etches silicon nitride selective to silicon oxide, silicon, and various other materials employed in the art. The memory opening fill structures 58 provide structural support while the laterally-extending cavities 43 are present within volumes previously occupied by the sacrificial material layers 42. The dielectric material plates 42′ provide structural support to remaining portions of the insulating layers 32 in the contact region 200. According to an aspect of the present disclosure, formation of support pillar structures in the contact region 200 is not necessary because the dielectric material plates 42′ provide structural support during the second selective isotropic etch process. Alternatively, support pillar structures (e.g., silicon oxide pillars) can be formed around the contact via cavities 85′ to provide additional support.

Each laterally-extending cavities 43 may be adjoined to a respective pair of connection cavities 143. The second isotropic etch process isotropically recesses the sacrificial material layers 42 employing the access lateral isolation trenches 179 and the contact via cavities 85′ as second conduits for a second isotropic etchant while the wide lateral isolation trench fill structures 76W prevent access by the isotropic etchant to the sacrificial material layers 42 through the wide lateral isolation trench segments 79W. In this case, the wide lateral isolation trench segments 79W are filled with the wide lateral isolation trench fill structures 76W during the second selective isotropic etch process.

In one embodiment, each of the laterally-extending cavities 43 may have a pair of laterally-convex sidewall sections 43S in a connection region 300 that is located between the memory array region 100 and the contact region 200. Each laterally-extending cavity 43 may have a portion located within the memory array region 100 and laterally extending between a respective pair of narrow lateral isolation trench segments 79N along the second horizontal direction hd2.

As shown in FIG. 19E, each of the connection cavities 143 may comprise a strip cavity portion 143S laterally extending along the first horizontal direction hd1 and having a uniform strip width along the second horizontal direction hd2 in the contact region 200. The uniform strip width is less than the uniform word line width. Further, each of the connection cavities 143 may comprise a disc-shaped cavity portion 143D that underlies a respective contact via cavity 85′ and is adjoined to the strip cavity portion 143S. A vertical stack of dielectric material plates 42′ may be vertically interlaced with the insulating layers 32. Each of the dielectric material plates 42′ may be laterally bounded by a respective laterally-extending cavity 43, a respective connection cavity 143, and a respective wide lateral isolation trench fill structure 76W.

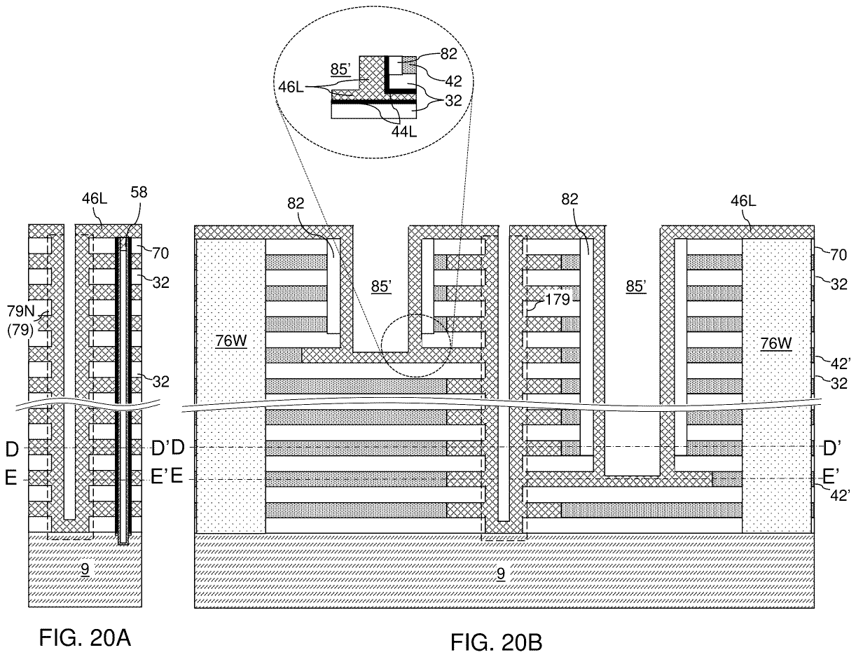

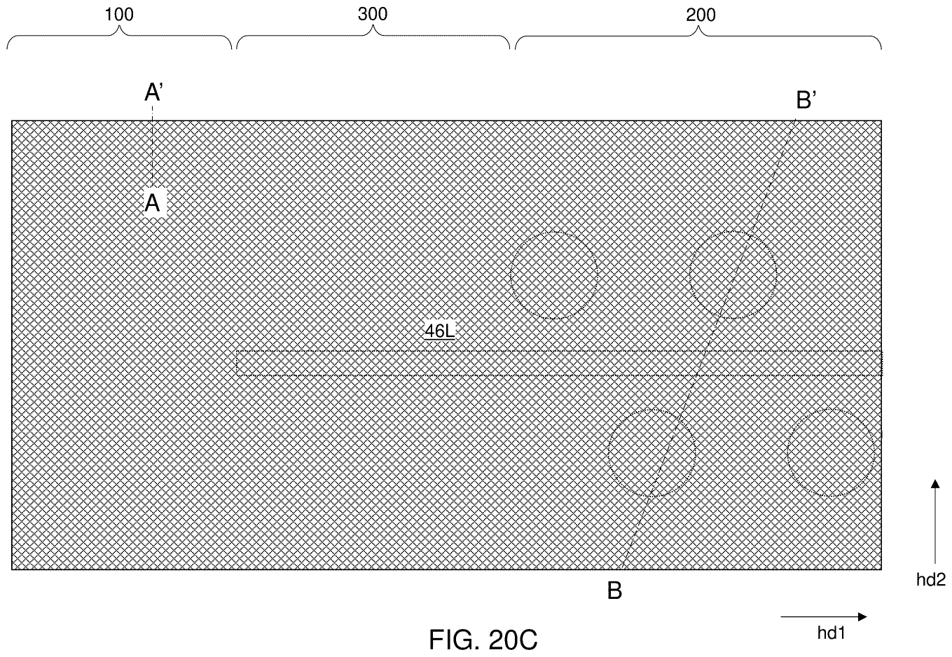

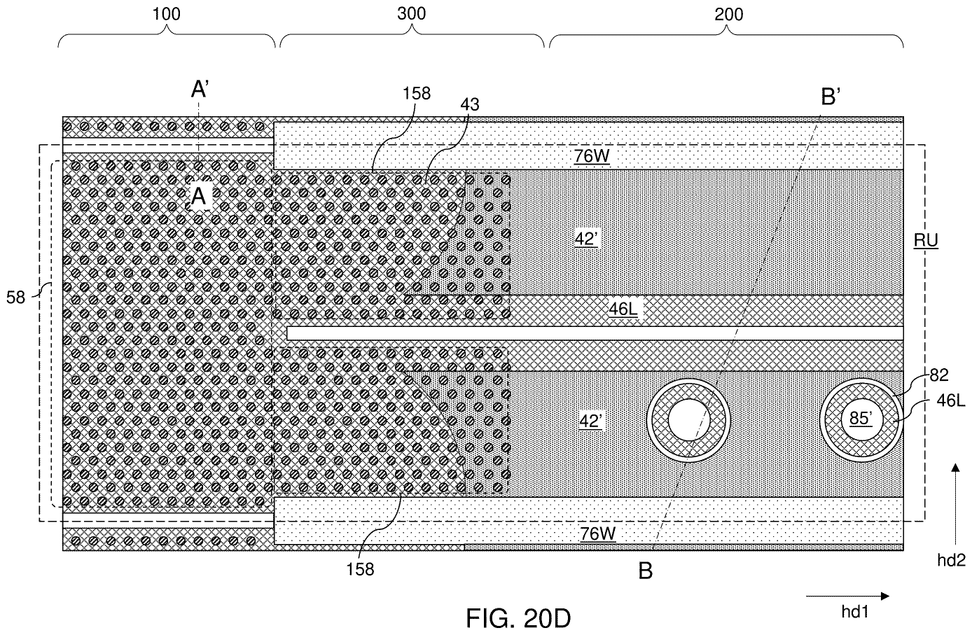

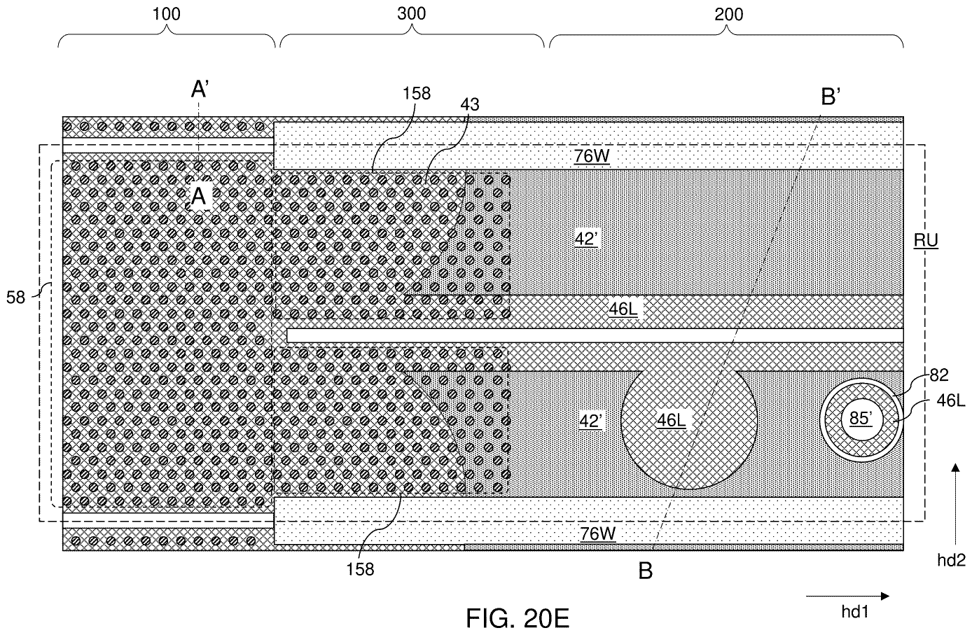

Referring to FIG. 20A-20E, an optional continuous backside blocking dielectric layer 44L may be conformally deposited into peripheral portions of the laterally-extending cavities 43, the connection cavities 143 and the contact via cavities 85′, as shown in the inset of FIG. 20B. The backside blocking dielectric 44L does not completely fill the cavities (43, 143, 85'). The backside blocking dielectric 44L may comprise any suitable dielectric material, such as a metal oxide dielectric layer, for example an aluminum oxide layer. At least one conductive material, such as a combination of a metallic barrier liner material and a metal fill material, may be conformally deposited in the laterally-extending cavities 43, the connection cavities 143, peripheral portions of the contact via cavities 85′, and over the insulating cap layer 70 to form a continuous electrically conductive layer 46L. If the continuous backside blocking dielectric layer 44L is present, then the continuous electrically conductive layer 46L is formed on the backside blocking dielectric 44L. The metallic barrier liner material may comprise a conductive metallic compound material such as TiN, TaN, WN, MoN, TiC, TaC, WC, alloys thereof, or a combination thereof. The metal fill material may comprise W, Ti, Ta, Mo, Co, Ru, Cu, alloys thereof, or combinations thereof. The total thickness of the at least one conductive material in regions that are not vertically bounded by a pair of an overlying insulating layer 32 and an underlying insulating layer 32 is greater than one half of the height of the laterally-extending cavities 43 and the connection cavities 143.

In one embodiment, each portion of the continuous electrically conductive layer 46L that is exposed to an overlying contact via cavity 85′ may have the same thickness as a tubular portion of the continuous electrically conductive layer 46L that is formed in the periphery of the overlying contact via cavity 85′. This thickness is greater than one half of the vertical spacing between vertically neighboring pairs of insulating layers 32, and may be less than or may be greater than the vertical spacing between vertically neighboring pairs of insulating layers 32. Generally, the continuous electrically conductive layer 46L comprises at least one electrically conductive material having a unform material composition throughout and is free of any material interface therein. As used herein, a material interface refers to an interface at which two different material are in direct contact with each other. For example, the metallic barrier liner material may have a unform material composition throughout and may be free of any material interface therein. Likewise, the metal fill material may have a unform material composition throughout and may be free of any material interface therein.

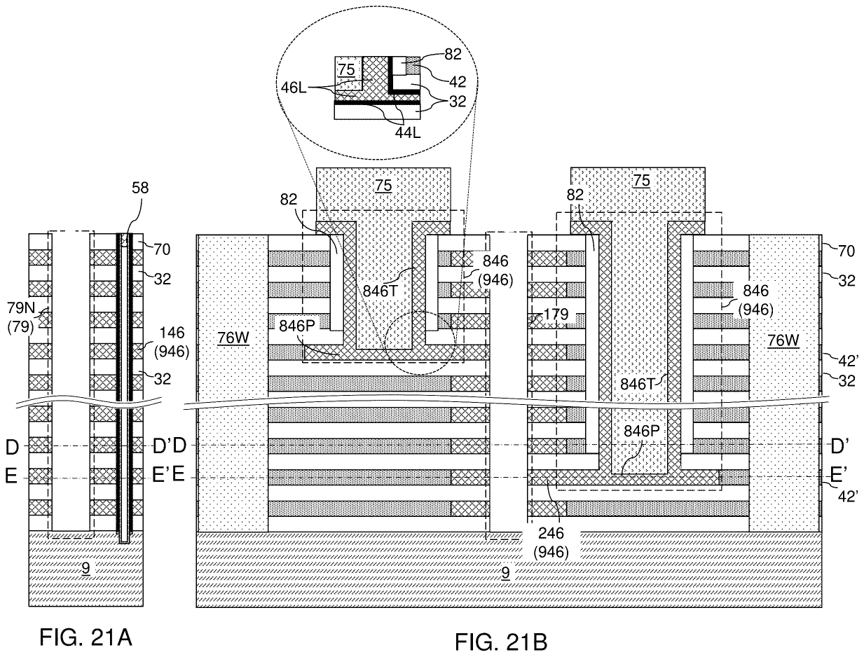

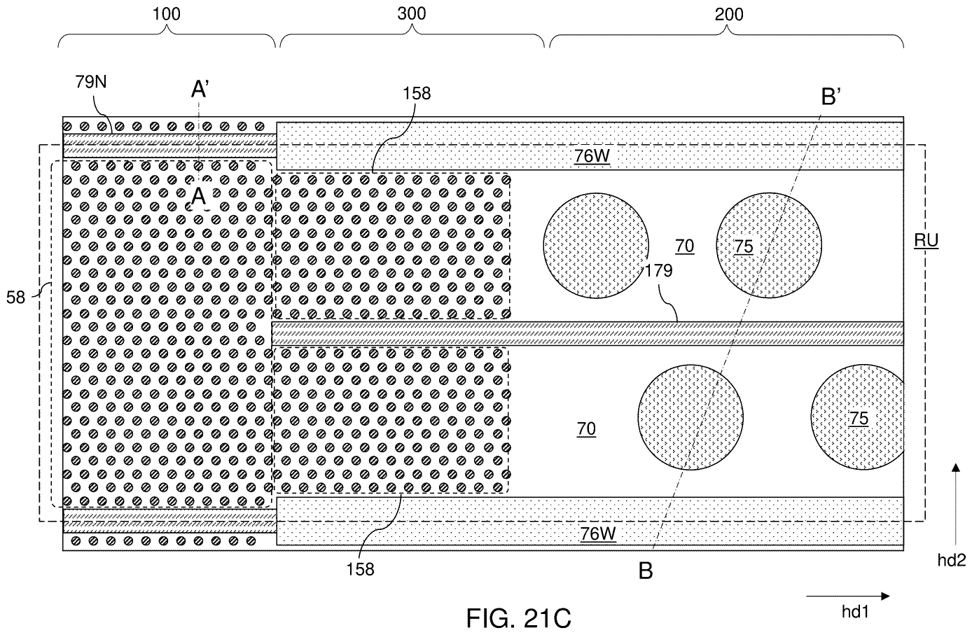

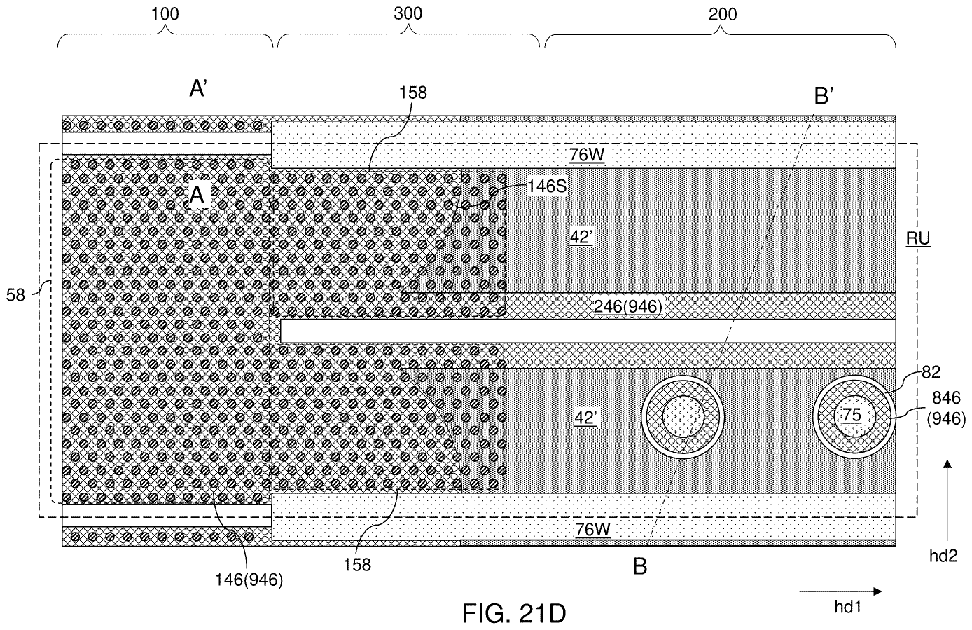

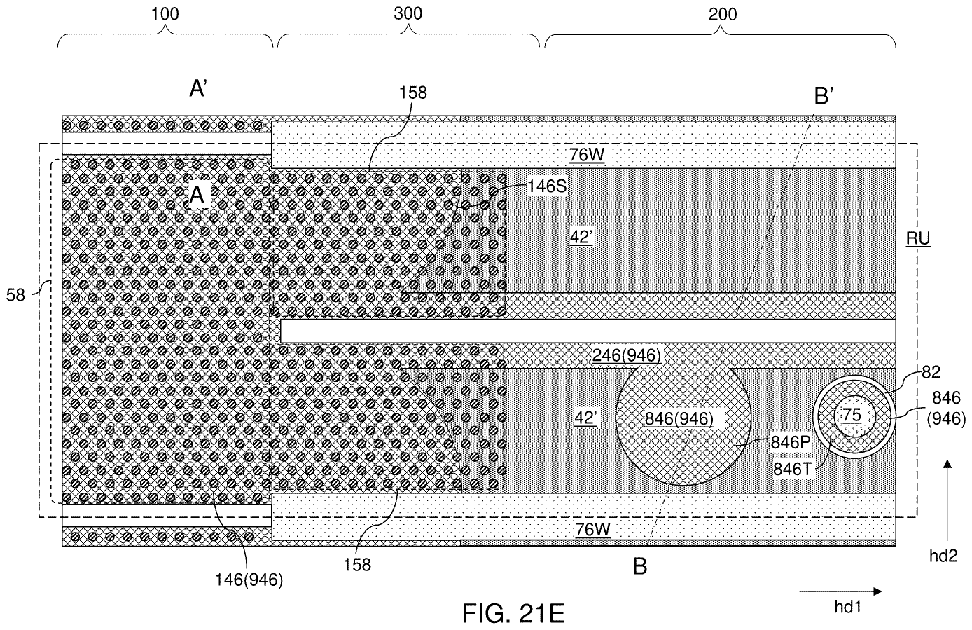

Referring to FIG. 21A-21E, a photoresist layer may be applied over the first exemplary structure, and may be lithographically patterned to form photoresist material portions 75 covering the areas of the contact via openings 85′. Unmasked portions of the continuous electrically conductive layer 46L can be isotropically etched to pattern the continuous electrically conductive layer 46L. Specifically, portions of the continuous electrically conductive layer 46L that are present in the narrow lateral isolation trench segments 79N, in the access lateral isolation trenches 179, or above the horizontal plane including the top surface of the insulating cap layer 70 and not covered by the photoresist material portions 75 can be removed during a selective etch process that etches materials of the continuous electrically conductive layer 46L selectively to the materials of the insulating layers 32, the insulating cap layer 70, and the semiconductor material layer 9.

The patterned portions of the continuous electrically conductive layer 46L comprise integrated word line and contact via structures 946. The integrated word line and contact via structures 946 are formed in the cavities (43, 143) that are formed by the first isotropic etch process and the second isotropic etch process. As shown in FIG. 21E, each of the integrated word line and contact via structures 946 comprises a respective horizontally-extending word line 146, a respective contact via structure 846, and a respective horizontally-extending lateral connection strip 246 connecting the respective horizontally-extending word line 146 and the respective contact via structure 846.

If the continuous backside blocking dielectric layer 44L is present, then it is separated into separate backside blocking dielectrics 44, as shown in the inset in FIG. 21B. Since the backside blocking dielectrics 44 are not removed at the intersections of the word lines 146, the connection strips 246 and the contact via structures 846, the chance of word line 146 breakdown is reduced.

As shown in FIG. 21B, the contact via structure 846 includes an annular vertically-extending tubular portion 846T and an underlying horizontally-extending bottom plate portion 846P which extends beyond the sidewall of the tubular portion 846T and contacts the lateral connection strip 246. The respective tubular portion 846T has a bottom end that is connected to the respective bottom plate 846P. In one embodiment, a center portion of the respective bottom plate 846P has a uniform inner bottom plate thickness; the respective tubular portion 846T has a uniform lateral thickness between an inner sidewall and an outer sidewall; and the uniform lateral thickness is the same as the uniform inner bottom plate thickness.

The insulating layers 32 are vertically spaced apart from each other and are interlaced with the horizontally-extending word lines 146 (and optionally with the backside blocking dielectrics 44) to provide a vertically alternating sequence (32, 146) of the insulating layers 32 and the horizontally-extending word lines 146. Each of the horizontally-extending word lines 146 laterally extend along a first horizontal direction hd1 and have a uniform word-line width along a second horizontal direction hd2 in a memory array region 100. The lateral connection strips 246 laterally extend along the first horizontal direction hd1 and have a uniform strip width along the second horizontal direction hd2 in a contact region 200. The uniform strip width is less than the uniform word line width. Drain side select gate electrodes may overlie the word lines 146 and source side select gate electrodes may underlies the word lines 146.

In one embodiment shown in FIGS. 21D and 21E, each of the horizontally-extending word lines 146 has a laterally-convex sidewall section 146S in a connection region 300 that is located between the memory array region 100 and the contact region 200. In one embodiment, each of the horizontally-extending word lines 146 has a variable width that changes from the uniform word-line width to the uniform strip width within the connection region 300 containing the laterally-convex sidewall sections 146S.

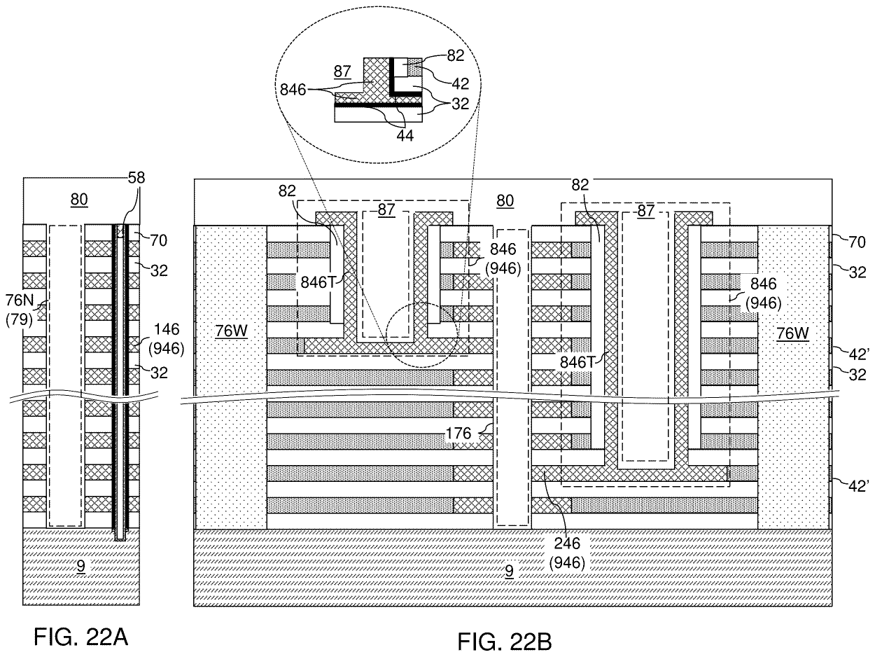

Referring to FIGS. 22A and 22B, a second dielectric fill material may be conformally deposited in the narrow lateral isolation trench segments 79N, in the access lateral isolation trenches 179, and over the insulating cap layer 70 to form a continuous dielectric material portion. The continuous dielectric material portion includes a contact-level dielectric layer 80 that is located above the insulating cap layer 79, lateral isolation trench fill structures (76N, 176) filling the lateral isolation trenches (79N, 179), and dielectric pillar material portions 87 that are laterally surrounded by the contact via structures 846. Each of the tubular portions 846T of the contact via structures 846 laterally encloses a respective dielectric pillar material portion 87.

In one embodiment, the contact-level dielectric layer 80 overlies the vertically alternating sequence (32, 146) and the tubular portions 846T of the contact via structures 846. The contact-level dielectric layer 80 and the dielectric pillar material portions 87 are portions of a dielectric material having a uniform material composition throughout. Additional portions of the dielectric material comprise lateral isolation trench fill structures (76N, 176) contacting sidewalls of each of the insulating layers 32 and each of the horizontally-extending word lines 146. The lateral isolation trench fill structures (76N, 176) comprise narrow lateral isolation trench fill structures 76N that are formed in the narrow lateral isolation trench segments 79N and lateral isolation trench fill material portion 176 that are formed in the access lateral isolation trenches 179. Thus, the continuous dielectric material portion having a uniform material composition throughout may comprise: a contact-level dielectric layer 80 overlying each of the vertically alternating sequences (32, 146); and narrow lateral isolation trench fill structures 76N which are vertically-extending portions that vertically extend downward from the contact-level dielectric layer 80 and filling at least the narrow lateral isolation trench segments 79N. In one embodiment, the lateral connection strips 246 of the integrated word line and contact via structures 846 are in direct contact with the vertically-extending portions of the continuous dielectric material portion.

In one embodiment, the wide lateral isolation trench fill structures 76W may comprise the same or a different dielectric material than the continuous dielectric material portion. In one embodiment, each access lateral isolation trench 179 is laterally spaced from the dual-width lateral isolation trenches 79. Access isolation trench fill structures 176 can fill the access lateral isolation trenches 179. The lateral connection strips 246 of the integrated word line and contact via structures 946 are in contact with a sidewall of a respective one of the access isolation trench fill structures 176.

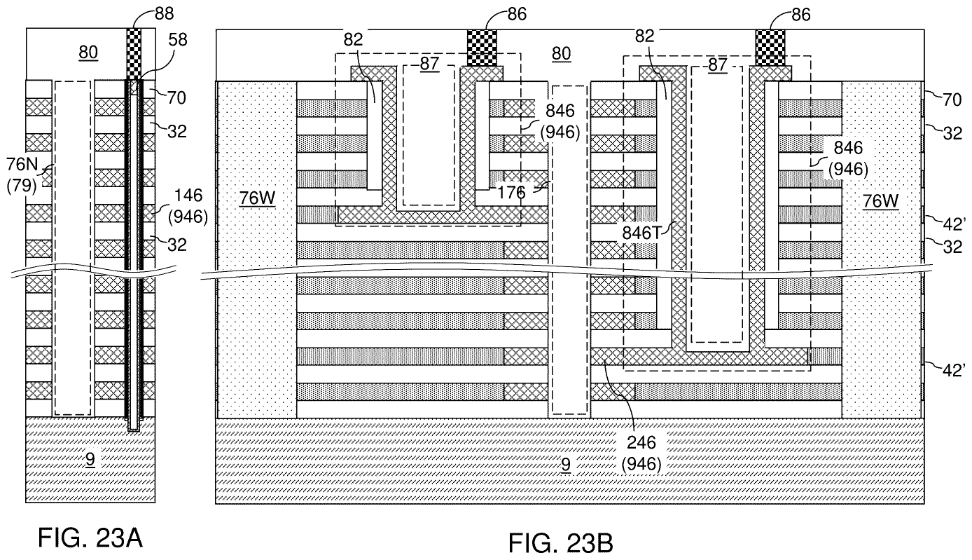

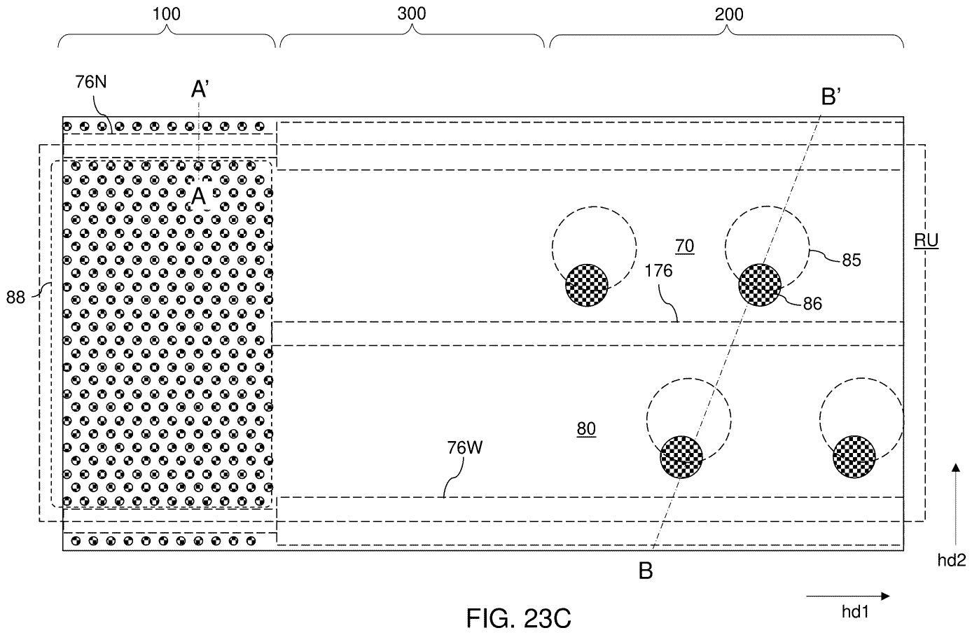

Referring to FIG. 23A-23C, various conductive via structures (88, 86) can be formed through the contact-level dielectric layer 80. For example, drain contact via structures 88 can be formed through the contact-level dielectric layer 80 on the drain regions 63 of the memory opening fill structures 58. Drain contact via structures preferably do not contact the dummy memory opening fill structures 158. Connection via structures 86 may be formed through the contact-level dielectric layer 80 on an annular top portion (e.g., the tubular portion 846T) of a respective one of the contact via structures 846 that overlies the horizontal plane including the top surface of the insulating cap layer 70.

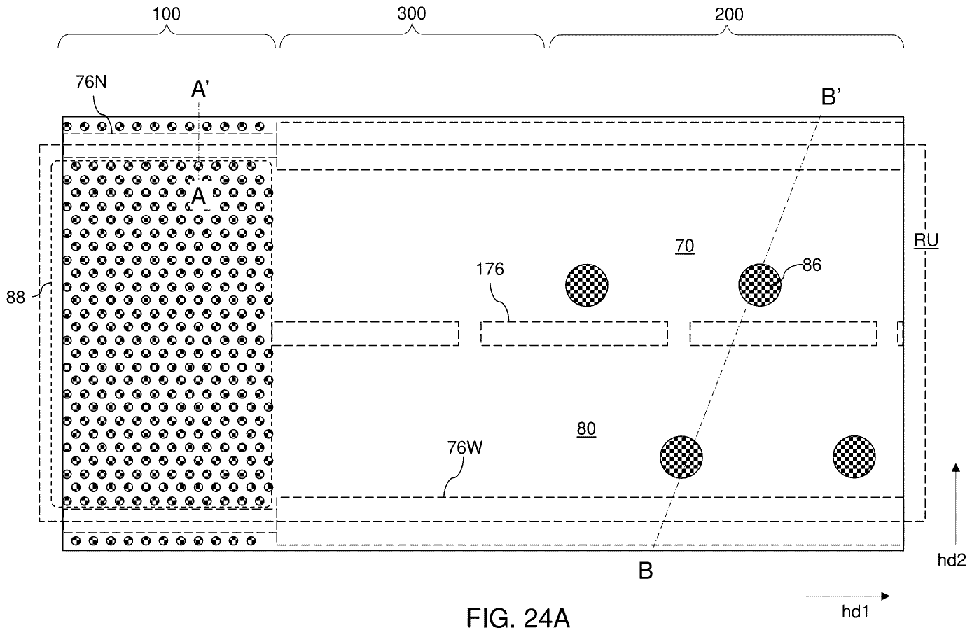

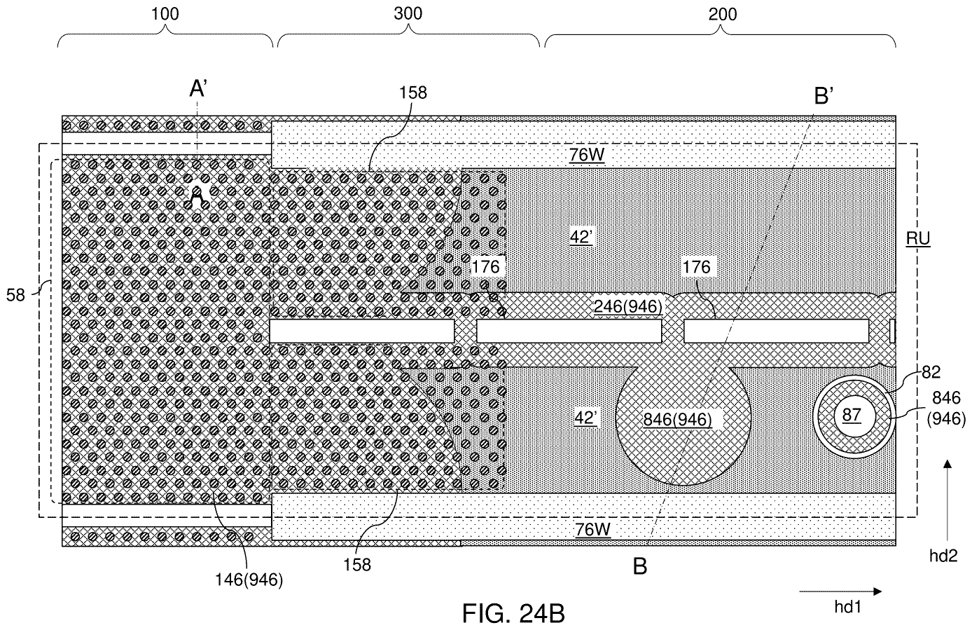

Referring to FIGS. 24A and 24B, an alternative configuration of the first exemplary structure is illustrated, which can be derived from the first exemplary structure by forming a plurality of access lateral isolation trenches 179 that are arranged along the first horizontal direction hd1 instead of each single continuous access lateral isolation trench 179 located between a respective neighboring pair of dual-width lateral isolation trenches 79. In this case, a row of lateral isolation trench fill material portion 176 may be formed between each neighboring pair of wide lateral isolation trench fill structures 76W.

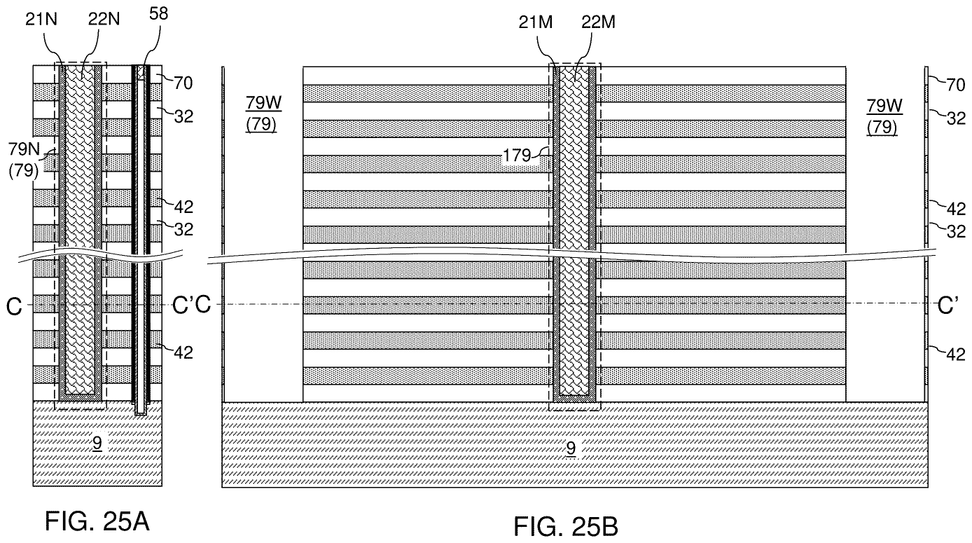

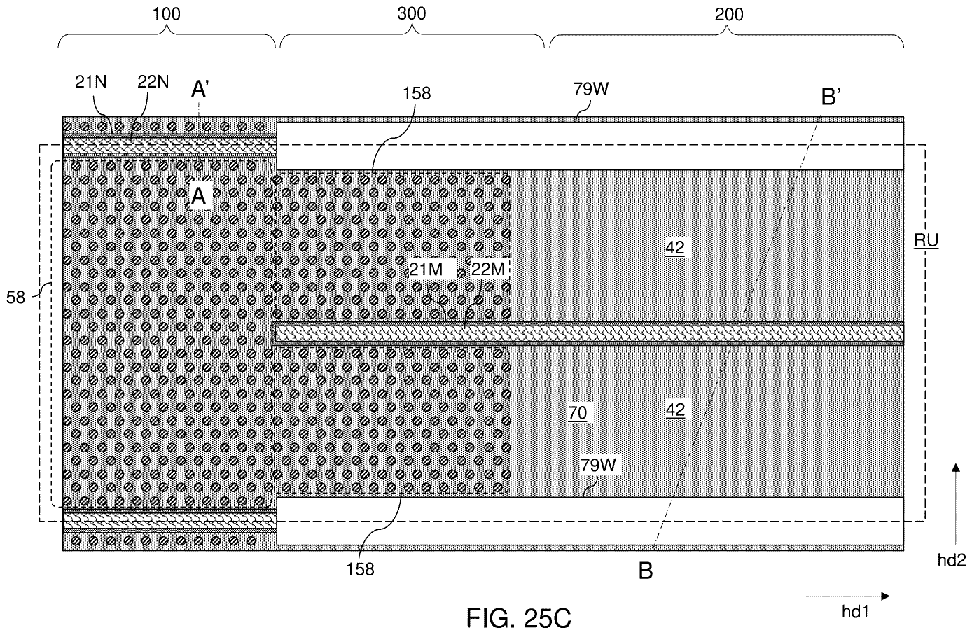

Referring to FIG. 25A-25C, a second exemplary structure according to a second embodiment of the present disclosure is illustrated, which may be the same as the first exemplary structure illustrated in FIGS. 7A and 7B.

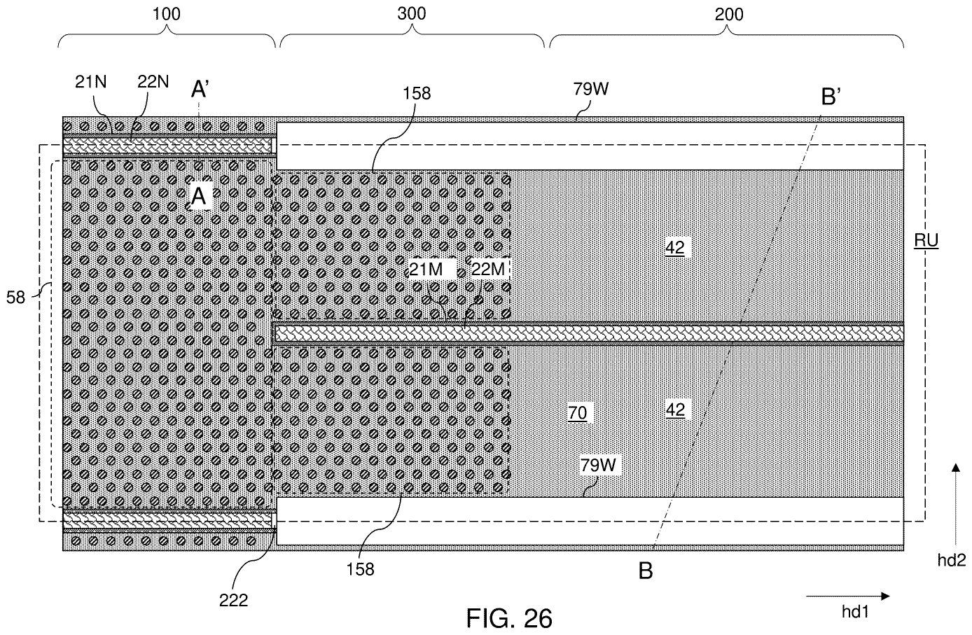

Referring to FIG. 26, an oxidation process may be performed to convert exposed surface portions (i.e., sidewalls) of the sacrificial narrow isolation trench fill structures 22N into sacrificial oxide liners 222. If the sacrificial narrow isolation trench fill structure 22N comprises amorphous silicon or polysilicon, then the sacrificial oxide liners 222 comprise silicon oxide liners that are formed by oxidation of the exposed sidewalls of the silicon structures 22N in the wide lateral isolation trench segments 79W.

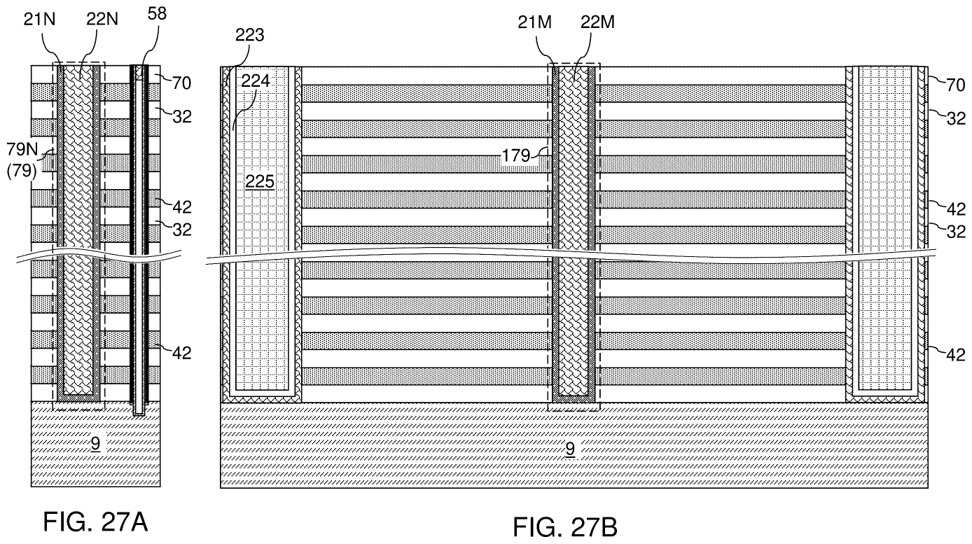

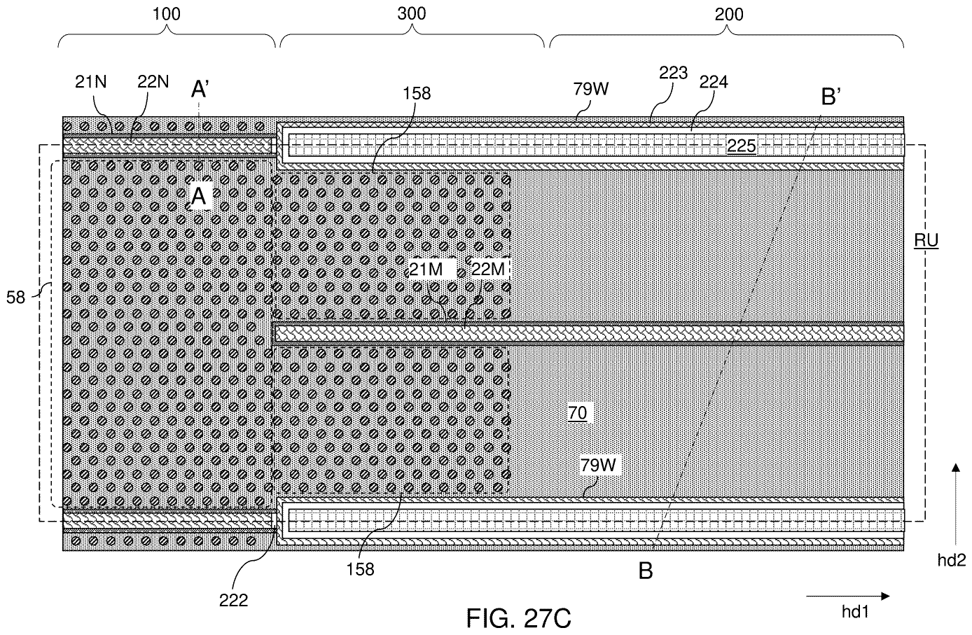

Referring to FIG. 27A-27C, a first sacrificial trench liner 223, a second sacrificial trench liner 224, and a wide sacrificial trench fill structure 225 may be formed within each wide lateral isolation trench segment 79W. For example, a first continuous sacrificial trench liner including a first sacrificial trench liner material (such as amorphous silicon or polysilicon), a second continuous sacrificial trench liner including a second sacrificial trench liner material (such as silicon nitride), and a sacrificial trench fill material (such as amorphous silicon or polysilicon) may be sequentially deposited to fill the entire volumes of the wide lateral isolation trench segments 79W, and portions of the first continuous sacrificial trench liner, the second continuous sacrificial trench liner, and the sacrificial trench fill material that overlie the horizontal plane including the top surface of the insulating cap layer 70 may be removed by performing a chemical mechanical polishing process. Top surfaces of the sacrificial narrow isolation trench fill structure 22N may be physically exposed after the chemical mechanical polishing process. Remaining portions of the first continuous sacrificial trench liner, the second continuous sacrificial trench liner, and the sacrificial trench fill material comprise the first sacrificial trench liners (e.g., silicon liners) 223, the second sacrificial trench liners (e.g., silicon nitride liners) 224, and the wide sacrificial trench fill structures (e.g., silicon structures) 225.

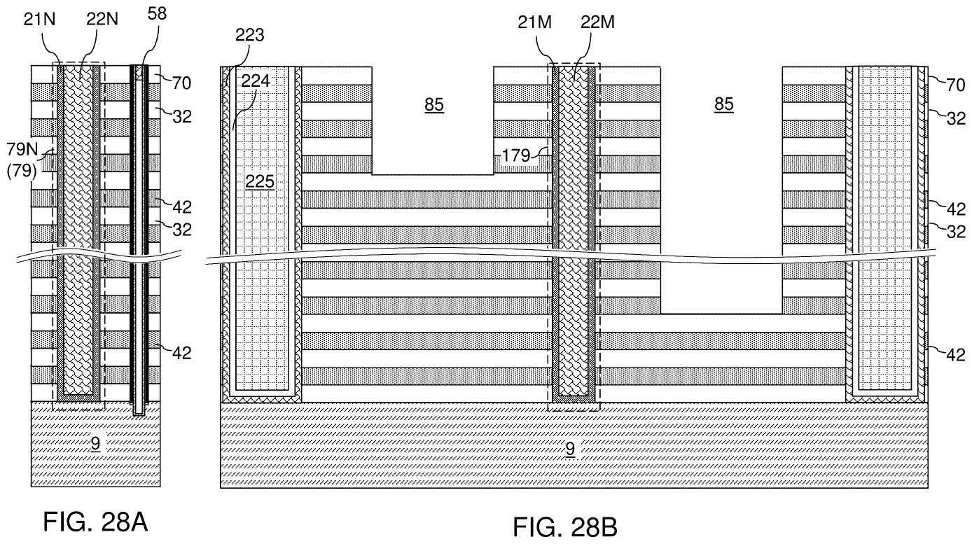

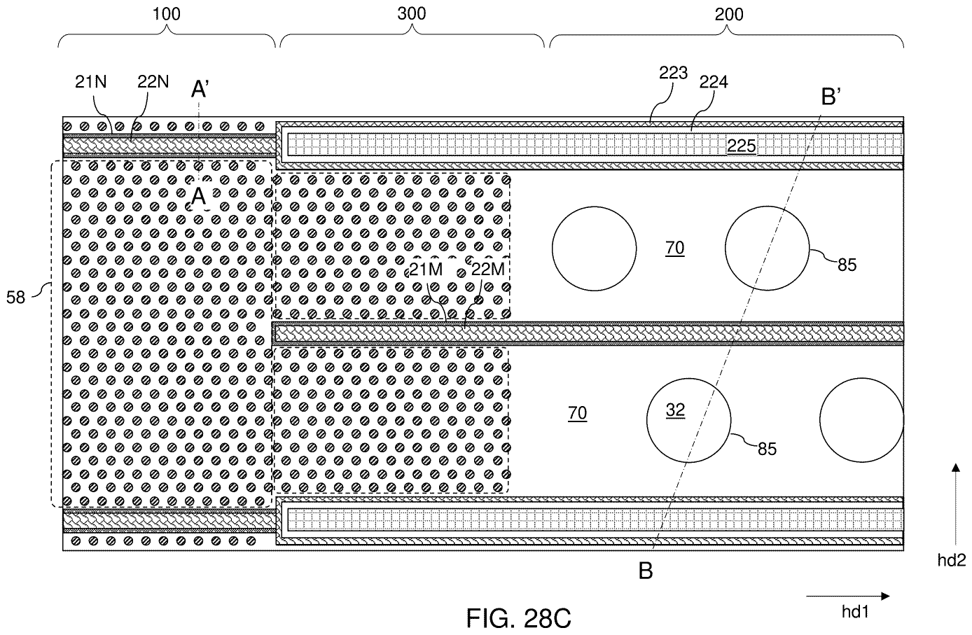

Referring to FIG. 28A-28C, the processing steps described with reference to FIG. 9A-9C can be performed to form the contact via openings 85.

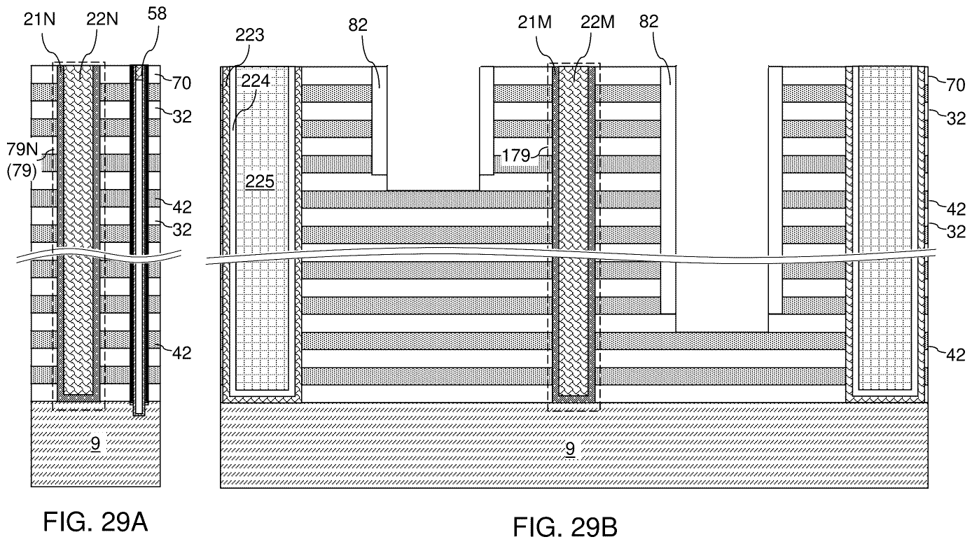

Referring to FIGS. 29A and 29B, the processing steps described with reference to FIGS. 10A and 10B can be performed to form tubular insulating spacers 82 and to vertically extend contact via cavities 85′.

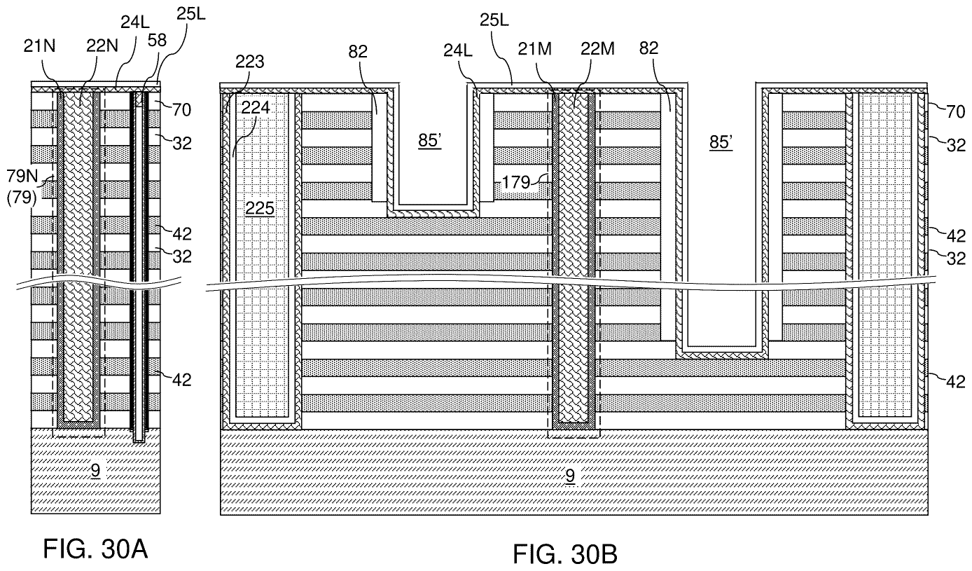

Referring to FIGS. 30A and 30B, the processing steps described with reference to FIGS. 12A, 12B, 13A, and 13B can be performed to form a sacrificial barrier liner 24L and a sacrificial dielectric liner 25L.

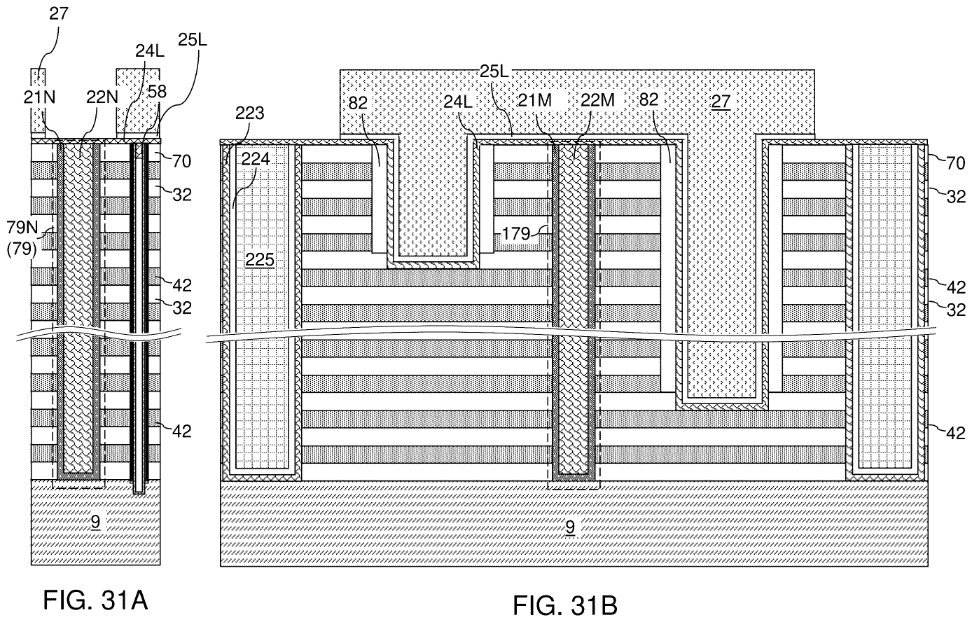

Referring to FIGS. 31A and 31B, the processing steps described with reference to FIGS. 14A and 14B can be performed with a modification in the pattern of the photoresist layer 27. Specifically, the photoresist layer 27 can be applied over the second exemplary structure, and can be lithographically patterned to form openings over the areas of the dual-width lateral isolation trenches 79 while covering areas outside of the dual-width lateral isolation trenches 79 in a plan view. A first etch process can be performed to remove unmasked portions of the sacrificial dielectric liner 25L selectively to the material of the sacrificial barrier liner 24L. Each portion of the sacrificial dielectric liner 25L overlying the dual-width lateral isolation trenches 79 may be removed, and surfaces of the sacrificial barrier liner 24L may be physically exposed within the areas of the dual-width lateral isolation trenches 79.

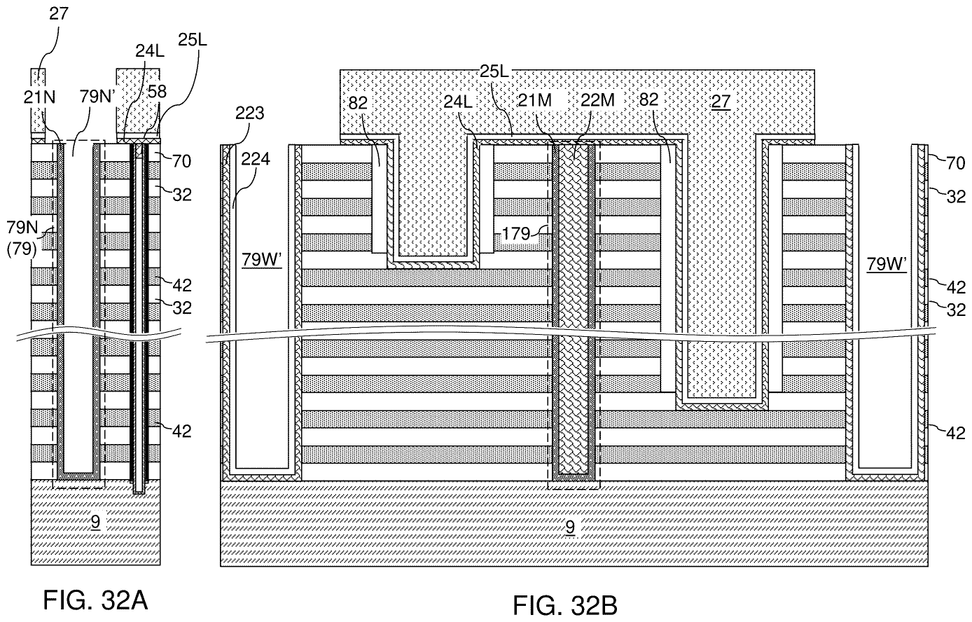

Referring to FIGS. 32A and 32B, a second etch process can be performed to remove unmasked portions of the sacrificial barrier liner 24L, the sacrificial narrow isolation trench fill structure 22N, and the wide sacrificial trench fill structure 225 selectively to the materials of the sacrificial narrow trench liners 21N and the second sacrificial trench liner 224. Surfaces of the sacrificial narrow trench liners 21N are physically exposed in the narrow lateral isolation trench segments 79N, and surfaces of the second sacrificial trench liners 224 are physically exposed in the wide lateral isolation trench segments 79W.

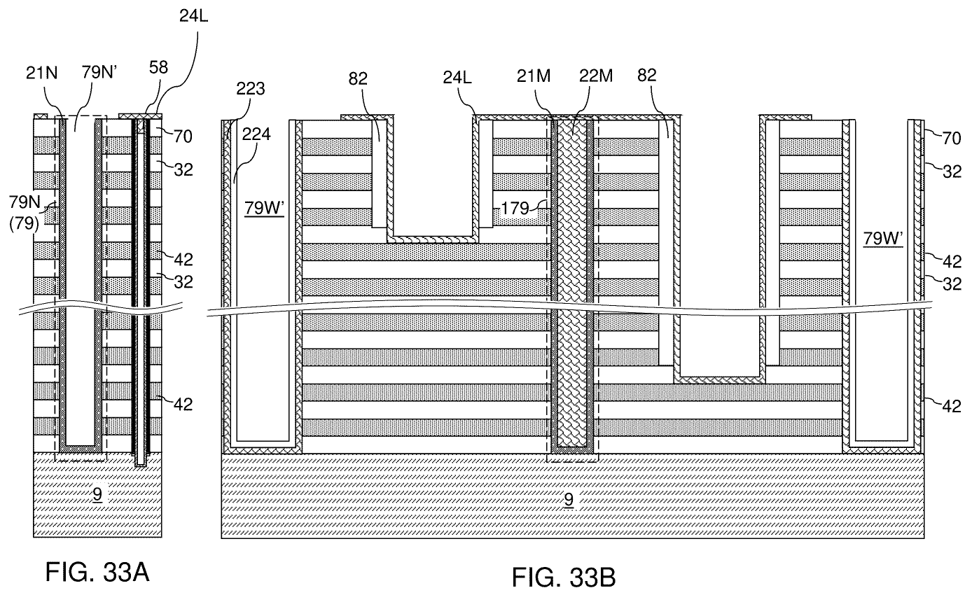

Referring to FIGS. 33A and 33B, the photoresist layer 27 can be subsequently removed, for example, by ashing. Remaining portions of the sacrificial dielectric liner 25L and sacrificial oxide liners 222 (e.g., the silicon oxide liners 25L and 222) may be removed by selective etching relative to the sacrificial narrow trench liners 21N and the second sacrificial trench liners 224 (e.g., the silicon nitride liners 21N and 224).

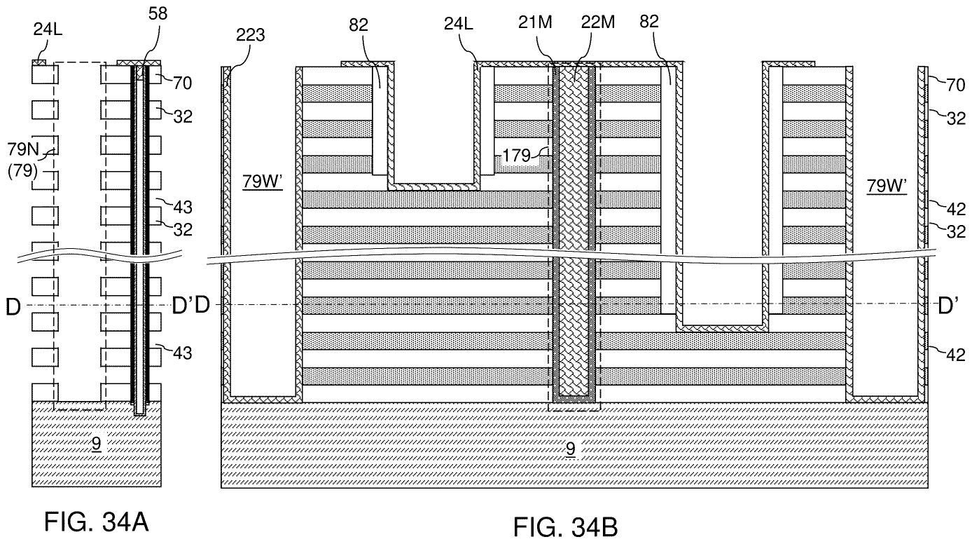

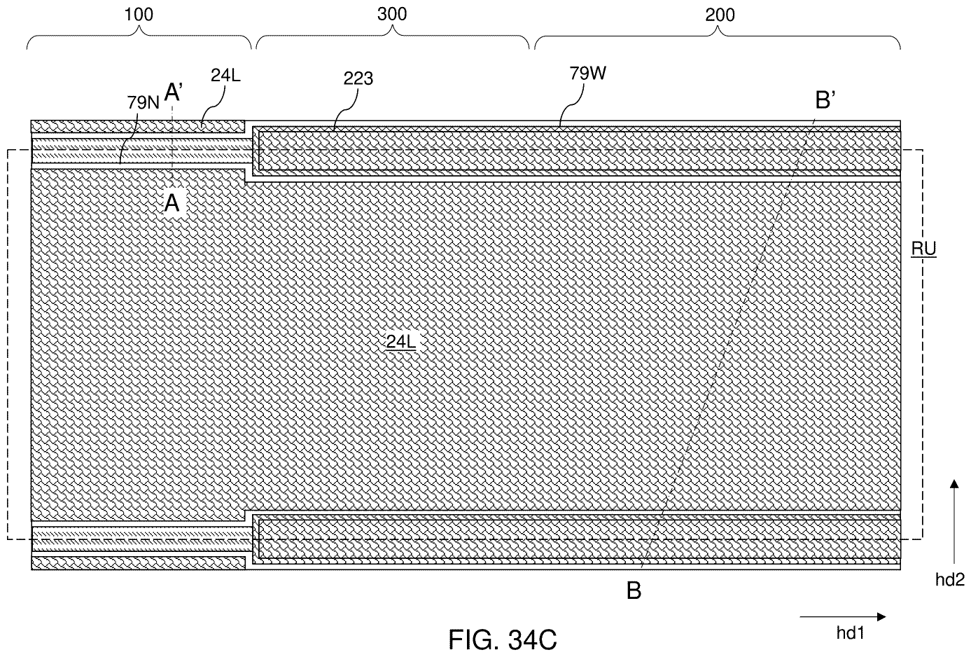

Referring to FIG. 34A-34D, the processing steps described with reference to FIG. 17A-17D can be performed. Specifically, a first selective isotropic etch process can be performed, which etches the materials of the sacrificial narrow trench liners 21N, the second sacrificial trench liners 224 and the sacrificial material layers 42. In one embodiment, the sacrificial narrower trench liners 21N, the second sacrificial trench liners 224 and the sacrificial material layers 42 may comprise the same material, such as silicon nitride. The first selective isotropic etch process removes the entirety of the sacrificial narrow trench liners 21N and the second sacrificial trench liners 224, laterally recesses physically exposed portions of the sacrificial material layers 42 by a first etch distance, and etches portions of the sacrificial access lateral isolation trench liners 21M. The first sacrificial trench liners (e.g., silicon liners) 223 remain in the wide lateral isolation trench segments 79W′.

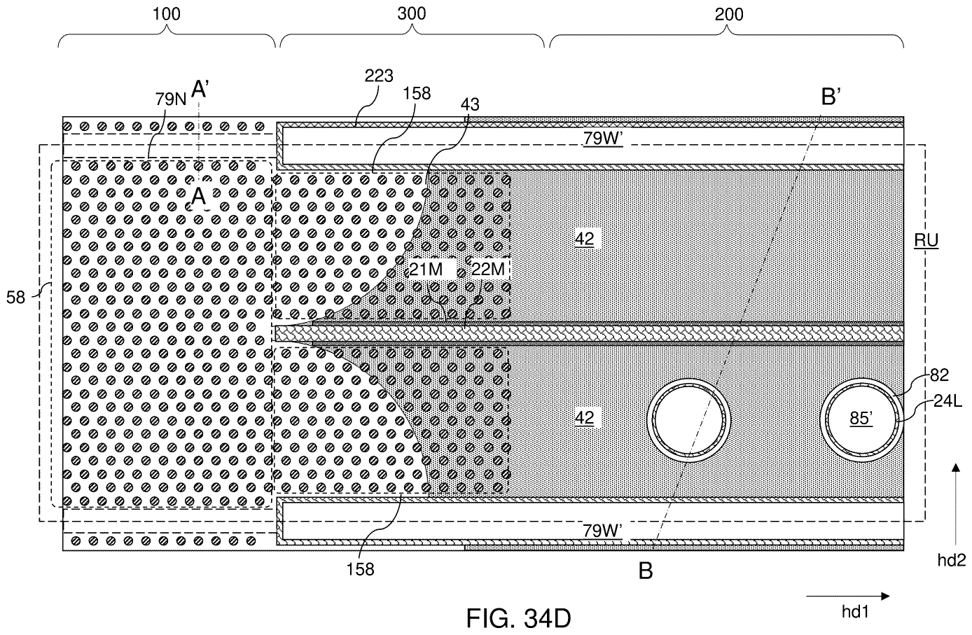

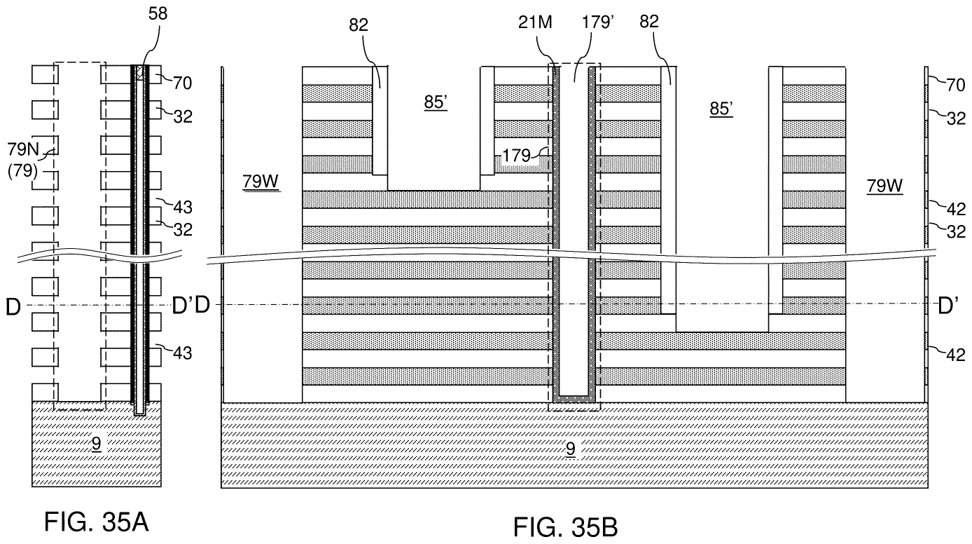

Referring to FIGS. 35A and 35B, an isotropic etch process can be performed to etch the sacrificial barrier liner 24L, the first sacrificial trench liners 223 and the sacrificial access lateral isolation trench fill structures 22M (i.e., the silicon liners and structures 24L, 223 and 22M) selectively to the materials of the sacrificial access lateral isolation trench liners 21M, the insulating layers 32, and the sacrificial material layers 42. Sidewalls of the sacrificial access lateral isolation trench liners 21M can be physically exposed around the wall-shaped voids within the access lateral isolation trenches 179. Further, top surface segments of the sacrificial material layers 42 may be exposed underneath the contact via cavities 85′.

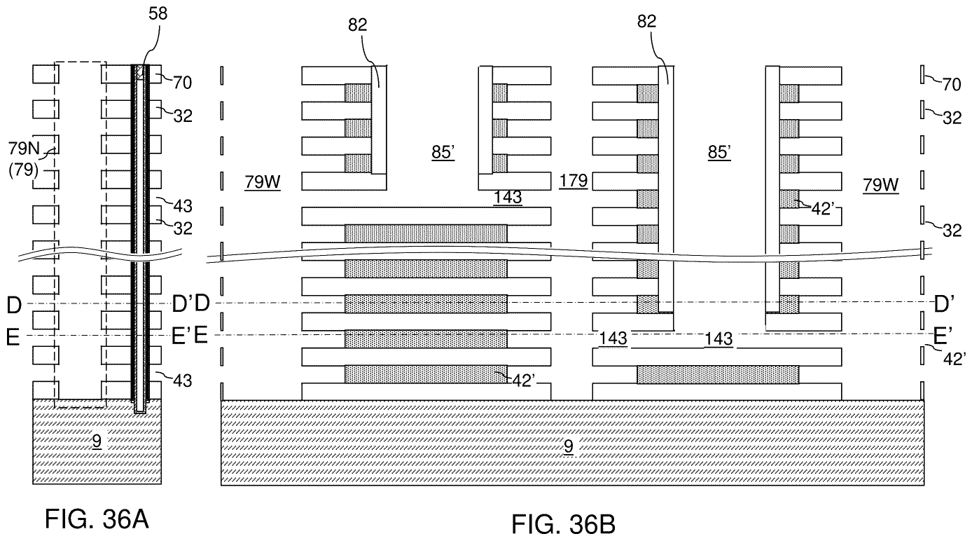

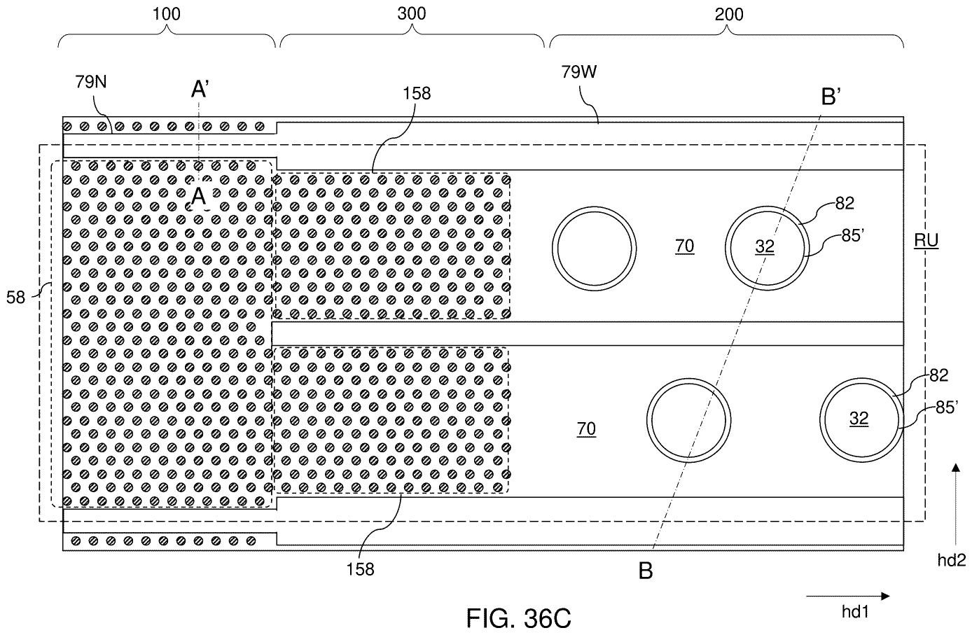

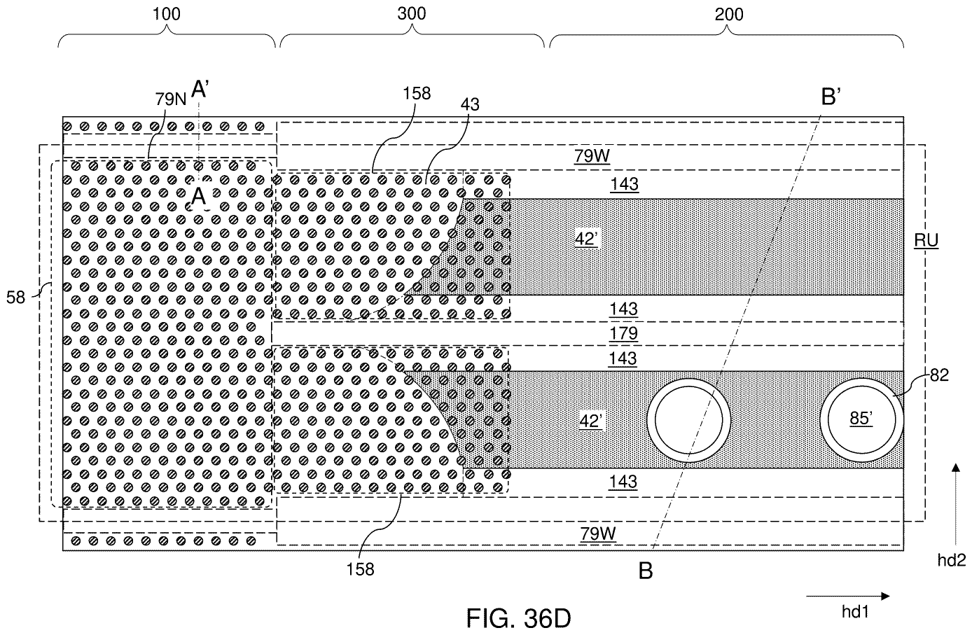

Referring to FIG. 36A-36E, a second selective isotropic etch process can be performed, which etches the materials of the sacrificial access lateral isolation trench liners 21M and the sacrificial material layers 42. The second selective isotropic etch process removes the entirety of the sacrificial access lateral isolation trench liners 21M, and laterally recesses physically exposed portions of the sacrificial material layers 42 by a second etch distance, which is less than the first etch distance. The second selective isotropic etch process etches portions of the sacrificial material layers 42 that are proximal to the wide lateral isolation trench segments 79W and further recesses the concave sidewalls of the sacrificial material layers 42 that are located in the connection region 300. Further, the second selective isotropic etch process etches portions of the sacrificial material layers 42 that are proximal to the contact via cavities 85′. Thus, the second selective isotropic etch process employs the dual-width lateral isolation trenches 79, the access lateral isolation trenches 179, and the contact via cavities 85′ as conduits for an isotropic etchant that etches the materials of the sacrificial access lateral isolation trench liners 21M and the sacrificial material layers 42. The lateral recessing of the portions of the sacrificial material layers 42 from underneath the contact via cavities 85′ is isotropic. The duration of the second selective isotropic etch process is selected such that each of the cavities formed by removal of portions of the sacrificial material layers 42 from underneath the contact via cavities 85′ merges with a respective cavity that is formed by removal of a strip portion of a sacrificial material layer 42 around an access lateral isolation trench 179.

In the second embodiment, the sacrificial material layers 42 are isotropically recessed from around the dual-width lateral isolation trenches 79, the access lateral isolation trenches 179, and the contact via cavities 85′ by the second lateral etch distance selectively to the materials of the insulating layers 32, the insulating cap layer 70, the tubular insulating spacers 82, the semiconductor material layer 9, and the material of the outermost layers of the memory films 50. Further, the laterally-extending cavities 43 can be laterally expanded during the second selective isotropic etch process. Connection cavities 143 are formed in volumes from which the sacrificial material layers 42 are removed around the access lateral isolation trenches 179 and the contact via cavities 85′. The second lateral etch distance is less than the lateral spacing between neighboring pairs of a respective access lateral isolation trench 179 and a wide lateral isolation trench segment 79W along the second horizontal direction hd2. Remaining portions of the sacrificial material layers 42 comprise dielectric material plates 42′.

The second selective isotropic etch process may comprise a wet etch process employing a wet etch solution, and/or may comprise a gas phase (dry) etch process in which the etchant is introduced in a vapor phase into the narrow lateral isolation trench segments 79N, the wide lateral isolation trench segment 79W and the access lateral isolation trench 179. For example, if the sacrificial material layers 42 include silicon nitride, the etch process can be a wet etch process in which the second exemplary structure is immersed within a wet etch tank including phosphoric acid, which etches silicon nitride selective to silicon oxide, silicon, and various other materials employed in the art. The memory opening fill structures 58 provide structural support while the laterally-extending cavities 43 are present within volumes previously occupied by the sacrificial material layers 42. The dielectric material plates 42′ provide structural support to remaining portions of the insulating layers 32 in the contact region 200.

Each laterally-extending cavity 43 may be adjoined to a respective pair of connection cavities 143, as shown in FIGS. 36D and 36E. The second isotropic etch process isotropically recesses the sacrificial material layers 42 employing the dual-width lateral isolation trenches 79, the access lateral isolation trenches 179 and the contact via cavities 85′ as second conduits for a second isotropic etchant.

As shown in FIG. 36E, each of the connection cavities 143 may comprise a pair of strip cavity portions laterally extending along the first horizontal direction hd1 and having a respective uniform strip width along the second horizontal direction hd2 in the contact region 200. The uniform strip widths are less than the uniform word line width. Further, each of the connection cavities 143 may comprise a disc-shaped cavity portion that underlies a respective contact via cavity 85′ and is adjoined to the strip cavity portions. A vertical stack of dielectric material plates 42′ may be vertically interlaced with the insulating layers 32.

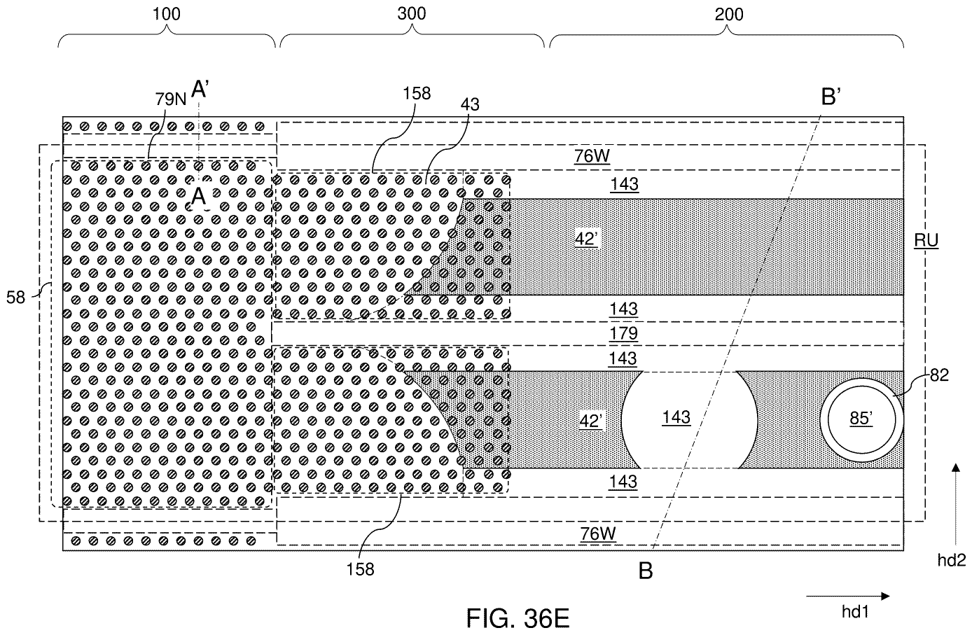

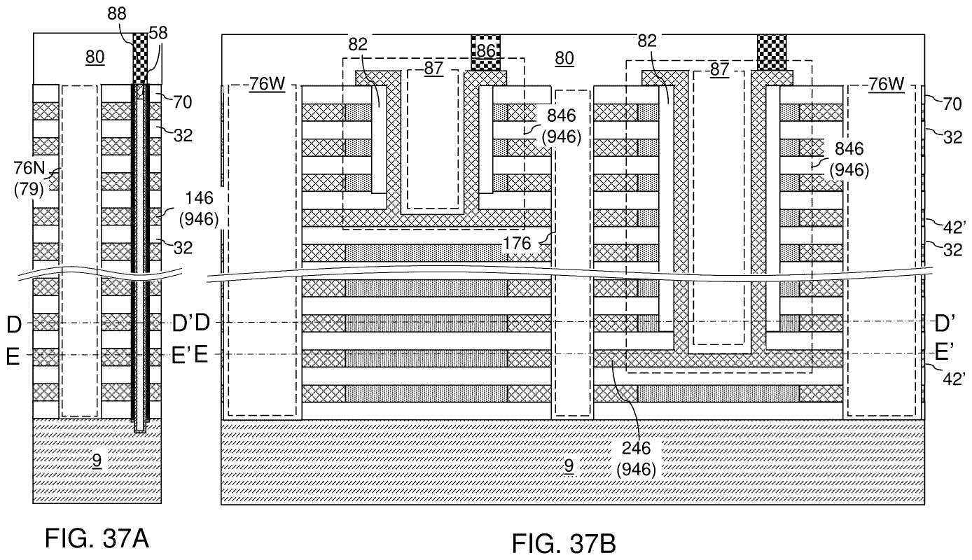

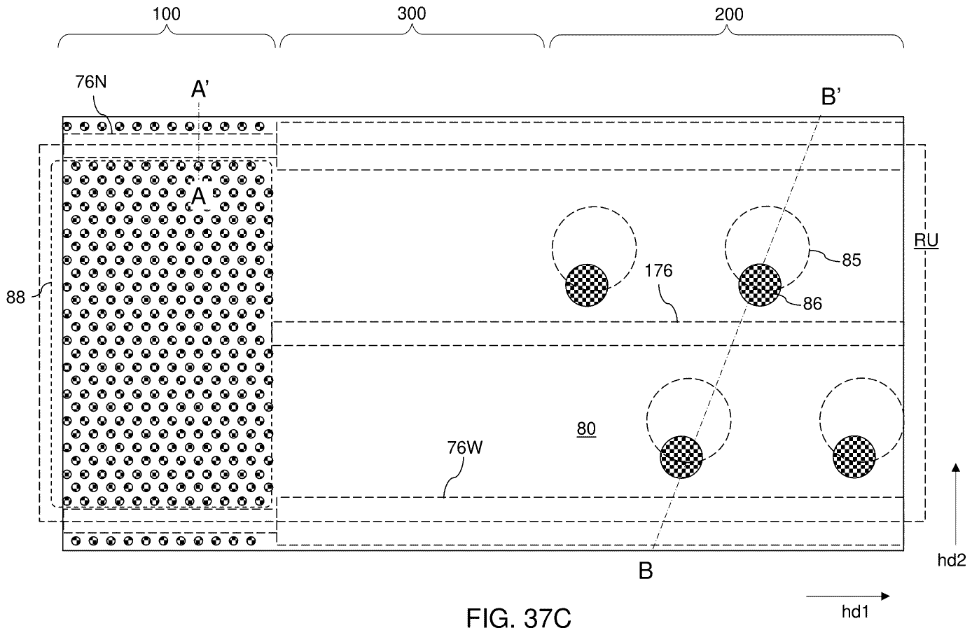

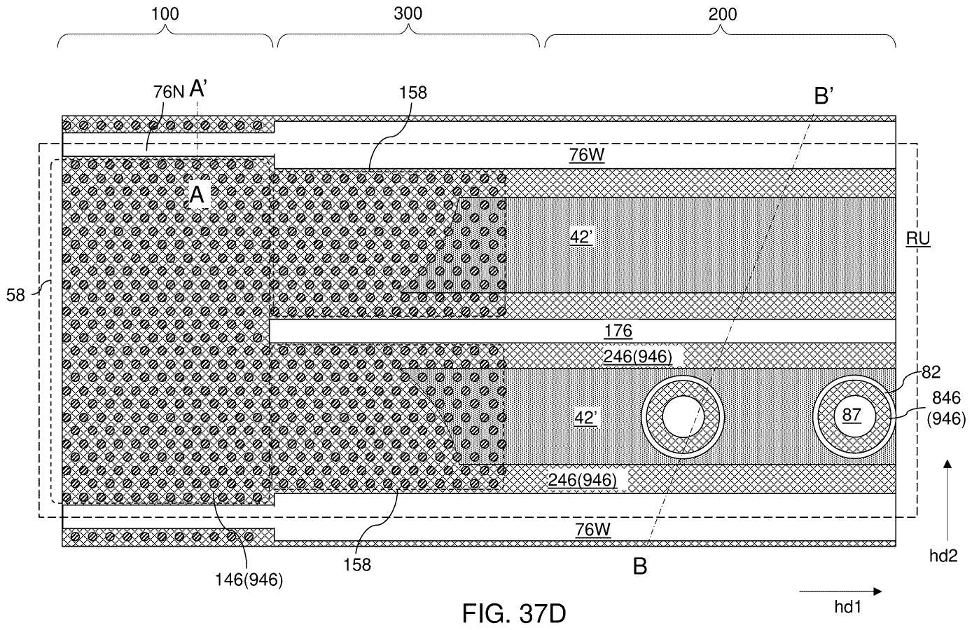

Referring to FIG. 37A-37E, the processing steps described with reference to FIG. 20A-23C can be performed to form integrated word line and contact via structures 946, a contiguous dielectric material portion (80, 76N, 76W, 87), and conductive via structures (88, 86). The integrated word line and contact via structures 946 are formed in the cavities (43, 143) that are formed by the first isotropic etch process and the second isotropic etch process. Each of the integrated word line and contact via structures 946 comprises a respective horizontally-extending word line 146, a respective contact via structure 846, and a respective pair of lateral connection strips 246 connecting the respective horizontally-extending word line 146 and the respective contact via structure 846.

The contiguous dielectric material portion (80, 76N, 76W, 87) comprises a dielectric fill material that is conformally deposited in the narrow lateral isolation trench segments 79N, in the wide lateral isolation trench segments 79W, in the access lateral isolation trenches 179, and over the insulating cap layer 70 to form a continuous dielectric material portion. The continuous dielectric material portion includes a contact-level dielectric layer 80 that is located above the insulating cap layer 79, lateral isolation trench fill structures (76N, 76W, 176) filling the lateral isolation trenches (79, 179), and dielectric pillar material portions 87 that are laterally surrounded by the contact via structures 846. Each of the tubular portions of the contact via structures 846 laterally encloses a respective dielectric pillar material portion 87.

In one embodiment, the contact-level dielectric layer 80 overlies the vertically alternating sequence (32, 146) and the tubular portions of the contact via structures 86. The contact-level dielectric layer 80 and the dielectric pillar material portions 87 are portions of a dielectric material having a uniform material composition throughout. Additional portions of the dielectric material comprise lateral isolation trench fill structures (76N, 76W, 176) contacting sidewalls of each of the insulating layers 32 and each of the horizontally-extending word lines 146. The lateral isolation trench fill structures (76N, 76W, 176) comprise narrow lateral isolation trench fill structures 76N that are formed in the narrow lateral isolation trench segments 79N, wide lateral isolation trench fill structures 76W that are formed in the wide lateral isolation trench segments 79W, and lateral isolation trench fill material portion 176 that are formed in the access lateral isolation trenches 179.

In one embodiment, the lateral connection strips 246 of the integrated word line and contact via structures 946 are in direct contact with a vertically-extending portion (such as a wide lateral isolation trench fill structures 76W or an access lateral isolation trench fill structure 176) of the continuous dielectric material portion (80, 76N, 76W, 87).

In one embodiment, each access lateral isolation trench that 179 is laterally spaced from the dual-width lateral isolation trenches 79. Access isolation trench fill structures 176 can fill the access lateral isolation trenches 179. The lateral connection strips 246 of the integrated word line and contact via structures 946 are in contact with a sidewall of a respective one of the access isolation trench fill structures 176. In one embodiment, the lateral connection strips 246 of the integrated word line and contact via structures 946 are in contact with a sidewall of the vertically-extending portion (such as a of the continuous dielectric material portion (80, 76N, 76W, 87)).

The various conductive via structures (88, 86) can be formed through the contact-level dielectric layer 80. For example, drain contact via structures 88 can be formed through the contact-level dielectric layer 80 on the drain regions 63. Connection via structures 86 may be formed through the contact-level dielectric layer 80 on an annular top portion of a respective one of the contact via structures 846 that overlies the horizontal plane including the top surface of the insulating cap layer 70.

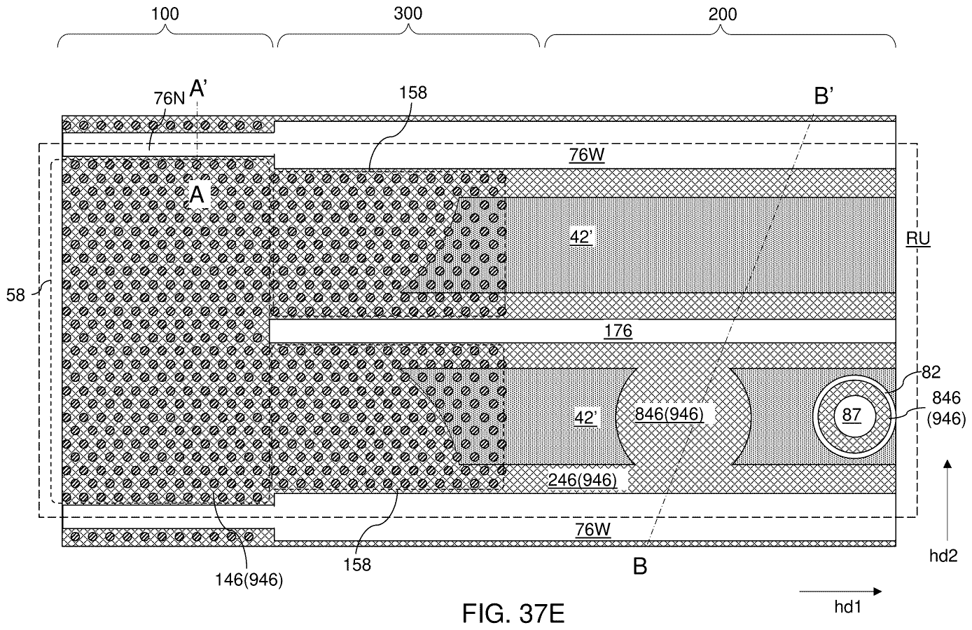

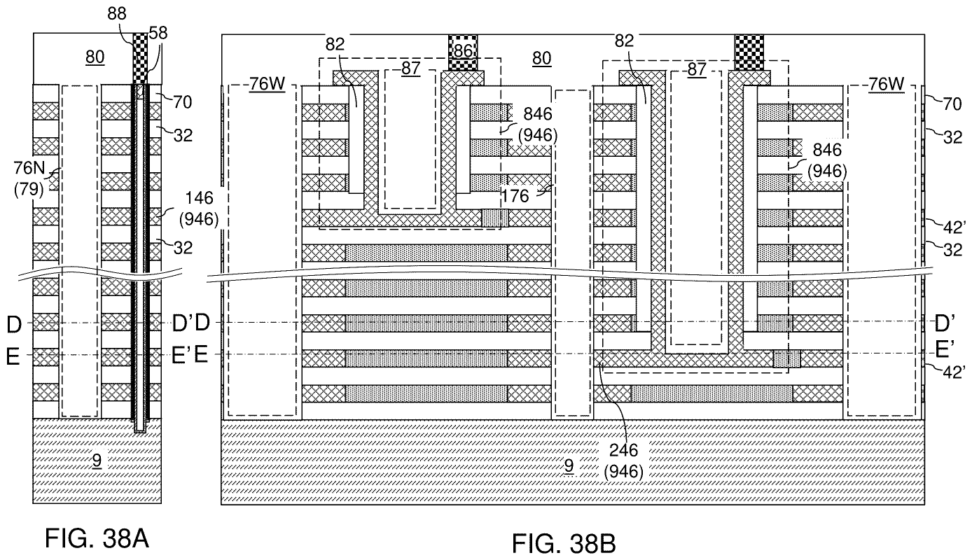

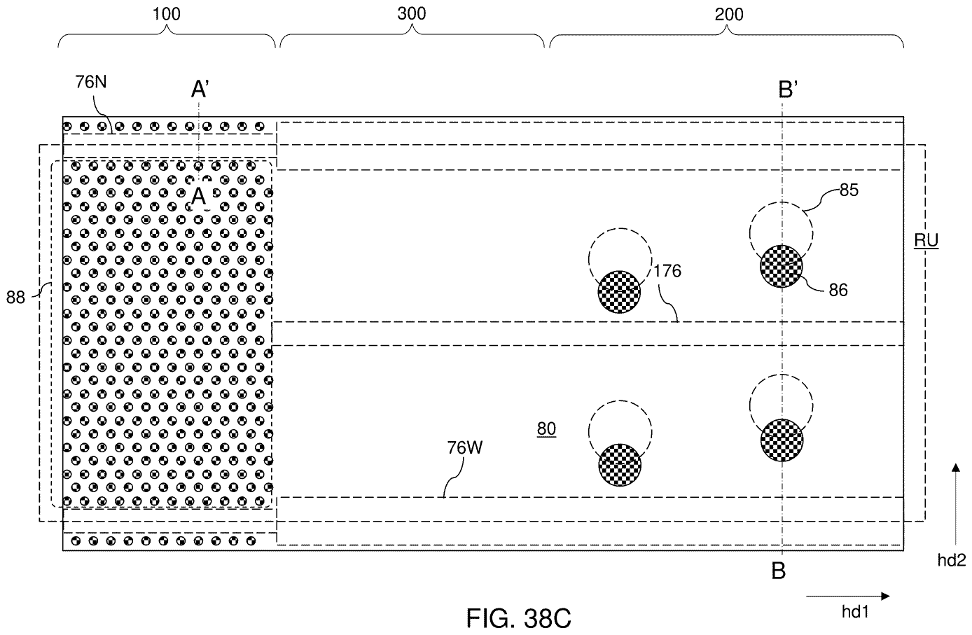

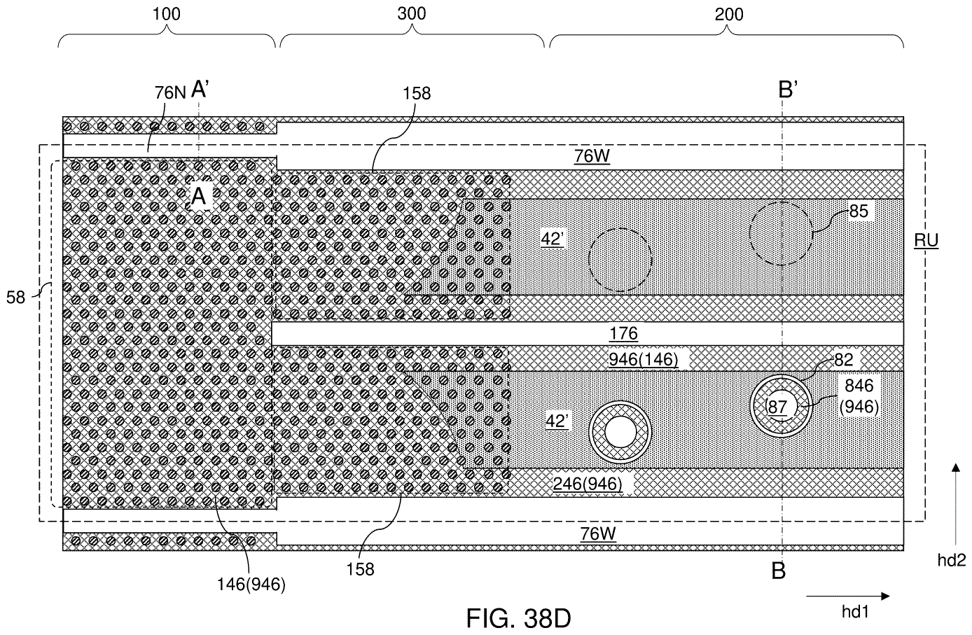

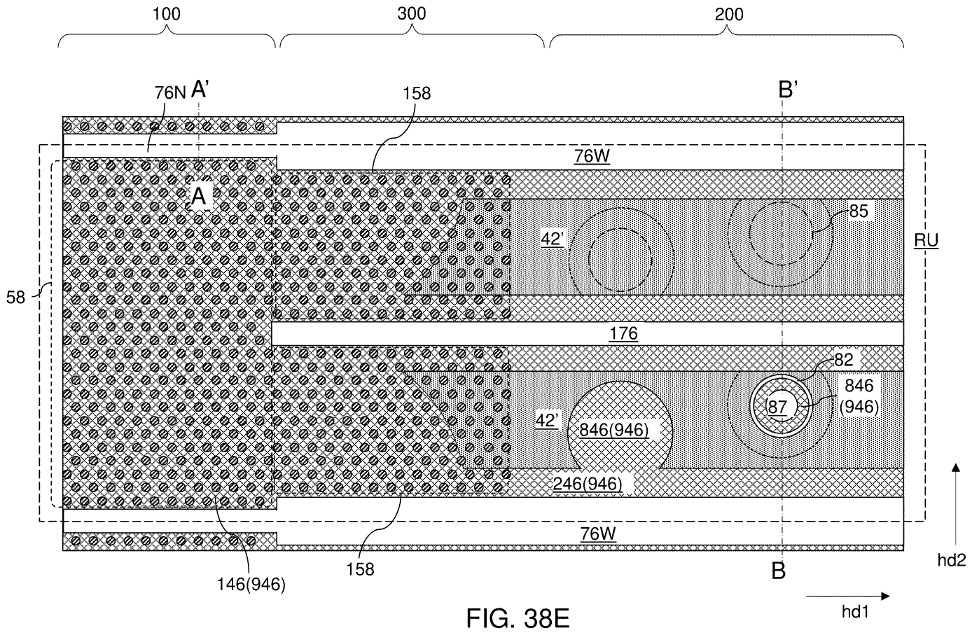

Referring to FIG. 38A-38E, a first alternative configuration of the second exemplary structure can be derived from the second exemplary structure described above by staggering the contact via openings 85 along the second horizontal direction hd2 such that each contact via structure 846 is in direct contact with only one lateral connection strip 246, as shown in FIG. 38E.

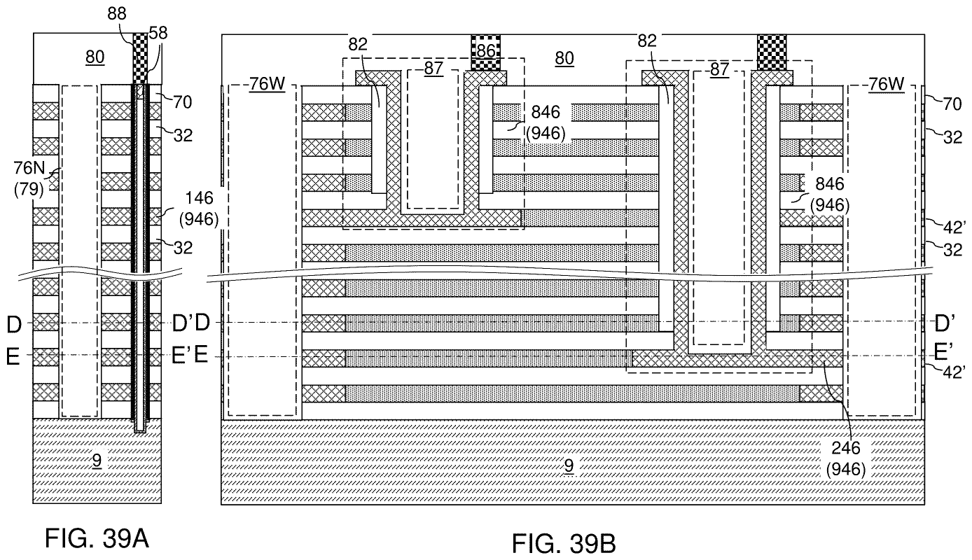

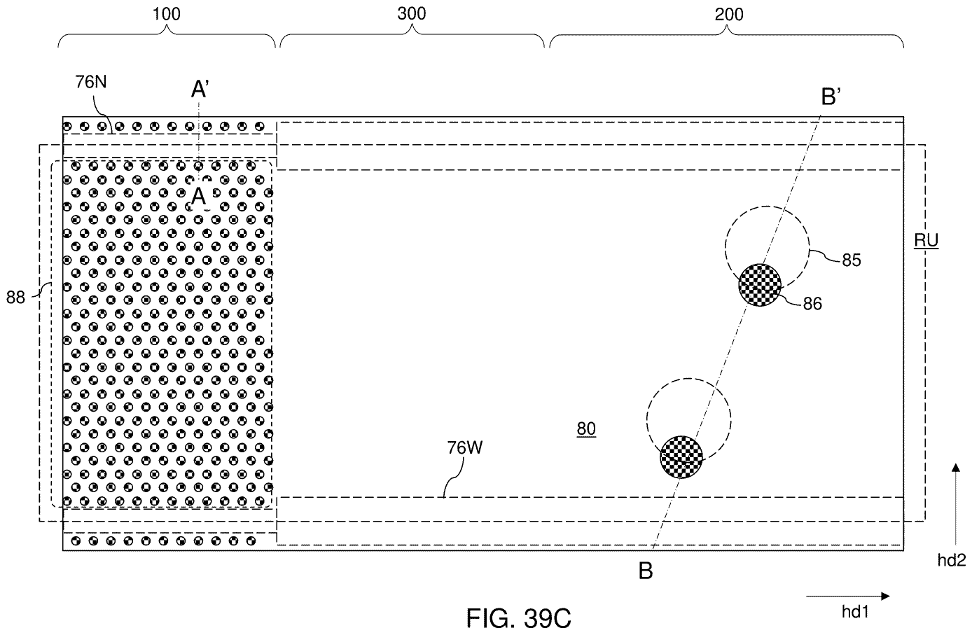

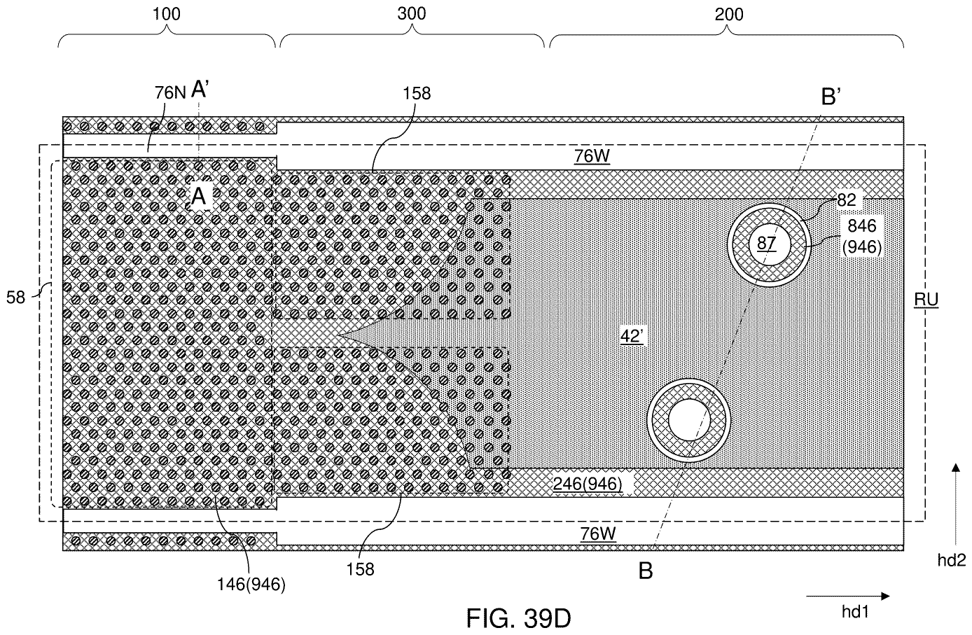

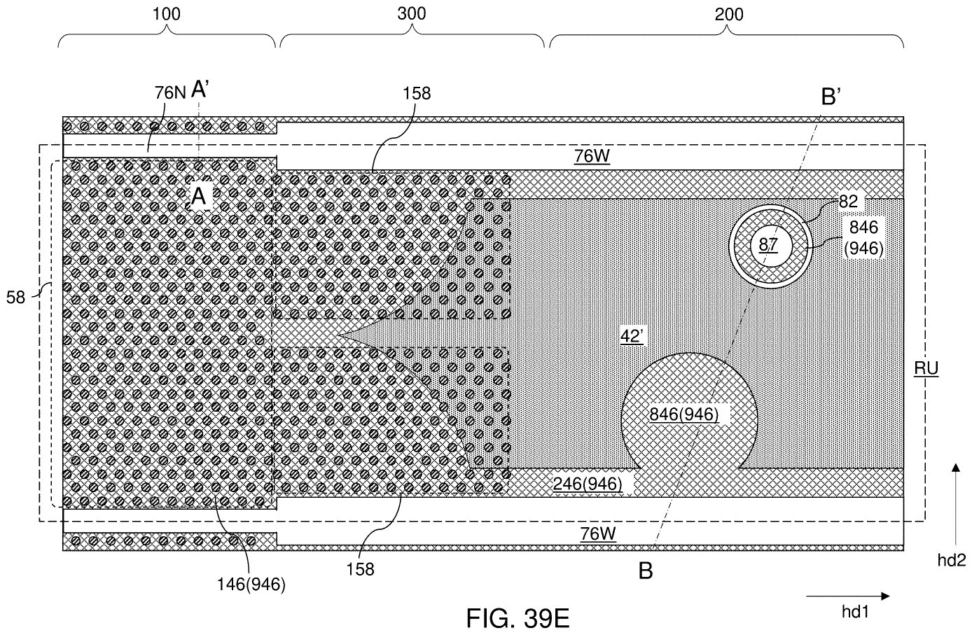

Referring to FIG. 39A-39E, a second alternative configuration of the second exemplary structure can be derived from the second exemplary structure by omitting formation of the access lateral isolation trenches 179. As a consequence, all structural components that are formed in the access lateral isolation trenches 179 in the second exemplary structure are absent in the second alternative configuration of the second exemplary structure. Further, each contact via structure 846 is in direct contact with only one lateral connection strip 246 that contacts a respective wide lateral isolation trench fill structure 76W.

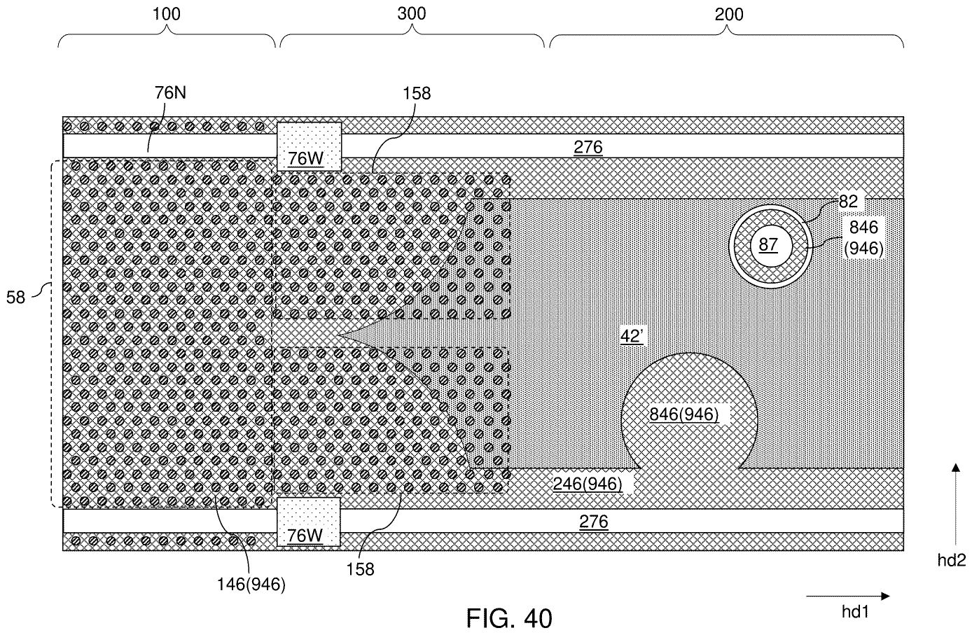

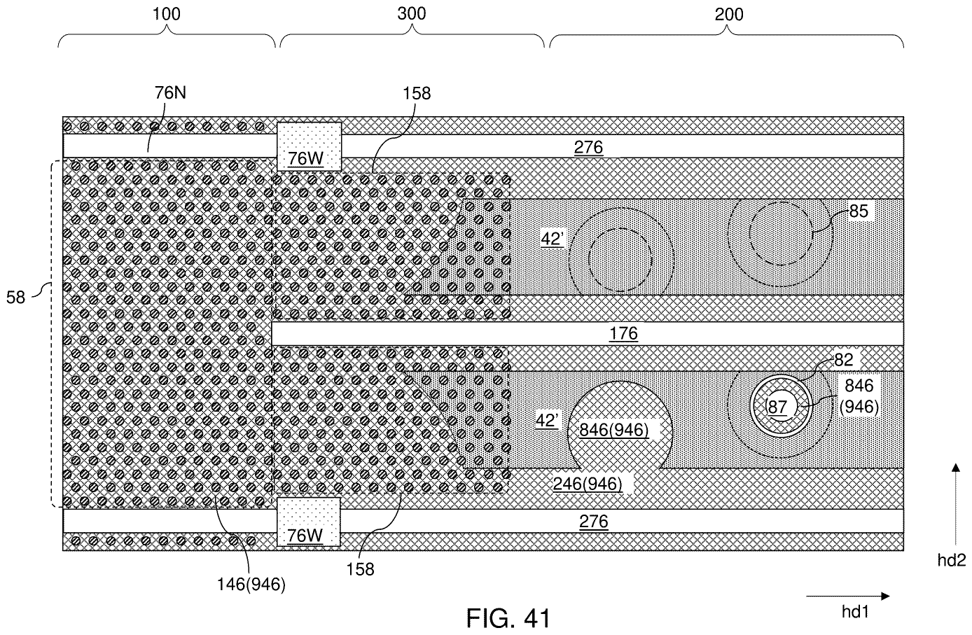

FIGS. 40, 41 and 42 are horizontal cross-sectional views of third, fourth and fifth alternative configurations of the second exemplary structure according to the second embodiment of the present disclosure. FIGS. 40, 41 and 42 are derived from FIGS. 39E, 38E and 37E, respectively. In the alternative configurations of FIGS. 40, 41 and 42, the wide lateral isolation trench fill structures 76W are formed separately from the narrow lateral isolation trench fill structures 76N as described above with respect to FIGS. 7A to 21E of the first embodiment. The wide lateral isolation trench fill structures 76W may be located in the connection region 300 and/or in the contact region 200. One or more of the wide lateral isolation trench fill structures 76W may be located at each boundary between adjacent memory blocks (e.g., repeating units RU).

In the alternative configurations of FIGS. 40, 41 and 42, the narrow lateral isolation trench segments 79N may be formed on two sides along the first horizontal direction hd1 (e.g., word line direction) of the wide lateral isolation trench segment 79W that is filled with wide lateral isolation trench fill structure 76W. The narrow lateral isolation trench segments 79N in the memory array region 100 are filled with the narrow lateral isolation trench fill structures 76N, while the narrow lateral isolation trench segments 79N in the connection region 300 and/or the contact region 200 are filled with the additional lateral isolation trench fill structures 276. The narrow lateral isolation trench fill structures 76N and the additional lateral isolation trench fill structures 276 are formed at the same time.

The narrow lateral isolation trench fill structures 76N and the additional lateral isolation trench fill structures 276 may have the same width as each other or a different width from each other along the second horizontal direction (e.g., bit line direction) hd2. The narrow lateral isolation trench fill structures 76N and the additional lateral isolation trench fill structures 276 have a different (e.g., smaller) width along the second horizontal direction than the wide lateral isolation trench fill structures 76W. The narrow lateral isolation trench fill structure 76N contacts a first end of the wide lateral isolation trench fill structures 76W and the additional lateral isolation trench fill structure 276 contacts an opposing second end of the wide lateral isolation trench fill structures 76W along the first horizontal direction.

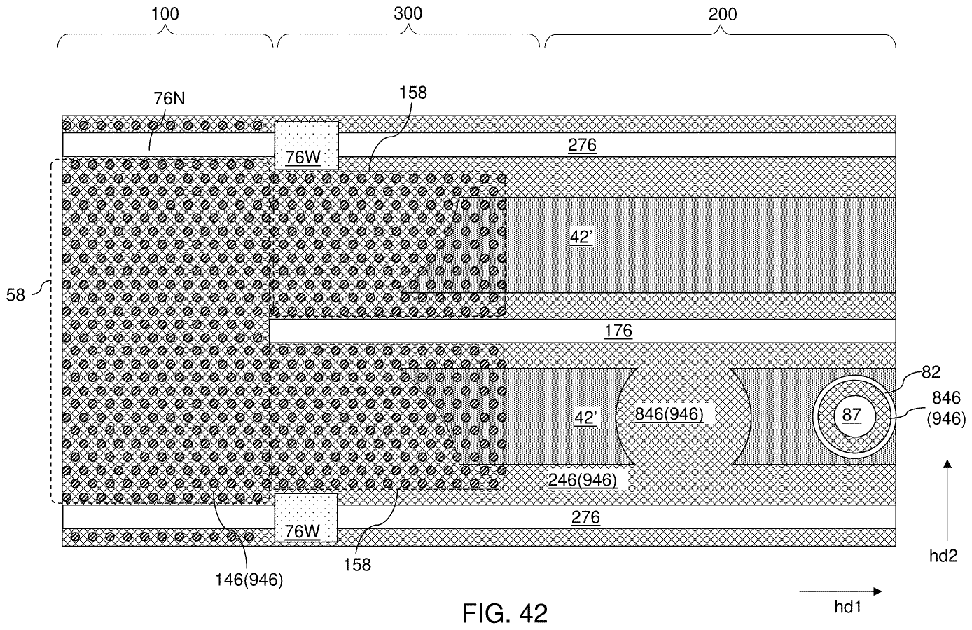

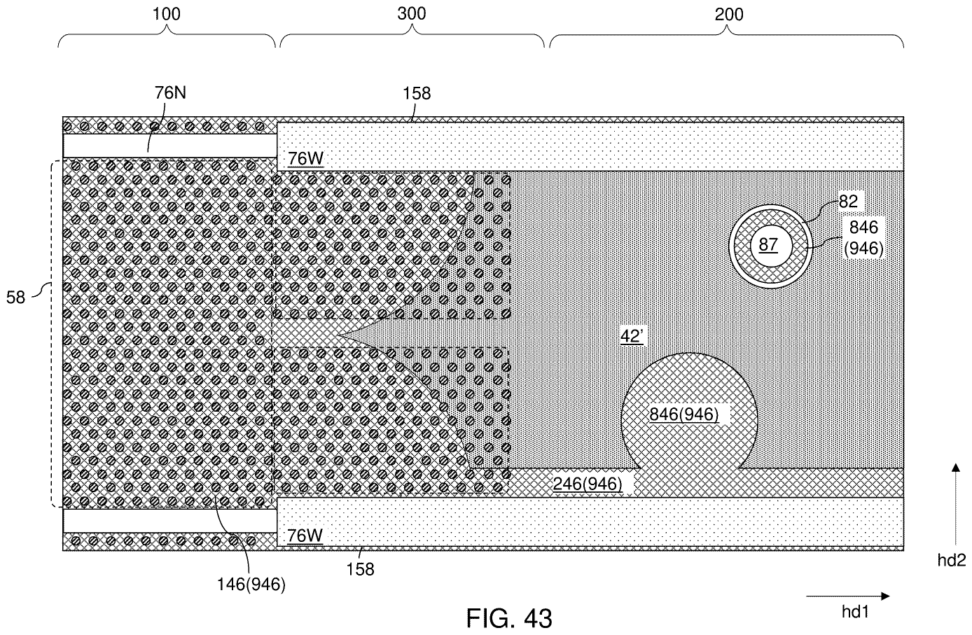

FIG. 43 is a horizontal cross-sectional view of the sixth alternative configuration of the second exemplary structure according to the second embodiment of the present disclosure that can be derived from the third alternative configuration shown in FIG. 40. In the sixth alternative configuration, the additional lateral isolation trench fill structures 276 are omitted and the wide lateral isolation trench fill structures 76W separate adjacent memory blocks in the connection regions 300 and the contact regions 200. In this configuration, the connection strips 246 are formed entirely through the contact via openings 85.

Referring to all drawings and according to various embodiments of the present disclosure, a memory device is provided, which comprises: integrated word line and contact via structures 946 each comprising a respective horizontally-extending word line 146, a respective contact via structure 846, and a respective lateral connection strip 246 connecting the respective horizontally-extending word line 146 and the respective contact via structure 846; insulating layers 32 vertically spaced apart from each other and interlaced with the horizontally-extending word lines 146 to provide a vertically alternating sequence (32, 146) of the insulating layers 32 and the horizontally-extending word lines 146; memory openings 49 vertically extending through the vertically alternating sequence (32, 146); and memory opening fill structures 58 located in the memory openings 49, wherein each of the memory opening fill structures 58 comprises a respective vertical stack of memory elements (which may comprise portions of memory material layers 54) located at levels of the horizontally-extending word lines 146 and a vertical semiconductor channel 60.

In one embodiment, the horizontally-extending word lines 146 laterally extend along a first horizontal direction hd1 and have a uniform word-line width along a second horizontal direction hd2 in a memory array region 100; the memory opening fill structures 58 are located in the memory array region 100; the lateral connection strips 246 laterally extend along the first horizontal direction hd1 and have a strip width along the second horizontal direction hd2 in a contact region 200, wherein the strip width is less than the uniform word line width; and the integrated word line and contact via structures 946 are located in the contact region 200.

In one embodiment, each of the horizontally-extending word lines 146 has a laterally-convex sidewall section in a connection region 300 that is located between the memory array region 100 and the contact region 200. In one embodiment, each of the horizontally-extending word lines 146 has a variable width that changes from the uniform word-line width to the strip width within the connection region 300 containing the laterally-convex sidewall sections.

In one embodiment, each of the contact via structures 846 has a respective bottom plate 846P and a respective tubular portion 846T having a bottom end that is connected to the respective bottom plate 846P. In one embodiment, a center portion of the respective bottom plate 846P has a uniform inner bottom plate thickness; the respective tubular portion 846T has a uniform lateral thickness between an inner sidewall and an outer sidewall; and the uniform lateral thickness is the same as the uniform inner bottom plate thickness.

In one embodiment, each of the tubular portions 846T of the contact via structures 846 laterally encloses a respective dielectric pillar material portion 87. In one embodiment, a contact-level dielectric layer 80 overlies the vertically alternating sequence (32, 146) and the tubular portions 846T. The contact-level dielectric layer 80 and the dielectric pillar material portions 87 are portions of a dielectric material having a uniform material composition throughout. In one embodiment, additional portions of the dielectric material comprise lateral isolation trench fill structures (76N, 76W, and/or 176) contacting sidewalls of each of the insulating layers 32 and each of the horizontally-extending word lines 146.

In one embodiment, the memory device further comprises metal oxide backside blocking dielectrics 44 which continuously extend along surfaces of the horizontally-extending word lines 146, the lateral connection strips 246, the bottom plates 846P and the tubular portions 846T.

In one embodiment, the memory device further comprises: additional integrated word line and contact via structures 946 comprising a respective additional horizontally-extending word line 146, a respective additional contact via structure 846, and a respective additional lateral connection strip 246. The additional integrated word line and contact via structures 946 are located in a second memory block (e.g., additional repeating unit RU) which is laterally spaced along the second horizontal direction hd1 from a first memory block (e.g., the repeating unit RU) containing the integrated word line and contact via structures 946 and the vertically alternating sequence of the insulating layers 32 and the horizontally-extending word lines 146. The memory device further comprises additional insulating layers 32 vertically spaced apart from each other and interlaced with the additional horizontally-extending word lines 146 to provide an additional vertically alternating sequence (32, 146) of the additional insulating layers 32 and the additional horizontally-extending word lines 146 located in the second memory block. The memory device further comprises a dual-width lateral isolation trench 79 extending along the first horizontal direction hd1 and laterally separating the first memory block from the second memory block, wherein the dual-width lateral isolation trench comprises a wide lateral isolation trench segment 79W having a first width and located in the contact region 200 and further comprising a narrow lateral isolation trench segment 79N having a second width and located in the memory array region 100, the first width being greater than the second width. A wide lateral isolation trench fill structure 76W fills the wide lateral isolation trench segment 79W; and a narrow lateral isolation trench fill structure 76N fills the narrow lateral isolation trench segment.

In the first embodiment, the narrow lateral isolation trench fill structure 76N comprises a part of a continuous dielectric material portion that has a uniform material composition throughout and further comprises a contact-level dielectric layer 80 overlying the vertically alternating sequence and the additional vertically alternating sequence; and the wide lateral isolation trench fill structure 76W is not part of the continuous dielectric material portion.

In the second embodiment, the narrow lateral isolation trench fill structure 76N and the wide lateral isolation structure 76W both comprise parts of a continuous dielectric material portion that has a uniform material composition throughout and further comprises a contact-level dielectric layer 80 overlying the vertically alternating sequence and the additional vertically alternating sequence.

In one embodiment, the lateral connection strips 246 of the integrated word line and contact via structures 946 are in contact with a sidewall of the wide lateral isolation trench fill structure 76W.

In the embodiments of FIG. 40-42, an additional lateral isolation trench fill structure 276 contacts a first end of the wide lateral isolation trench fill structure 76W, and the narrow lateral isolation trench fill structure 76N contacts a second end of the wide lateral isolation trench fill structure 76W opposite to the first end. The wide lateral isolation trench fill structure 76W has a greater width along the second horizontal direction hd2 than the narrow lateral isolation trench fill structure 76N and the additional lateral isolation trench fill structure 276.

In various embodiments, the memory device also comprises: an access lateral isolation trench 179 that is laterally spaced from the dual-width lateral isolation trench 79 along the second horizontal direction hd2; and an access isolation trench fill structure 176 filling the access lateral isolation trench 179. The lateral connection strips 246 of the integrated word line and contact via structures 946 are in contact with a sidewall of the access isolation trench fill structure 176. In one embodiment shown in FIG. 38A-38E, plural rows of the integrated word line and contact via structures 946 extending along the first horizontal direction are located between the access isolation trench 179 and the dual-width isolation trench 79.

In one embodiment, each of the integrated word line and contact via structures 946 comprises at least one electrically conductive material having a unform material composition throughout and is free of any material interface therein. In one embodiment, a vertical stack of dielectric material plates 42′ may be vertically interlaced with the insulating layers 32. Each of the dielectric material plates 42′ is in contact with a sidewall of the horizontally-extending word line 146, a sidewall of the lateral connection strip 246, and a sidewall of the contact via structure 846 of a respective one of the integrated word line and contact via structures 946.

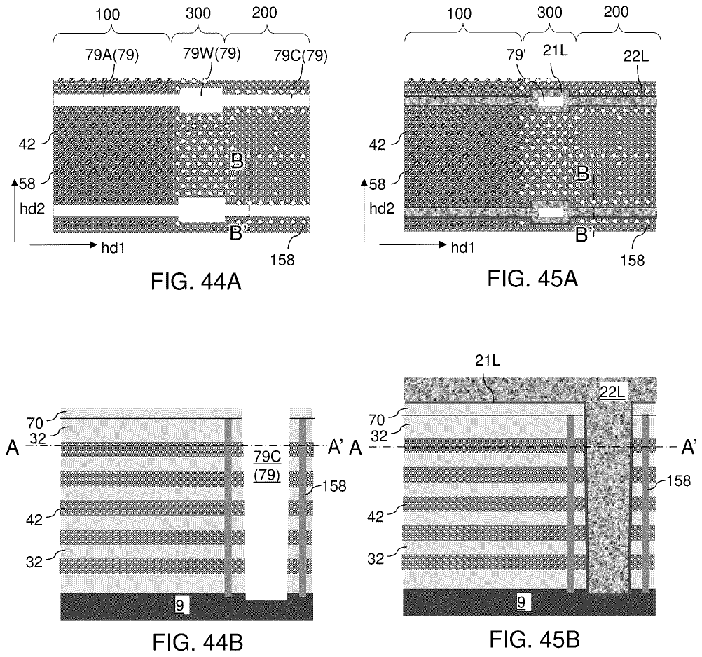

Referring to FIGS. 44A and 44B, a third exemplary structure according to a third embodiment of the present disclosure may be derived from the first exemplary structure illustrated in FIG. 4A-4C by performing the set of processing steps described with reference to FIG. 5A-5C with a modification in the pattern of the lateral isolation trenches 79. Generally, the third exemplary structure illustrated in FIGS. 44A and 44B may be provided by forming an alternating stack of insulating layers 32 and sacrificial material layers 42 over a substrate; forming memory openings 49 through the alternating stack in at least one memory array region 100 (which may comprise two memory array regions 100 laterally spaced apart from each other along the first horizontal direction hd1 by a combination of two connection regions 300 and a contact region 200); and forming memory opening fill structures 58 in the memory openings 49. In one embodiment, the sacrificial material layers 42 comprise a first sacrificial material which is a dielectric material (such as silicon nitride). Each of the memory opening fill structures 58 comprises a respective vertical stack of memory elements comprising portions of a respective memory film 50.

The at least one lateral isolation trench 79 employed in the third exemplary structure may comprise a plurality of lateral isolation trenches 79 each laterally extending along the first horizontal direction hd1 and laterally spaced apart from each other along the second horizontal direction hd2. In one embodiment, the lateral isolation trenches 79 may comprise array-region lateral isolation trench segments 79A that are formed in a respective memory array region 100 adjacent to the memory opening fill structures 58; contact-region lateral isolation trench segments 79C that are formed in the contact region 200; and wide lateral isolation trench segments 79W adjoining a respective pair of an array region lateral isolation trench 79A and a contact-region lateral isolation trench segment 79C. The wide lateral isolation trench segments 79W are wider than along the second horizontal direction hd2 than the respective pair of the array region lateral isolation trench 79A and the contact-region lateral isolation trench segment 79C.

In one embodiment, a continuous lateral isolation trench 79 that laterally extends along the first horizontal direction hd1 may comprise a combination of at least one array-region lateral isolation trench segment 79A, at least one wide lateral isolation trench segment 79W, and a contact-region lateral isolation trench segment 79C. The array-region lateral isolation trench segments 79A and the contact-region lateral isolation trench segments 79C may have widths that are comparable to the width of the narrow lateral isolation trench segments 79N described above, and the wide lateral isolation trench segments 79W may have a width that is comparable to the width of the wide lateral isolation trench segments 79W described above.

Referring to FIGS. 45A and 45B, a sacrificial barrier liner 21L and a sacrificial fill material layer 22L may be formed by performing the processing steps described with reference to FIGS. 6A and 6B. A cavity 79′ may be present in the center portion of each wide lateral isolation trench segment 79W.

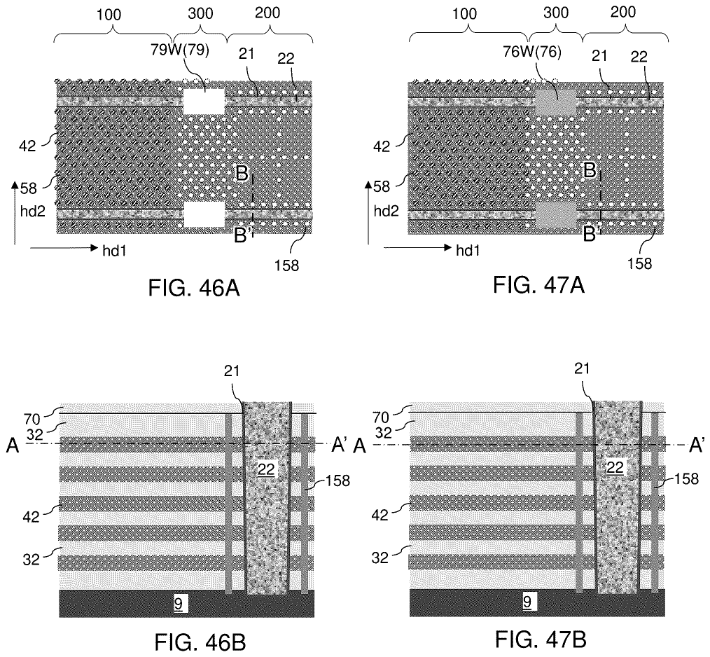

Referring to FIGS. 46A and 46B, portions of the sacrificial barrier liner 21L and the sacrificial fill material layer 22L located within the volumes of the wide lateral isolation trench segments 79W may be removed by performing the processing steps described with reference to FIGS. 7A and 7B. Each of the array-region lateral isolation trench segments 79A and the contact-region lateral isolation trench segments 79C may be filled with a respective combination of a sacrificial barrier liner 21 and a sacrificial lateral isolation trench fill structure 22.

Referring to FIGS. 47A and 47B, the wide lateral isolation trench fill sections 79W may be filled with wide lateral isolation trench fill structures 76W by performing the processing steps described with reference to FIGS. 8A and 8B.

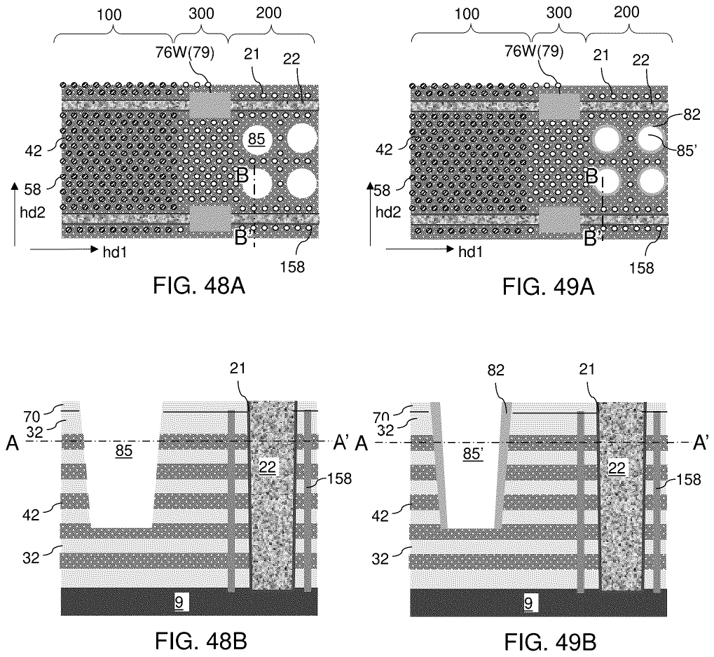

Referring to FIGS. 48A and 48B, contact via openings 85 are formed within the contact region 200 by performing the processing steps described with reference to FIG. 9A 9C. The bottom surface of each contact via opening 85 may be a surface of an underlying insulating layer 32, or may be a surface of an underlying sacrificial material layer 42. In one embodiment, a predominant fraction of the contact via opening 85 may be formed through a respective subset of the sacrificial material layers 42 and through a subset of the insulating layers 32 such that a respective first sacrificial material layer 42 of the sacrificial material layers 42 is exposed underneath the contact via opening 85.

Referring to FIGS. 49A and 49B, the processing steps described with reference to FIGS. 10A and 10B may be performed to form a tubular insulating spacer 82 in a peripheral portion of each contact via opening 85. Contact via cavities 85′ laterally surrounded by the tubular insulating spacers 82 are present within the volumes of the contact via openings 85.

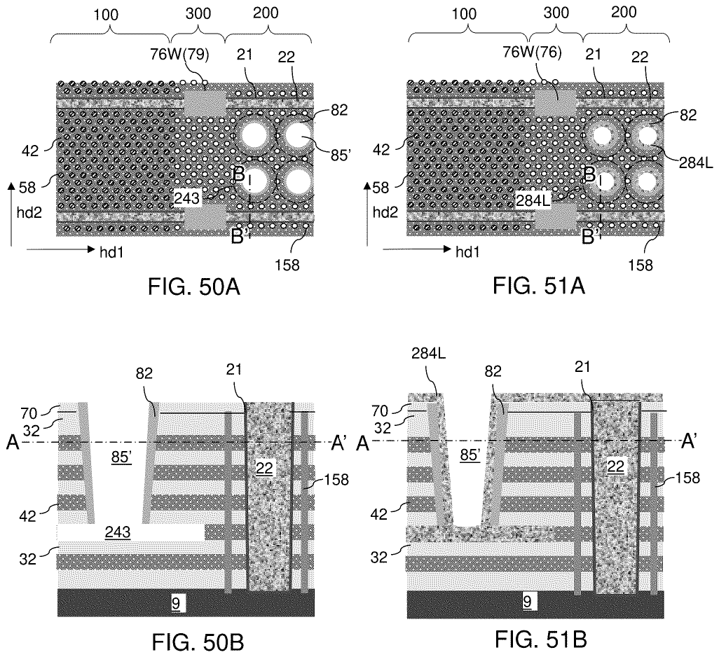

Referring to FIGS. 50A and 50B, a selective isotropic etch process can be performed to isotropically etch the first sacrificial material layers 42 selectively to the materials of the insulating layers 32, the tubular insulating spacers 82, the insulating cap layer 70, the sacrificial barrier liners 21, and the sacrificial lateral isolation trench fill structures 22. For example, if the sacrificial material layers 42 comprise silicon nitride, the selective isotropic etch process may comprise a wet etch process employing hot phosphoric acid. A plate-shaped cavity 243 may be formed underneath each contact via cavity 85′. The plate-shaped cavity 243 may have a uniform thickness which equals the thickness of the sacrificial material layers 42. The duration of the selective isotropic etch process is selected such that the plate-shaped cavities 243 is laterally spaced from the sacrificial barrier liners 21 and the sacrificial lateral isolation trench fill structures 22. The lateral extents of the plate-shaped cavities 243 are illustrated in dotted lines in FIG. 50A.

Referring to FIGS. 51A and 51B, a sacrificial fill material layer 284L comprising a second sacrificial material can be conformally deposited in the plate-shaped cavities 243, peripheral regions of the contact via cavities 85′, and over the insulating cap layer 70. The sacrificial fill material layer 284L comprises a second sacrificial material that is different from the first sacrificial material of the sacrificial material layers 42. For example, the sacrificial fill material layer 284L may comprise a semiconductor material (such as amorphous silicon, polysilicon, or silicon-germanium), porous or non-porous organosilicate glass, a carbon-based material (such as amorphous carbon or diamond-like carbon), or a polymer material. The thickness of the sacrificial fill material layer 284L may be selected such that the entire volume of the plate-shaped cavities 243 is filled with the sacrificial fill material layer 284L, but only a peripheral portion of the volume of a contact via opening 85 is filled with the sacrificial fill material layer 284L. A contact via cavity 85′ may be present within each volume of a contact via opening 85. The lateral extents of portions of the sacrificial fill material layer 284L filling a respective plate-shaped cavity 243 are illustrated in dotted lines in FIG. 51A.

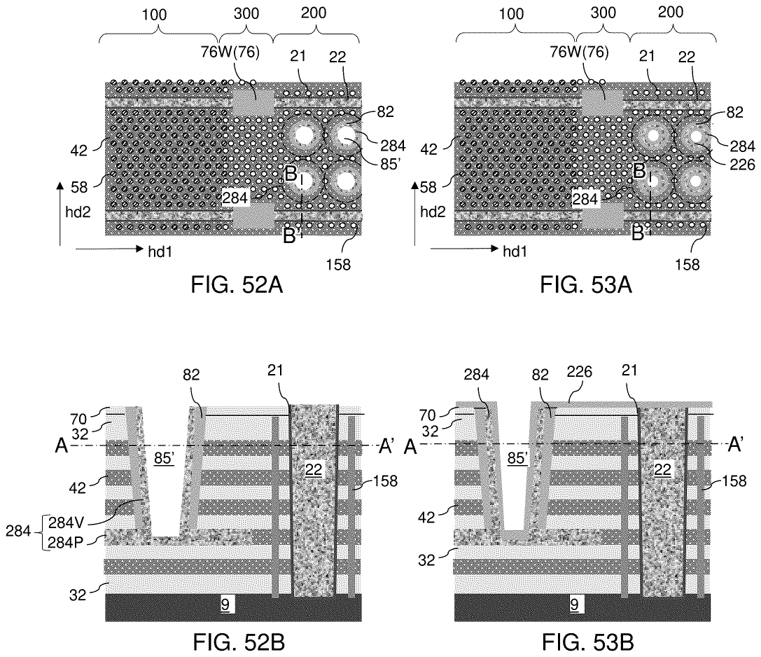

Referring to FIGS. 52A and 52B, the sacrificial fill material layer 284L may be patterned into a plurality of sacrificial plate-and-via structures 284. In one embodiment, a photoresist layer (not shown) can be applied over the third exemplary structure, and can be lithographically patterned into discrete photoresist material portions covering a respective one of the contact via openings 85. Portions of the sacrificial fill material layer 284L that are not covered by the discrete photoresist material portions may be etched by a selective etch process that etches the material of the sacrificial fill material layer 284L selectively to the material of the insulating cap layer 70. Remaining portions of the sacrificial fill material layer 284L constitute the plurality of sacrificial plate-and-via structures 284. In this case, each sacrificial plate-and-via structure 284 comprises a sacrificial material plate 284P that is located within a respective plate-shaped cavity 243 and is free of any opening therein. Alternatively, the patterning of the sacrificial fill material layer 284 into the plurality of sacrificial plate-and-via structures 284 may comprise performing an anisotropic etch process that etches the material of the sacrificial fill material layer 284L selectively to the materials of the insulating cap layer 70 and the insulating layers 32. In this case, each sacrificial plate-and-via structure 284 comprises an annular sacrificial material plate 284P that is located within a respective plate-shaped cavity 243 and contains a vertically-extending opening therein. The lateral extents of the sacrificial material plates 284 of the plate-shaped cavities 243 are illustrated in dotted lines in FIG. 52A.

Each sacrificial integrated plate-and-via structure 284 is formed through a respective upper portion of the alternating stack (32, 42). Each sacrificial integrated plate-and-via structure 284 comprises a sacrificial material plate 284P that is formed within a respective plate-shaped cavity 243 and a sacrificial vertically-extending portion 284V that vertically extends upward from the sacrificial material plate 284P. Each sacrificial integrated plate-and-via structure 284 is formed in volumes of a respective plate-shaped cavity 243 and a peripheral region of a respective contact via cavity 85′, which is a cavity that is laterally surrounded by a respective tubular insulating spacer 82. In one embodiment, the bottom periphery of the sidewall of the vertically-extending portion 284V is laterally recessed inward relative to a top periphery of a top surface of the sacrificial material plate 284P.

Referring to FIGS. 53A and 53B, an insulating cover layer 226 can be formed over the sacrificial integrated plate-and-via structures 284 and the insulating cap layer 70. The insulating cover layer 226 comprises an insulating material, such as undoped silicate glass (e.g., silicon oxide) or a doped silicate glass, and may have a thickness in a range from 10 nm to 50 nm, although lesser or greater thicknesses may also be employed.

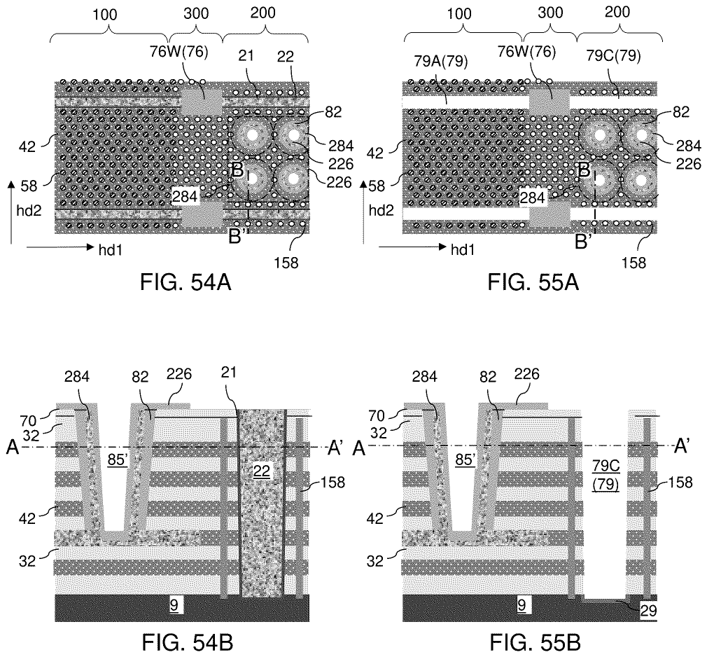

Referring to FIGS. 54A and 54B, the insulating cover layer 226 may be patterned into a plurality of insulating cover layer 226 each covering a respective one of the sacrificial integrated plate-and-via structures 284, using photolithography and etching. Top surfaces of the sacrificial lateral isolation trench fill structures 22 are physically exposed, while the top surfaces of the vertically-extending portions 284V of the sacrificial integrated plate-and-via structures 284 are covered by the insulating cover layer 226.

Referring to FIGS. 55A and 55B, a first selective isotropic etch process can be performed to etch the sacrificial lateral isolation trench fill structures 22 selectively to the sacrificial barrier liners 21. For example, if the sacrificial lateral isolation trench fill structures 22 comprise amorphous silicon or polysilicon, a wet etch process employing hot trimethyl-2 hydroxyethyl ammonium hydroxide (“hot TMY”) or tetramethylammonium hydroxide may be performed to remove the sacrificial lateral isolation trench fill structures 22. Subsequently, a second selective isotropic etch process can be performed to etch the sacrificial barrier liners 21 selectively to the materials of the insulating layers 32 and the insulating cover layers 226. For example, if the sacrificial barrier liners 21 comprise silicon nitride, a wet etch process employing hot phosphoric acid may be performed. Voids are formed in the volumes of the array-region lateral isolation trench segments 79A and in the volumes of the contact-region lateral isolation trench segments 79C. An oxidation process may be performed to convert physically exposed surface portions of the semiconductor material layer 9 in the substrate into semiconductor oxide liners 29 at the bottom of the lateral isolation trenches 79.

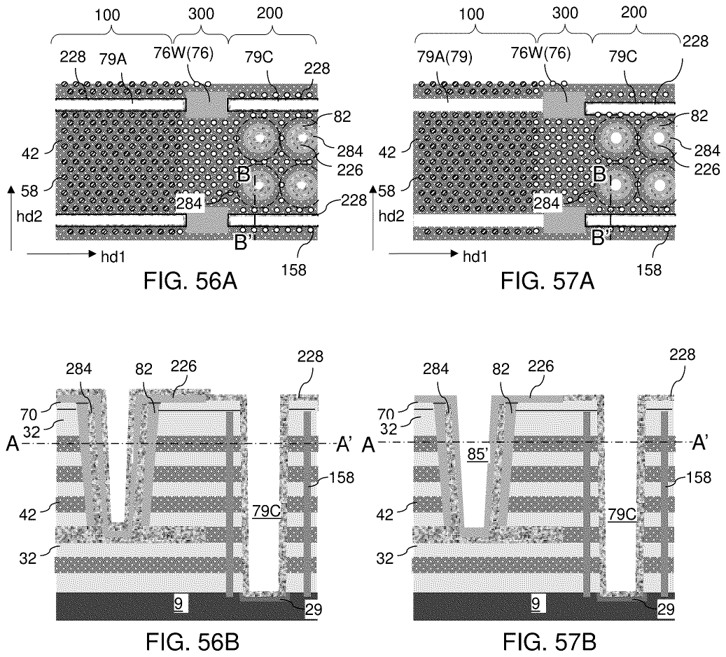

Referring to FIGS. 56A and 56B, a sacrificial etch barrier layer 228 can be conformally deposited over the insulating cover layer 226 and on the physically exposed surfaces of the array-region lateral isolation trench segments 79A and the contact-region lateral isolation trench segments 79C. The sacrificial etch barrier layer 228 comprises a sacrificial material that is subsequently employed as an etch barrier material. For example, the sacrificial etch barrier layer 228 may comprise amorphous silicon or polycrystalline silicon, and may have a thickness in a range from 30 nm to 100 nm, although lesser or greater thicknesses may also be employed.

Referring to FIGS. 57A and 57B, portions of the sacrificial etch barrier layer 228 that are located outside the contact-region lateral isolation trench segments 79C are removed. For example, a photoresist layer (not shown) can be applied over the third exemplary structure, and can be lithographically patterned to form photoresist material portions overlying the areas of the contact-region lateral isolation trench segments 79C. A selective etch process can be performed to remove the portions of the sacrificial etch barrier layer 228 that are not covered by the patterned photoresist material portions (e.g., portions located in array-region lateral isolation trench segments 79A). The patterned photoresist material portions can be subsequently removed, for example, by ashing.

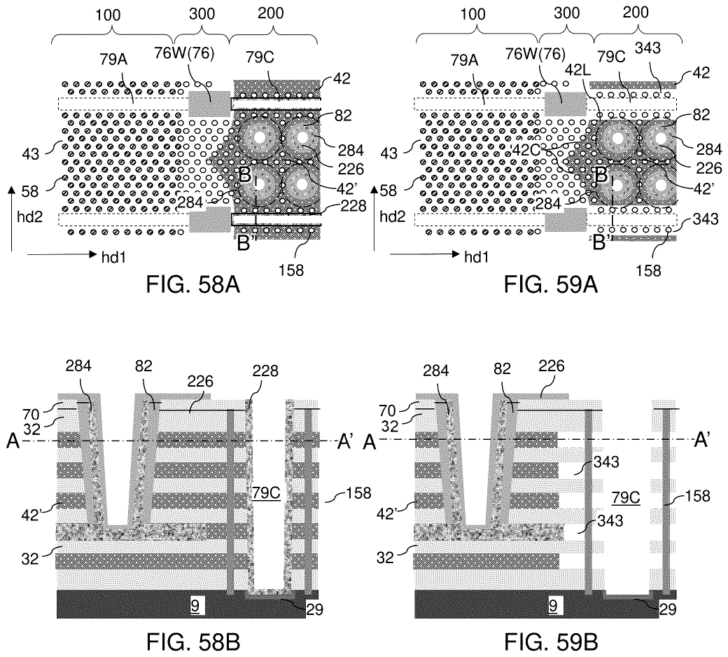

Referring to FIGS. 58A and 58B, the processing steps described with reference to FIG. 17A-17D may be performed to form the laterally-extending cavities 43. Specifically, a first selective isotropic etch process can be performed to remove first portions of the sacrificial material layers 42 that are proximal to the array-region lateral isolation trench segments 79A. The array-region lateral isolation trench segments 79A may be employed as conduits for introducing an isotropic etchant that selectively etches physically exposed portions of the sacrificial material layers 42 selectively to the materials of the insulating layers 32, the wide lateral isolation trench fill structures 76W, and the sacrificial etch barrier layers 228 located in the contact-region lateral isolation trench segments 79C. Remaining portions of the sacrificial material layers 42 located in the contact region 200 constitute dielectric plates 42′. Each of the dielectric plates 42′ may comprise a respective pair of laterally concave and vertically straight sidewalls that are adjoined to each other.

Referring to FIGS. 59A and 59B, an isotropic etch process can be performed to remove the remaining sacrificial etch barrier layers 228 located in the contact-region lateral isolation trench segments 79C. For example, if the sacrificial etch barrier layers 228 comprise amorphous silicon or polysilicon, a wet etch process employing hot TMY or tetramethylammonium hydroxide may be performed.

Subsequently, a second selective isotropic etch process can be performed to remove second portions of the sacrificial material layers 42 that are proximal to the voids within the volumes of the contact-region lateral isolation trench segments 79C or proximal to the voids of the laterally-extending cavities 43. The second portions of the sacrificial material layers 42 are laterally recessed selectively to the materials of the insulating layers 32, the wide lateral isolation trench fill structures 76W, the insulating cover layer 226, and the sacrificial integrated plate-and-via structures 284. Strip-shaped cavities 343 are formed in the volumes from which portions of the sacrificial material layers 42 that are proximal to the contact-region lateral isolation trench segments 79C are removed. The laterally-extending cavities 43 may be laterally extended by a lateral extension distance that equals the uniform width of the strip-shaped cavities 343. Each strip-shaped cavity 343 is adjoined to a respective one of the laterally-extending cavities 43. The dielectric plates 42′ may be isotropically laterally recessed. Each of the dielectric plates 42′ may comprise a respective pair of laterally concave and vertically straight sidewalls 42C that are adjoined to each other, and a respective pair of lengthwise sidewalls 42L that are parallel to the first horizontal direction hd1, as shown in FIG. 59A.

In summary, the laterally-extending cavities 43 and strip-shaped cavities 343 may be formed by removing portions of the sacrificial material layers 42 that are proximal to at least one lateral isolation trench 79. The at least one lateral isolation trench 79 may comprise a plurality of array-region lateral isolation trench segments 79A and a plurality of contact-region lateral isolation trench segments 79C. A vertical stack of dielectric plates 42′ can be formed at the levels of the laterally-extending cavities 43. A first subset of the dielectric plates 42′ may laterally surround vertically-extending portions of the sacrificial integrated plate-and-via structure 284. Each sacrificial material plate of the sacrificial integrated plate-and-via structures 284 may be physically exposed to a respective one of the strip-shaped cavities 343.

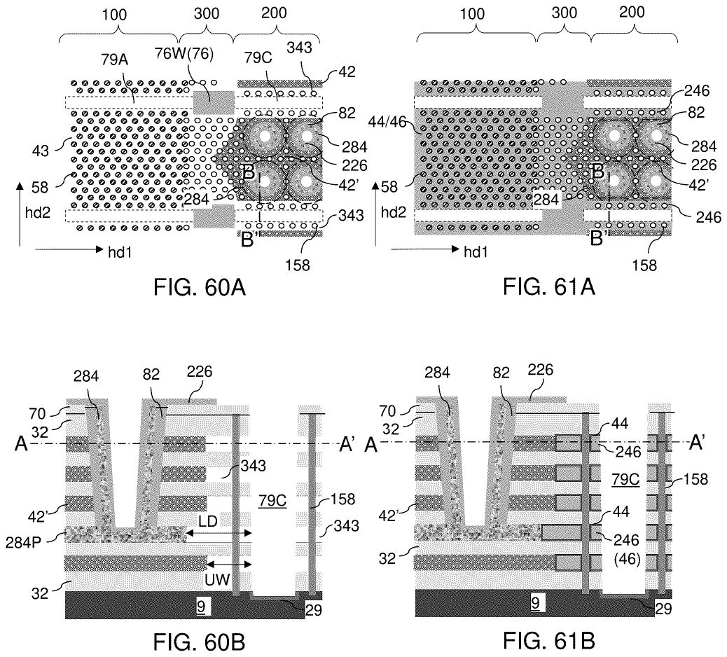

Referring to FIGS. 60A and 60B, a selective isotropic etch process can be performed to etch portions of the sacrificial integrated plate-and-via structures 284 that are exposed to the strip-shaped cavities 343. Thus, the lateral distance LD between the sacrificial material plate 284P of each sacrificial integrated plate-and-via structure 284 and a most proximal contact-region lateral isolation trench segment 79C is greater than the uniform width UW of the strip-shaped cavities 343, as shown in FIG. 60B. The selective isotropic etch process locally expands each of the strip-shaped cavities 343 along the second horizontal direction hd2 by laterally recessing the sacrificial material plates 284P selectively to the dielectric plates 42′ and the insulating layers 32.

Referring to FIGS. 61A and 61B, the processing steps described with reference to FIG. 20A-20E and 21A-21E may be performed to form a combination of a backside blocking dielectric 44 and an electrically conductive layers 46 or horizontally-extending lateral connection strips 246 within each contiguous combination of a respective laterally-extending cavity 43 and a respective subset of the strip-shaped cavities 343, respectively. A vertically alternating sequence (32, 46) of the insulating layers 32 and the electrically conductive layers 46 is formed between each neighboring pair of lateral isolation trenches 79. Each of the lateral isolation trenches 79 may contain a respective wide lateral isolation trench fill structure 76W. In this embodiment, the horizontally-extending lateral connection strips 246 comprise portions of the electrically conductive layers 46 that are located in the strip-shaped cavities 343 and are formed during the same step as the electrically conductive layers 46.

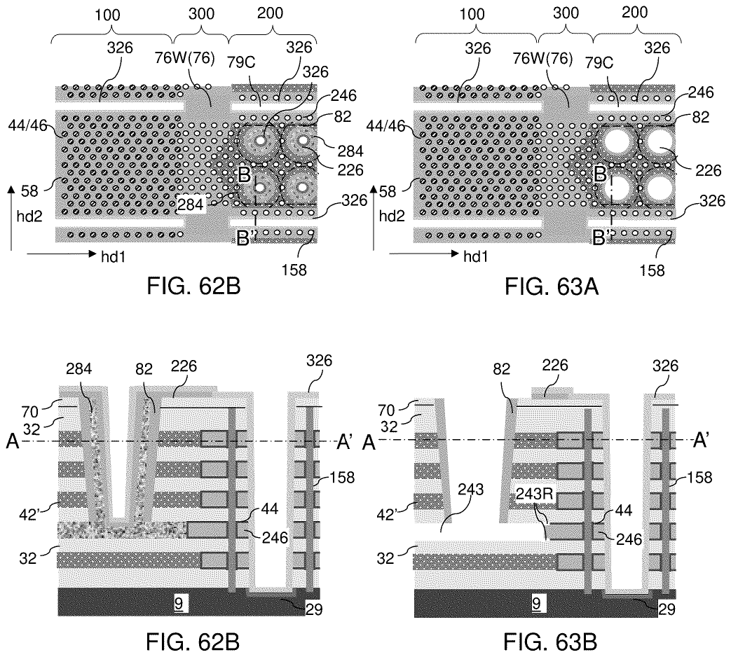

Referring to FIGS. 62A and 62B, an insulating liner 326 can be conformally deposited over the sacrificial integrated plate-and-via structures 284 and on the sidewalls of the lateral isolation trenches 79. The insulating liner 326 comprises an insulating material, such as undoped silicate glass (i.e., silicon oxide) or a doped silicate glass. The thickness of the insulating liner 326 may be in a range from 30 nm to 100 nm, although lesser or greater thicknesses may also be employed.

Referring to FIGS. 63A and 63B, a photoresist layer (not shown) can be applied over the third exemplary structure, and can be lithographically patterned to cover the lateral isolation trenches 79 without covering the areas of the sacrificial integrated plate-and-via structures 284. Portions of the insulating liner 326 and the insulating cover layer 226 that are not covered by the photoresist layer can be removed by performing an isotropic etch process. For example, if the insulating liner 326 and the insulating cover layer 226 comprise silicon oxide, a wet etch process employing dilute hydrofluoric acid may be performed to remove the unmasked portions of the insulating liner 326 and the insulating cover layer 226.

A selective isotropic etch process can be performed to remove the sacrificial integrated plate-and-via structures 284 selectively to the materials of the insulating liner 326, the tubular insulating spacers 82, the insulating layers 32, and the electrically conductive layers 46. For example, if the sacrificial integrated plate-and-via structures 284 comprise a semiconductor material, a wet etch process employing hot TMY or trimethylammonium hydroxide may be performed to remove the sacrificial integrated plate-and-via structures 284. Voids are formed in the volumes of the plate-shaped cavities 243.

Subsequently, an additional selective isotropic etch process can be performed to remove portions of the backside blocking dielectrics 44 from around the volumes of the plate-shaped cavities 243. The additional selective isotropic etch process may be selective to the materials of the insulating liner 326, the tubular insulating spacers 82, the insulating layers 32, and the electrically conductive layers 46. For example, if the backside blocking dielectrics 44 comprise aluminum oxide or a dielectric transition metal oxide, the additional selective isotropic etch process may comprise a wet etch process employing hot phosphoric acid. The duration of the additional selective isotropic etch process can be selected such that the etch distance of the additional selective isotropic etch process for the material of the backside blocking dielectrics 44 is greater than the thickness of the backside blocking dielectrics 44. Two annular rim-shaped cavities 243R can be formed around each void of a respective plate-shaped cavity 243 upon removal of horizontally-extending portions of the backside blocking dielectrics 44 around the plate-shaped cavities 243, as shown in FIG. 63B.

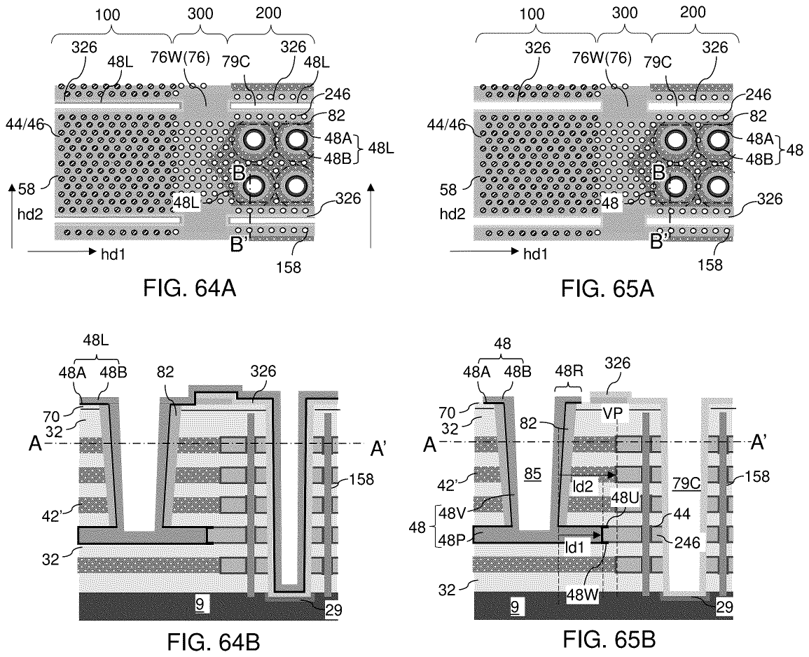

Referring to FIGS. 64A and 64B, at least one electrically conductive material can be conformally deposited to form a conformal electrically conductive material layer 48L. In one embodiment, the conformal electrically conductive material layer 48L comprises a metallic barrier liner 48A and a metal layer 48B. The metallic barrier liner 48A may comprise metallic barrier material, such as TiN, TaN, WN, or MoN, and may have a thickness in a range from 3 nm to 30 nm, although lesser or greater thicknesses may also be employed. The metal layer 48B comprises a metal such as W, Co, Mo, Ru, etc. The thickness of the metal layer 48B may be in a range from 50 nm to 300 nm, although lesser or greater thicknesses may also be employed.

Referring to FIGS. 65A and 65B, the conformal electrically conductive material layer 48L can be patterned, for example, by applying and patterning a photoresist layer over the conformal electrically conductive material layer 48L, and by transferring the pattern in the patterned photoresist layer into the conformal electrically conductive material layer 48L by performing an etch process. The etch process may be selective to the material of the insulating liner 326. Patterned portions of the conformal electrically conductive material layer 48L constitute integrated plate-and-via structures 48 (e.g., word line contact via structures).

Each integrated plate-and-via structure 48 comprises an electrically conductive plate 48P and a vertically-extending portion 48V extending upward from the electrically conductive plate 48P. Each electrically conductive plate is in contact with a sidewall of a connection strip 246 portion of a respective first electrically conductive layer 46 of the electrically conductive layers 46 at an interface. A first lateral distance ld1 between a bottom periphery of an outer sidewall of the vertically-extending portion 48V and the interface is less than a second lateral distance ld2 between the bottom periphery and each electrically conductive layer 46 (e.g., connecting strip 246 thereof) that overlies the first electrically conductive layer 46.

In one embodiment, the bottom periphery of the sidewall of the vertically-extending portion 48V is laterally recessed inward relative to a top periphery of a top surface of the electrically conductive plate 48P. In one embodiment, the bottom periphery of the sidewall of the vertically-extending portion 48Vis laterally spaced from each electrically conductive layer 46 (e.g., connecting strip 246 thereof) that underlies the first electrically conductive layer 46 by the second lateral distance ld2.

In one embodiment, the electrically conductive plate 48P comprises: an upper lateral protrusion 48U contacting a segment of a top surface of the first electrically conductive layer 46 (e.g., connecting strip 246 thereof); and a lower lateral protrusion 48W contacting a segment of a bottom surface of the first electrically conductive layer 46 (e.g., connecting strip 246 thereof). In one embodiment, the first electrically conductive layer 46 is vertically spaced from an overlying insulating layer 32 and from an underlying insulating layer 32 by a backside blocking dielectric 44. In one embodiment, the vertical thickness of the upper lateral protrusion 48U and the vertical thickness of the lower lateral protrusion 48W are the same as the thickness of the backside blocking dielectric 44, which may be in a range from 1 nm to 5 nm, although lesser or greater thicknesses may also be employed. In one embodiment, the vertical extent of the electrically conductive plate 48P is the same as a sum of a thickness of the first electrically conductive layer 46 and twice the thickness of the backside blocking dielectric 44.

In one embodiment, a vertical stack of dielectric plates 42′ can be located at levels of the electrically conductive layers 46. A first subset of the dielectric plates 42′ laterally surrounds the vertically-extending portions of the integrated plate-and-via structures 48. In one embodiment, tubular insulating spacers 82 laterally surround the vertically-extending portions 48V of the integrated plate-and-via structures 48 and contact the first subset of the dielectric plates 42′. In one embodiment, the tubular insulating spacers 82 are in contact with the entirety of the outer sidewalls of the vertically-extending portions 48V of the integrated plate-and-via structures 48, and are in contact with annular segments of the top surfaces of the electrically conductive plates 48P of the integrated plate-and-via structures 48. In one embodiment, each integrated plate-and-via structure 48 comprises a rim portion 48R that laterally protrudes outward from a top end of the vertically-extending portion 48V and overlies a respective vertically alternating sequence (32, 46).

The sidewall of the electrically conductive plate 48P contacts a sidewall of a respective one of the electrically conductive layers 46 (e.g., connecting strip 246 thereof). The interface between the sidewall of the electrically conductive plate 48P contacts a sidewall of a respective one of the electrically conductive layers 46 is laterally offset from overlying and underlying electrically conductive layers 46. Therefore, a likelihood of leakage current and capacitive interference between the electrically conductive plate 48P and the overlying and underlying electrically conductive layers 46 are reduced.

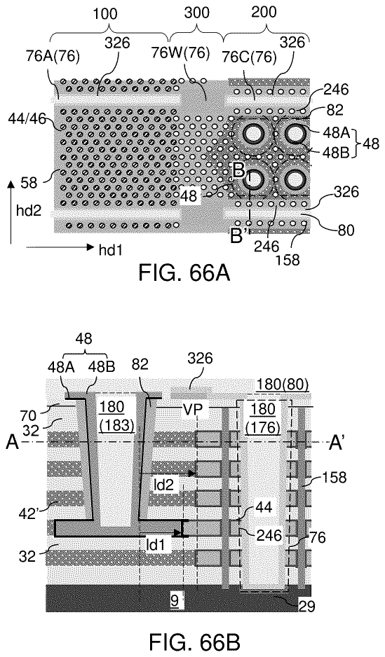

Referring to FIGS. 66A and 66B, a dielectric fill material, such as silicon oxide, can be deposited in the remaining volumes of the lateral isolation trenches 79, in the voids within the contact via openings 85, and over the insulating cap layer 70 to form a continuous dielectric material portion 180. The continuous dielectric material portion 180 may comprise: a contact-level dielectric layer 80 overlying the vertically alternating sequence (32, 46); dielectric cores 183 each laterally surrounded by the vertically-extending portion of a respective integrated plate-and-via structure 48; and lateral isolation trench fill material portions 176 located in a respective lateral isolation trench 79.

In one embodiment, each lateral isolation trench 79 may be filled with a respective lateral isolation trench fill structure 76. Each lateral isolation trench fill structure 76 may comprise a combination of a portion of an insulating liner 326 and a lateral isolation trench fill material portion 176. Each lateral isolation trench fill structure 76 may have a lengthwise sidewall that laterally extends along a first horizontal direction hd1 and contacts first sidewalls of the insulating layers 32 and first sidewalls of the electrically conductive layers 46 of a respective vertically alternating sequence (32, 46). In one embodiment, second sidewalls of the electrically conductive layer 46 are located within a vertical plane VP that is at the second lateral distance ld2 from the bottom periphery of the outer sidewall of the vertically-extending portion of the integrated plate-and-via structure 48. In one embodiment, the vertical plane VP is parallel to the first horizontal direction hd1.

In one embodiment, the entirety of the interface is more distal from the lateral isolation trench fill structure 76 than the vertical plane VP is from the vertical plane. In one embodiment, first sidewalls of the vertical stack of dielectric plates 42′ are parallel to the first horizontal direction hd1 and are located between the lateral isolation trench fill structure 76 and the vertically-extending portion of the integrated plate-and-via structure 48.

Referring to the drawings of the present disclosure and according to the third embodiment of the present disclosure, a memory device is provided, which comprises: a vertically alternating sequence (32, 46) of insulating layers 32 and electrically conductive layers 46; memory openings 49 vertically extending through the vertically alternating sequence (32, 46); memory opening fill structures 58 located in the memory openings 49, wherein each of the memory opening fill structures 58 comprises a respective vertical stack of memory elements (comprising portions of a respective memory film 50) located at levels of the electrically conductive layers 46 and a vertical semiconductor channel 60; and an integrated plate-and-via structure 48 comprising an electrically conductive plate 48P and a vertically-extending portion 48V extending upward from the electrically conductive plate 48P, wherein the electrically conductive plate 48P is in contact with a sidewall of a first electrically conductive layer 46 of the electrically conductive layers 46 at an interface, and a first lateral distance ld1 between a bottom periphery of an outer sidewall of the vertically-extending portion 48V and the interface is less than a second lateral distance ld2 between the bottom periphery of the outer sidewall of the vertically-extending portion 48V and each electrically conductive layer 46 that overlies the first electrically conductive layer 46.

In one embodiment, the bottom periphery of the sidewall of the vertically-extending portion 48V is laterally recessed inward relative to a top periphery of a top surface of the electrically conductive plate 48P. In one embodiment, the bottom periphery of the outer sidewall of the vertically-extending portion 48V is laterally spaced from each electrically conductive layer 46 that underlies the first electrically conductive layer 46 by the second lateral distance ld2. In one embodiment, the electrically conductive plate 48P comprises: an upper lateral protrusion 48U contacting a segment of a top surface of the first electrically conductive layer 46; and a lower lateral protrusion 48W contacting a segment of a bottom surface of the first electrically conductive layer 46.

In one embodiment, the first electrically conductive layer 46 is vertically spaced from an overlying insulating layer 32 of the insulating layers 32 and from an underlying insulating layer 32 of the insulating layers 32 by a backside blocking dielectric 44. In one embodiment, a vertical thickness of the upper lateral protrusion 48U and a vertical thickness of the lower lateral protrusion 48W are the same as a thickness of the backside blocking dielectric 44. In one embodiment, a vertical extent of the electrically conductive plate 48P is the same as a sum of a thickness of the first electrically conductive layer 46 and twice a thickness of the backside blocking dielectric 44.

In one embodiment, the memory device also comprises a vertical stack of dielectric plates 42′ located at levels of the electrically conductive layers 46, wherein a first subset of the dielectric plates 42′ laterally surrounds the vertically-extending portion 48V of the integrated plate-and-via structure 48. In one embodiment, the memory device also comprises a tubular insulating spacer 82 laterally surrounding the vertically-extending portion 48V of the integrated plate-and-via structure 48 and contacting the first subset of the dielectric plates 42′. In one embodiment, the tubular insulating spacer 82 is in contact with an entirety of the outer sidewall of the vertically-extending portion 48V, and is in contact with an annular segment of a top surface of the electrically conductive plate 48P.

In one embodiment, the memory device comprises a continuous dielectric material portion 180 that comprises: a contact-level dielectric layer 80 overlying the vertically alternating sequence (32, 46); a dielectric core 183 laterally surrounded by the vertically-extending portion of the integrated plate-and-via structure 48; and a lateral isolation trench fill material portion 76 located in a respective lateral isolation trench 79.

In one embodiment, the memory device also comprises a lateral isolation trench fill structure 76 having a lengthwise sidewall that laterally extends along a first horizontal direction hd1 and contacts first sidewalls of the insulating layers 32 and first sidewalls of the electrically conductive layers 46. In one embodiment, second sidewalls of the electrically conductive layer 46 are located within a vertical plane VP that is at the second lateral distance ld2 from the bottom periphery of the outer sidewall of the vertically-extending portion 48V of the integrated plate-and-via structure 48; and the vertical plane VP is parallel to the first horizontal direction hd1. In one embodiment, an entirety of the interface is more distal from the lateral isolation trench fill structure 76 than the vertical plane VP is from the lateral isolation trench fill structure 76.

In one embodiment, first sidewalls of the vertical stack of dielectric plates 42′ are parallel to the first horizontal direction hd1 and are located between the lateral isolation trench fill structure 76 and the vertically-extending portion of the integrated plate-and-via structure 48.

In one embodiment, a lateral connection strip portion 246 of the first electrically conductive layer 46 extends along the first horizontal direction hd1 between the lateral isolation trench fill structure 76 and the vertical stack of dielectric plates 42'; and the electrically conductive plate 48P is in contact with the sidewall of the lateral connection strip portion 246 of the first electrically conductive layer 46.

In one embodiment, the integrated plate-and-via structure 48 also comprises a rim portion 48R that laterally protrudes outward from a top end of the vertically-extending portion and overlies the vertically alternating sequence (32, 46).

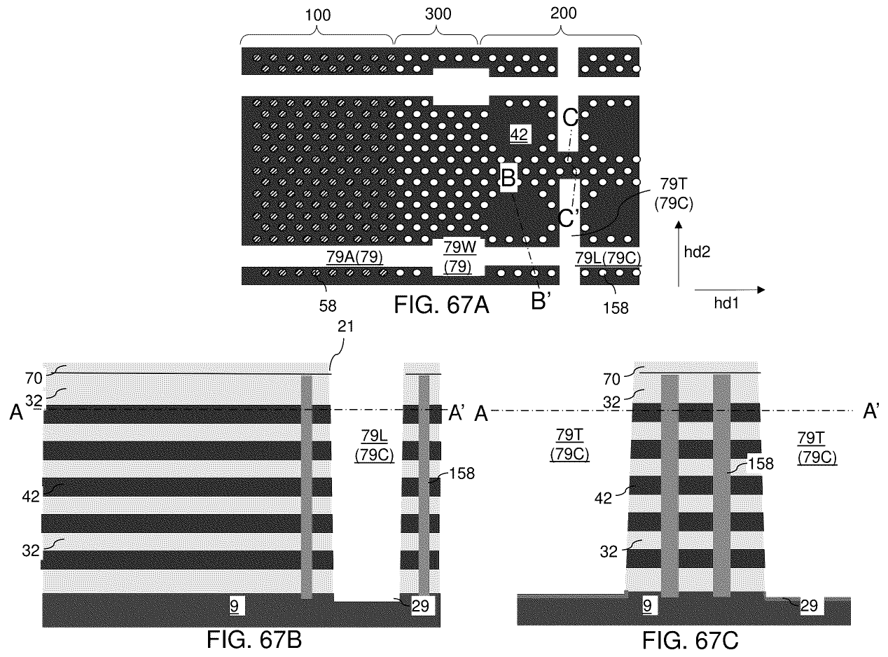

Referring to FIG. 67A-67C, a fourth exemplary structure according to the fourth embodiment of the present disclosure may be derived from the third exemplary structure illustrated in FIGS. 44A and 44B by modifying the pattern of the contact-region lateral isolation trench segments 79C such that the contact-region lateral isolation trench segments 79C comprise a combination of longitudinal lateral isolation trench segments 79L that laterally extend along a first horizontal direction (e.g., word line direction) hd1 and transverse lateral isolation trench segments 79T that laterally extend along a second horizontal direction (e.g., bit line direction) hd2. Generally, the fourth exemplary structure illustrated in FIG. 67A-67C may be provided by forming an alternating stack of insulating layers 32 and sacrificial material layers 42 over a substrate; forming memory openings 49 through the alternating stack in at least one memory array region 100 (which may be two memory regions (e.g., two memory planes) 100 laterally spaced apart from each other along the first horizontal direction hd1 by a combination of two connection regions 300 and a contact region 200); and forming memory opening fill structures 58 in the memory openings 49. In one embodiment, the sacrificial material layers 42 comprise a first sacrificial material which is a dielectric material (such as silicon nitride). Each of the memory opening fill structures 58 comprises a respective vertical stack of memory elements (e.g., portions of a respective memory film 50) and a vertical semiconductor channel 60.

The at least one lateral isolation trench 79 employed in the fourth exemplary structure may comprise a plurality of lateral isolation trenches 79. In one embodiment, the lateral isolation trenches 79 may comprise array-region lateral isolation trench segments 79A that are formed in a respective memory array region 100 adjacent to the memory opening fill structures 58; longitudinal lateral isolation trenches 79L each laterally extending along the first horizontal direction hd1 and laterally spaced apart from each other along the second horizontal direction hd2; transverse lateral isolation trench segments 79T that are formed in the contact region 200 and laterally extending along the second horizontal direction hd2 and each adjoined to a respective one of the longitudinal lateral isolation trench segments 79L; and wide lateral isolation trench segments 79W adjoining a respective pair of an array region lateral isolation trench 79A and a longitudinal lateral isolation trench segment 79C. The transverse lateral isolation trench segments 79T are laterally spaced apart from each other along the second horizontal direction hd2.

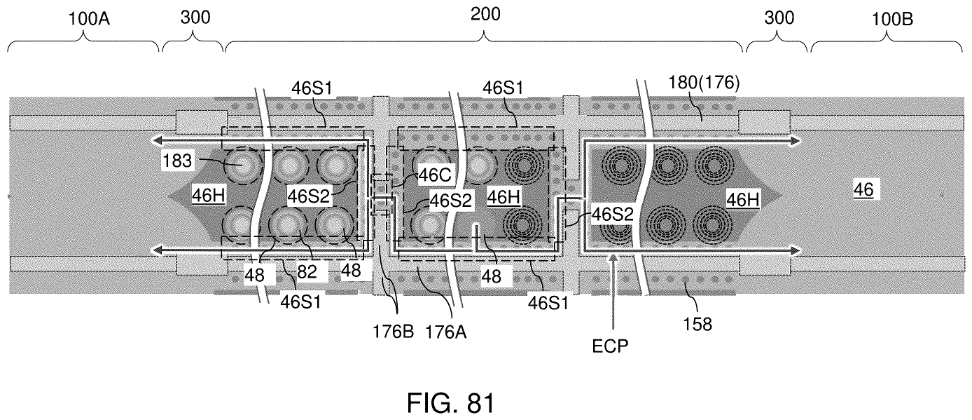

Thus, in the fourth embodiment, each of the lateral isolation trenches 79 comprises a respective longitudinal lateral isolation trench segment 79L that laterally extends along a first horizontal direction hd1 and at least one transverse lateral isolation trench segment 79T that laterally extends along a second horizontal direction hd2 different from the first horizontal direction hd1 and is formed in a contact region 200. In one embodiment, the second horizontal direction hd2 may be perpendicular to the first horizontal direction hd1. In one embodiment, a continuous lateral isolation trench 79 may comprise a combination of at least one array-region lateral isolation trench segment 79A, at least one wide lateral isolation trench segment 79W, a longitudinal lateral isolation trench segment 79L, and at least one transverse lateral isolation trench segment 79T that intersects the longitudinal lateral isolation trench segment 79L. In one embodiment that will be described in more detail with respect to FIG. 81, the at least one transverse lateral isolation trench segment 79T may comprise a plurality of transverse lateral isolation trench segments 79T that are laterally spaced apart from each other along the first horizontal direction hd1. The array-region lateral isolation trench segments 79A, the longitudinal lateral isolation trench segments 79L, and the transverse lateral isolation trench segments 79T may have widths that are comparable to the width of the narrow lateral isolation trench segments 79N described above, and the wide lateral isolation trench segments 79W may have a width that are comparable to the width of the wide lateral isolation trench segments 79W described above. Thus, the wide lateral isolation trench segments 79W are wider than the array-region lateral isolation trench segments 79A, the longitudinal lateral isolation trench segments 79L, and the transverse lateral isolation trench segments 79T.

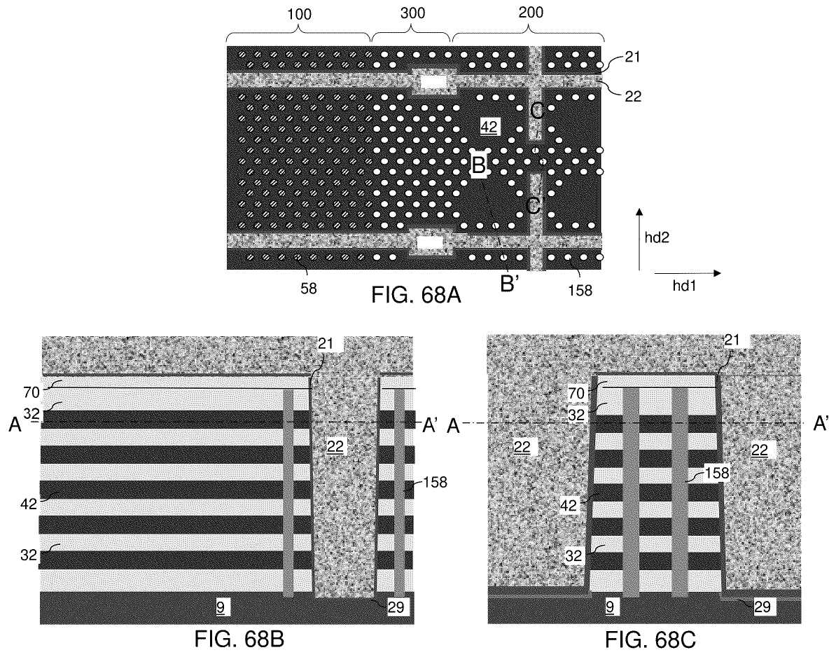

Referring to FIG. 68A-68C, a sacrificial barrier liner 21L and a sacrificial fill material layer 22L may be formed by performing the processing steps described with reference to FIGS. 6A and 6B. A cavity 79′ may be present in the center portion of each wide lateral isolation trench 79W.

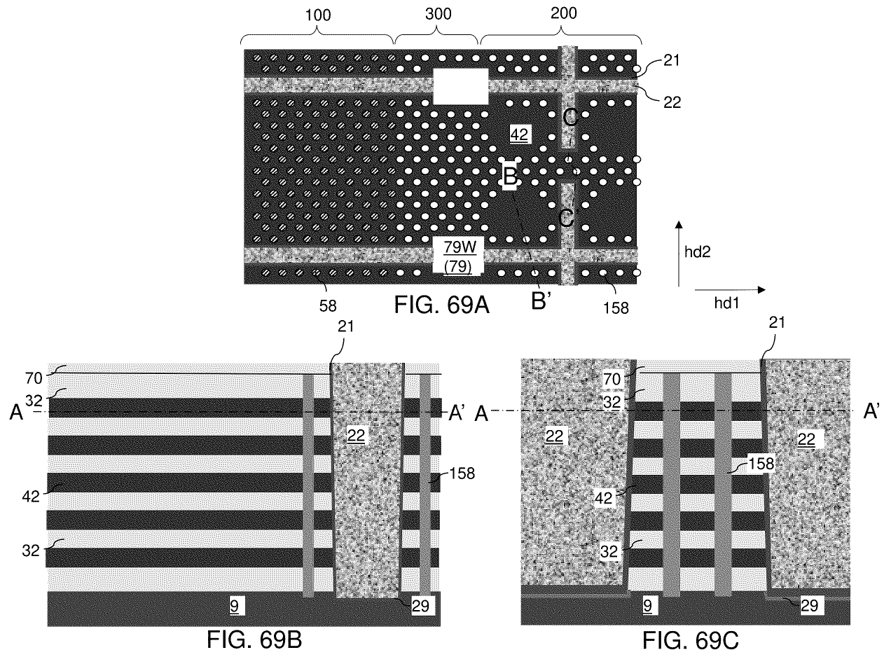

Referring to FIG. 69A-69C, the sacrificial barrier liner 21L and the sacrificial fill material layer 22L may be planarized with the top surface of the insulating cap layer 70 by chemical mechanical polishing, and portions of the sacrificial barrier liner 21L and the sacrificial fill material layer 22L located within the volumes of the wide lateral isolation trenches 79W may be removed by performing the processing steps described with reference to FIGS. 7A and 7B. Each of the array-region lateral isolation trench segments 79A, longitudinal lateral isolation trench segments 79L, and the transverse lateral isolation trench segments 79T may be filled with a respective combination of a sacrificial barrier liner 21 and a sacrificial lateral isolation trench fill structure 22.

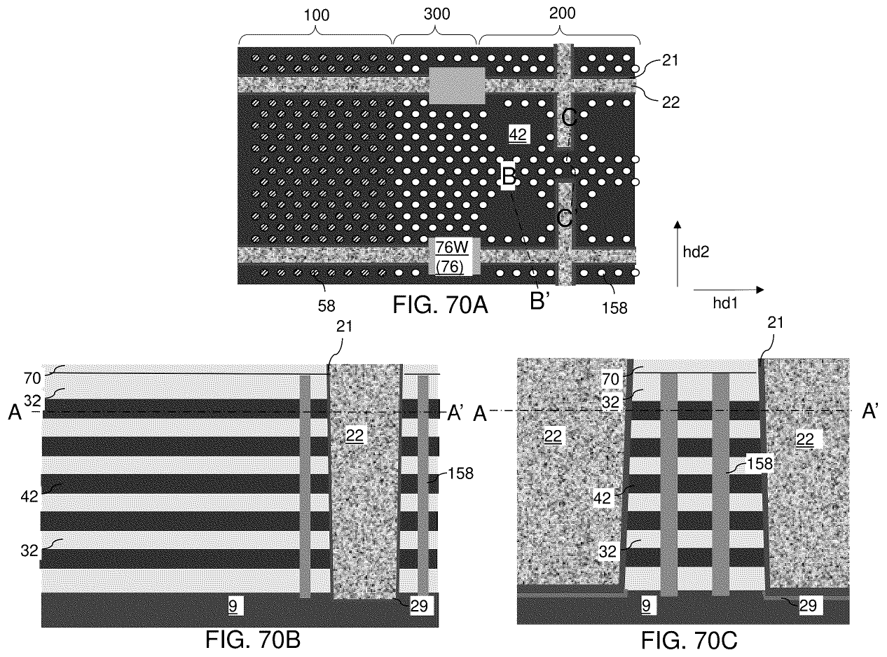

Referring to FIG. 70A-70C, the wide lateral isolation trench fill sections 79W may be filled with wide lateral isolation trench fill structures 76W by performing the processing steps described with reference to FIGS. 8A and 8B.

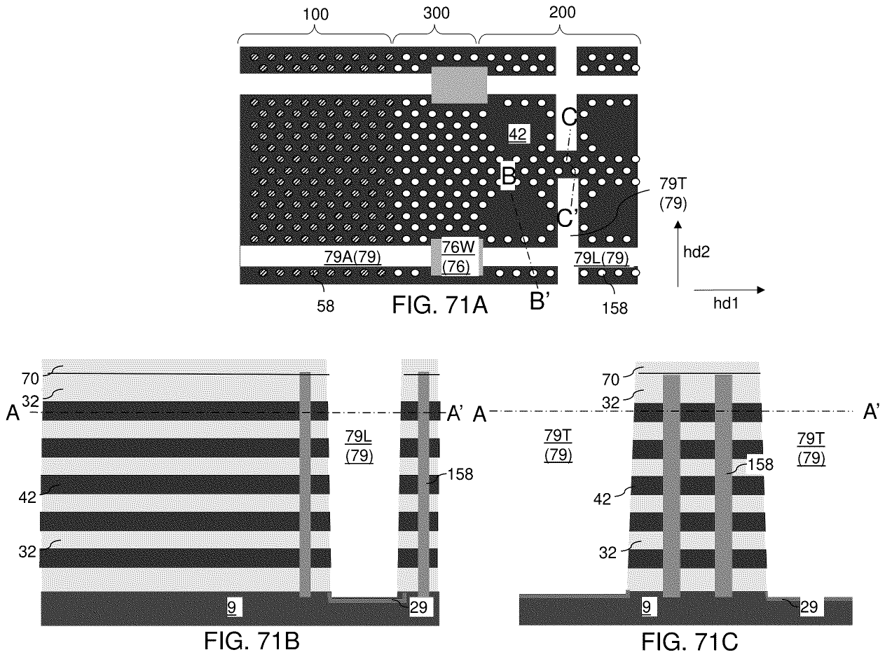

Referring to FIG. 71A-71C, the sacrificial lateral isolation trench fill structures 22 may be removed selectively to the materials of the sacrificial barrier liners 21 and the insulating cap layer 70. For example, if the sacrificial lateral isolation trench fill structures 22 comprise a semiconductor material, such as amorphous silicon or polysilicon, a wet etch process employing hot TMY or trimethylaluminum hydroxide may be performed to remove the sacrificial lateral isolation trench fill structures 22.

Subsequently, the sacrificial barrier liners 21 may be removed by performing an isotropic etch process. For example, if the sacrificial barrier liners 21 comprise silicon nitride, a wet etch process employing hot phosphoric acid may be performed to remove the sacrificial barrier liners 21.

An oxidation process may be performed to convert physically exposed surface portions of the semiconductor material layer 9 in the substrate into semiconductor oxide liners 29 at the bottom of the lateral isolation trenches 79.

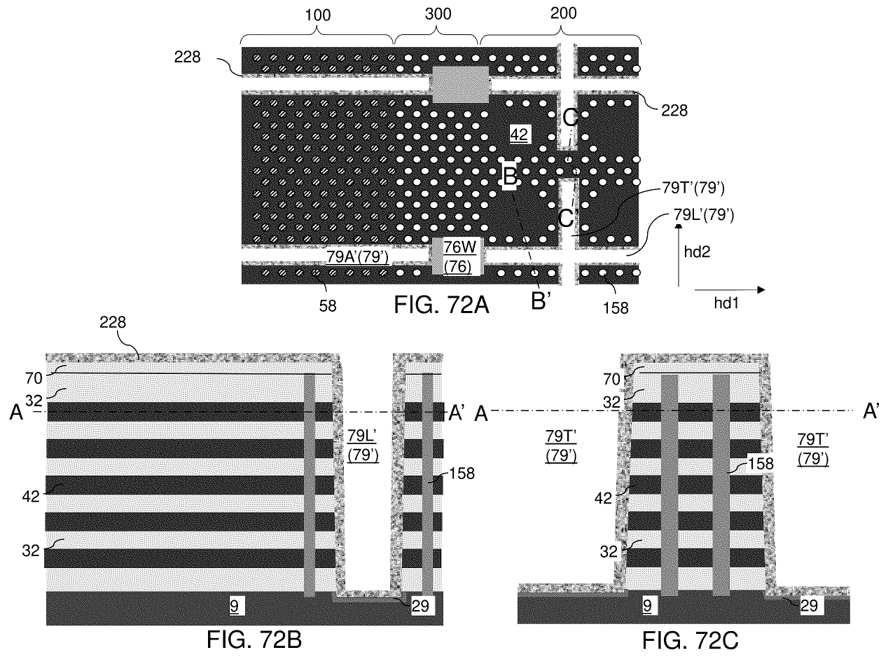

Referring to FIG. 72A-72C, the above described sacrificial etch barrier layer 228 can be conformally deposited in the array-region lateral isolation trenches 79A, the longitudinal lateral isolation trenches 79L and the transverse lateral isolation trenches 79T. The sacrificial etch barrier layer 228 comprises a sacrificial etch barrier material, such as amorphous silicon or polysilicon. The thickness of the sacrificial etch barrier layer 228 may be in a range from 30 nm to 200 nm, although lesser or greater thicknesses may also be employed. Unfilled volumes of the array-region lateral isolation trenches 79A comprise array-region lateral isolation cavities 79A′. Unfilled volumes of the longitudinal lateral isolation trenches 79L comprise longitudinal lateral isolation cavities 79L′. Unfilled volumes of the transverse lateral isolation trenches 79T comprise transverse lateral isolation cavities 79T′.

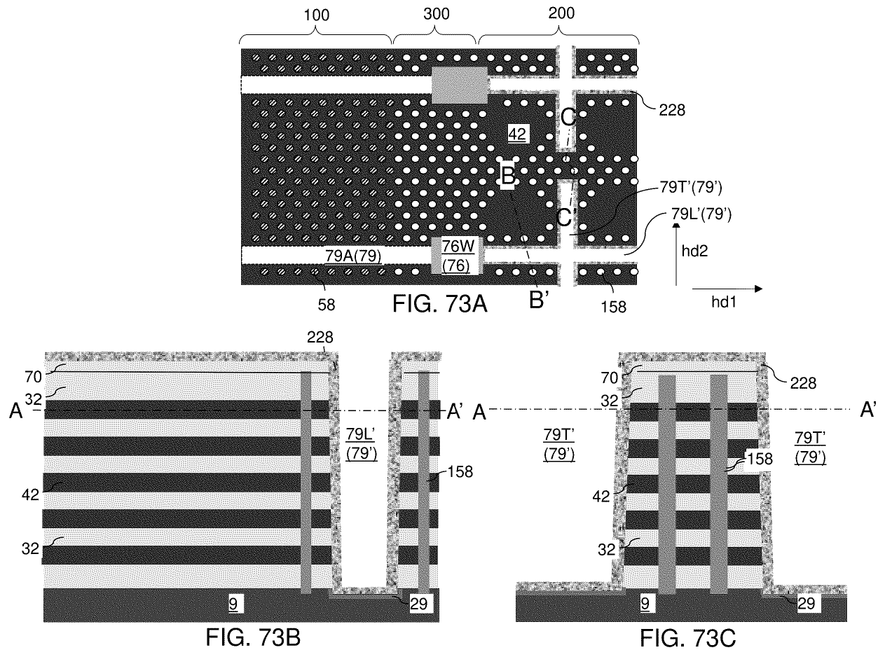

Referring to FIG. 73A-73C, portions of the sacrificial etch barrier layer 228 may be removed from inside the array-region lateral isolation trench segments 79A. For example, a photoresist layer (not shown) can be applied over the fourth exemplary structure, and may be lithographically patterned to cover the longitudinal lateral isolation trenches 79L and the transverse lateral isolation trenches 79T, and a selective etch process may be performed to remove portions of the sacrificial etch barrier layer 228 in the array-region lateral isolation trenches 79A that are not covered by the patterned photoresist layer selectively to the materials of the alternating stacks (32, 42), the insulating cap layer 70, and the semiconductor oxide liners 29.

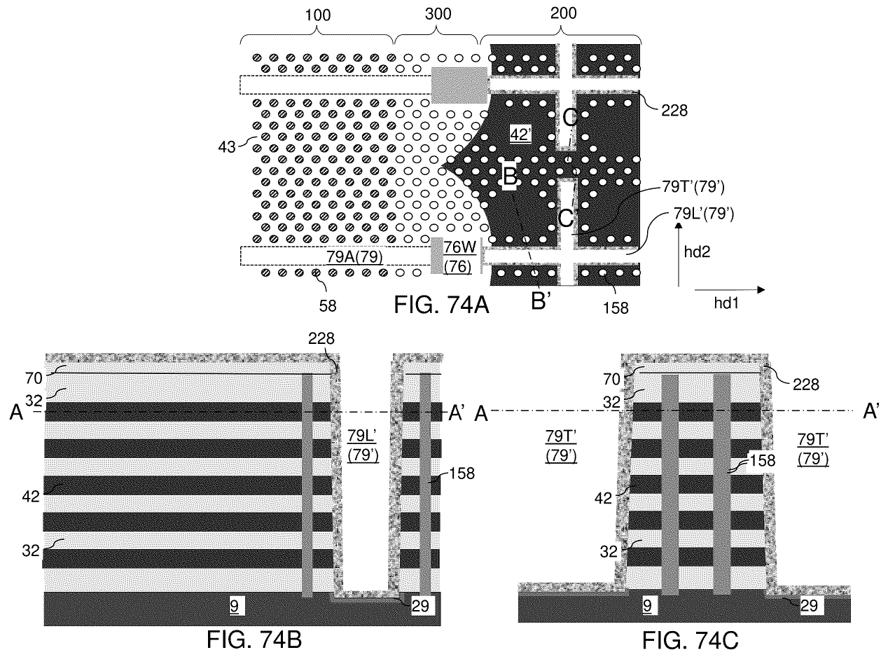

Referring to FIG. 74A-74C, the processing steps described with reference to FIG. 17A-17D may be performed to form the laterally-extending cavities 43. Specifically, a first selective isotropic etch process can be performed to remove first portions of the sacrificial material layers 42 that are proximal to the array-region lateral isolation trenches 79A. The array-region lateral isolation trenches 79A may be employed as conduits for introducing an isotropic etchant that selectively etches physically exposed portions of the sacrificial material layers 42 selectively to the materials of the insulating layers 32, the wide lateral isolation trench fill structures 76W, and the sacrificial etch barrier layers 228. Remaining portions of the sacrificial material layers 42 constitute dielectric plates 42′. Each of the dielectric plates 42′ may comprise a respective pair of laterally concave and vertically straight sidewalls that are adjoined to each other, as described above with respect to FIG. 59A.

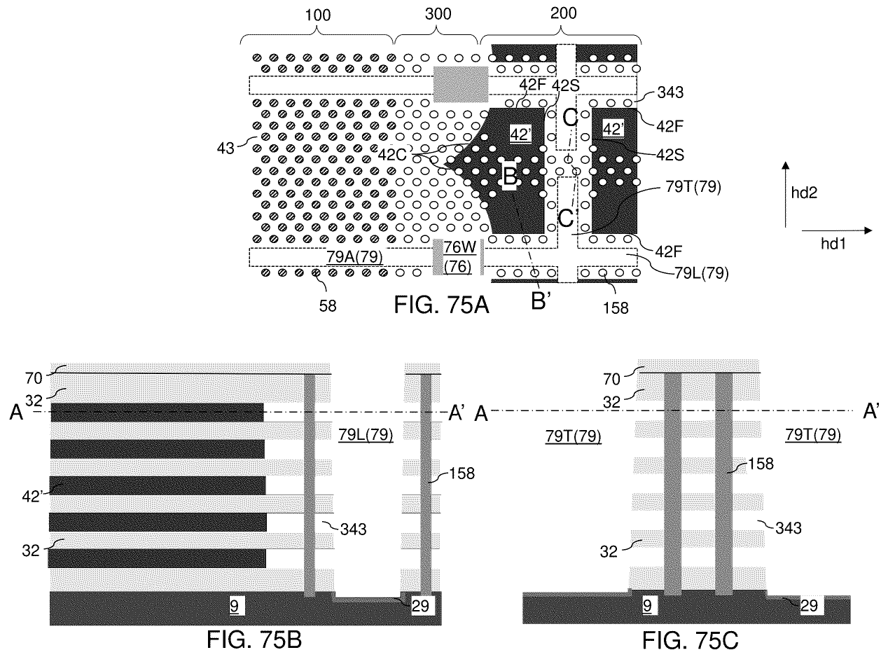

Referring to FIG. 75A-75C, an isotropic etch process can be performed to remove the remaining sacrificial etch barrier layers 228. For example, if the sacrificial etch barrier layers 228 comprise amorphous silicon or polysilicon, a wet etch process employing hot TMY or tetramethylammonium hydroxide may be performed.

Subsequently, a second selective isotropic etch process can be performed to remove second portions of the sacrificial material layers 42 that are proximal to the voids within the volumes of the longitudinal lateral isolation trench segments 79L and the transverse lateral isolation trench segments 79T, or proximal to the voids of the laterally-extending cavities 43. The second portions of the sacrificial material layers 42 are laterally recessed selectively to the materials of the insulating layers 32 and the wide lateral isolation trench fill structures 76W. Strip-shaped cavities 343 are formed in the volumes from which portions of the sacrificial material layers 42 are removed that were proximal to the longitudinal lateral isolation trench segments 79L or the transverse lateral isolation trench segments 79T. The laterally-extending cavities 43 may be laterally extended by a lateral extension distance that equals the uniform width of the strip-shaped cavities 343. Each strip-shaped cavity 343 is adjoined to a respective one of the laterally-extending cavities 43. The dielectric plates 42′ may be isotropically laterally recessed. A first subset of the dielectric plates 42′ may comprise a respective pair of laterally concave and vertically straight sidewalls that are adjoined to each other, and a respective pair of lengthwise sidewalls that are parallel to the first horizontal direction hd1, as described above with respect to FIG. 59A.

In summary, laterally-extending cavities 43 and strip-shaped cavities 343 may be formed by removing portions of the sacrificial material layers 42 that are proximal to at least one lateral isolation trench 79. The at least one lateral isolation trench 79 may comprise a plurality of array-region lateral isolation trenches 79A, a plurality of longitudinal lateral isolation trenches 79L, and a plurality of transverse lateral isolation trenches 79T. Multiple vertical stack of dielectric plates 42′ can be formed at the levels of the laterally-extending cavities 43. The multiple vertical stack of dielectric plates 42′ may comprise a two-dimensional array of vertical stacks of dielectric plates 42′. A plurality of vertical stacks of dielectric plates 42′ may be formed between a neighboring pair of longitudinal lateral isolation trenches 79L.

The strip-shaped cavities 343 may be formed by laterally recessing the sacrificial material layers 42 around the lateral isolation trenches 79 in the contact region 200. According to an aspect of the fourth embodiment, portions of the sacrificial material layers 42 located between neighboring pairs of the transverse lateral isolation trench segments 79T are removed during formation of the strip-shaped cavities 343. In one embodiment, neighboring pairs of the transverse lateral isolation trench segments 79T are interconnected to each other through a respective subset of strip-shaped cavities 343.

As described above, remaining portions of the sacrificial material layers 42 after formation of the strip-shaped cavities 343 and the laterally-extending cavities 43 constitute vertical stacks of dielectric plates 42′. Generally, the lateral spacing between each neighboring pair of transverse lateral isolation trenches 79T along the second horizontal direction hd2 is less than twice the etch distance of the second selective isotropic etch process for the material of the sacrificial material layers 42. Thus, each dielectric plate 42′ as formed at the processing steps of FIG. 74A-74C is divided into a respective plurality of dielectric plates 42′ that are laterally spaced apart along the first horizontal direction hd1, as shown in FIG. 75A.

In one embodiment, each of the dielectric plates 42′ comprises a respective pair of first sidewalls 42F that are parallel to the first horizontal direction hd1 and a second sidewall 42S that is parallel to the second horizontal direction hd2. In one embodiment, a first subset of the dielectric plates 42′ is physically exposed to a respective one of the laterally-extending cavities 43. In one embodiment, each dielectric plate 42′ within the first subset of the dielectric plates 42′ comprises a respective pair of laterally concave and vertically straight sidewalls 42C that are adjoined to each other. A second subset of the dielectric plates 42′ is laterally spaced from the laterally-extending cavities 43 at least by the first subset of the dielectric plates 42′. In one embodiment, each dielectric plate 42′ within the second subset of the dielectric plates 42′ comprises an additional second sidewall 42S that is parallel to the second horizontal direction hd2.

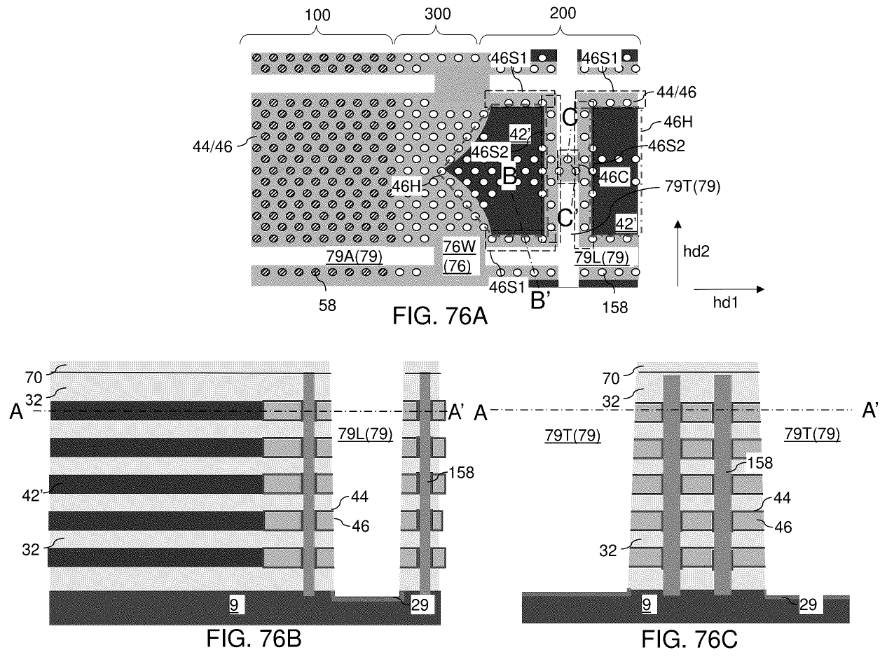

Referring to FIG. 76A-76C, the processing steps described with reference to FIG. 20A-20E and 21A-21E may be performed to form a combination of a backside blocking dielectric 44 and an electrically conductive layers 46 within each contiguous combination of a respective laterally-extending cavity 43 and a respective subset of the strip-shaped cavities 343. A vertically alternating sequence (32, 46) of the insulating layers 32 and the electrically conductive layers 46 is formed between each neighboring pair of lateral isolation trenches 79. Each of the lateral isolation trenches 79 may contain a respective wide lateral isolation trench fill structure 76W.

The electrically conductive layers 46 are formed in the laterally-extending cavities 43 and the strip-shaped cavities 343 at the same time. Each of the electrically conductive layers 46 is formed in a respective one of the laterally-extending cavities 43 and strip portions of the electrically conductive layers are formed in each of the strip-shaped cavities 343 that is located at a same level as the respective one of the laterally-extending cavities 43. In one embodiment, each of the electrically conductive layers 46 comprises first electrically conductive strips 46S1 that laterally extend along a first horizontal direction hd1, second electrically conductive strips 46S2 that laterally extend along a second horizontal direction and adjoined to a respective pair of the first electrically conductive strips 46S1, and at least one connection strip 46C laterally extending along the first horizontal direction hd1 and connecting a respective pair of the second electrically conductive strips 46S2.

In one embodiment, the first electrically conductive strips 46S1 and the second electrically conductive strips 46S2 have a uniform width throughout. The uniform width may be in a range from 50 nm to 600 nm, such as from 100 nm to 300 nm, although lesser or greater uniform widths may also be employed. In one embodiment, the at least one connection strip 46C has a width along the second horizontal direction hd2 that is perpendicular to the first horizontal direction hd1 which is greater than the uniform width. The width of each connection strip 46C may be in a range from 1.1 to 2 times of the uniform width.

Multiple vertical stacks of dielectric plates 42′ are embedded within the alternating stacks (32, 46). Each hole in an electrically conductive layer 46 in which a dielectric plate 42′ is located is herein referred to as a through-conductive-layer hole 46H. Each dielectric plate 42′ of the multiple vertical stacks of dielectric plates 42′ is located within a respective through-conductive-layer hole 46H. As described above, each of the dielectric plates 42′ comprises a respective pair of first sidewalls 42F that are parallel to the first horizontal direction hd1 and a second sidewall 42S that is parallel to the second horizontal direction hd2. In one embodiment, each dielectric plate 42′ within a first subset of the dielectric plates 42′ comprises a respective pair of laterally concave and vertically straight sidewalls 42C that are adjoined to each other. In one embodiment, each dielectric plate 42′ within a second subset of the dielectric plates 42′ comprises an additional second sidewall 42S that is parallel to the second horizontal direction hd2.

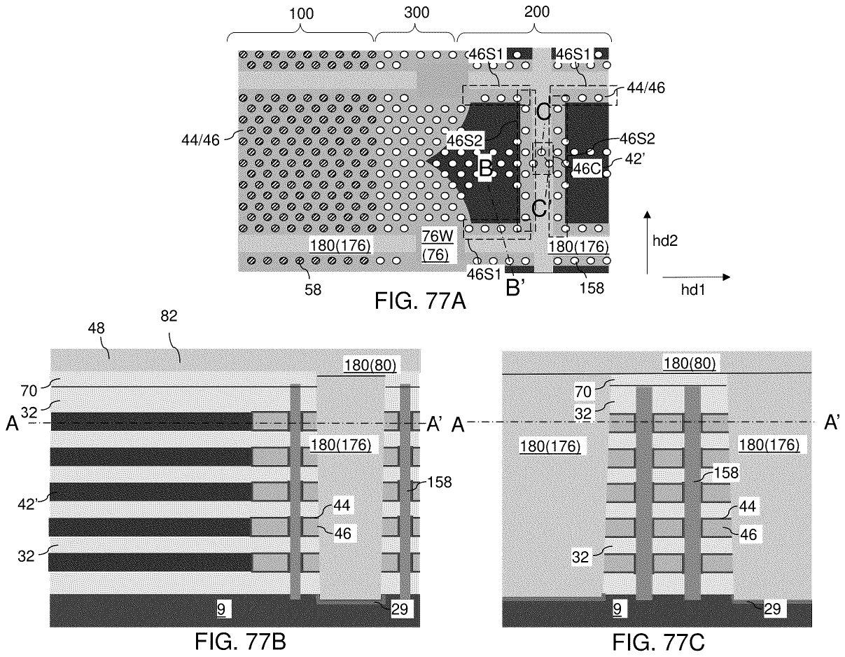

Referring to FIG. 77A-77C, a dielectric fill material, such as silicon oxide, can be deposited in the remaining volumes of the lateral isolation trenches 79 and over the insulating cap layer 70 to form a continuous dielectric material portion 180. The continuous dielectric material portion 180 may comprise a contact-level dielectric layer 80 overlying the vertically alternating sequence (32, 46), and lateral isolation trench fill material portions 176 located in a respective lateral isolation trench 79.

In one embodiment, each lateral isolation trench 79 may be filled with a respective lateral isolation trench fill material portion 176. Each lateral isolation trench fill material portion 176 may have a lengthwise sidewall that laterally extends along a first horizontal direction hd1 and contacts first sidewalls of the insulating layers 32 and first sidewalls of the electrically conductive layers 46 of a respective vertically alternating sequence (32, 46).

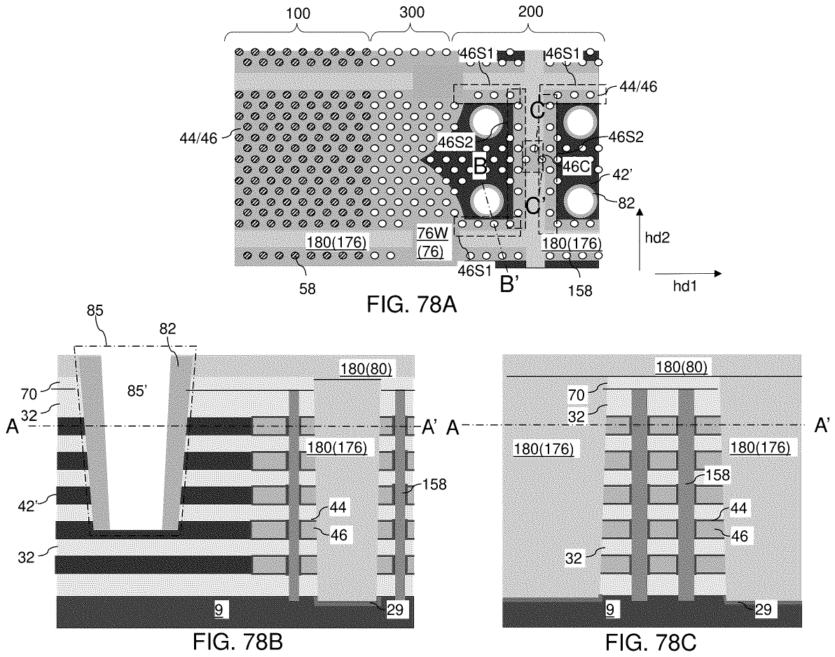

Referring to FIG. 78A-78C, the contact via openings 85 are formed within the contact region 200 by performing the processing steps described with reference to FIG. 9A 9C. Each contact via opening 85 may be formed through the contact-level dielectric layer 80 and the insulating cap layer 70, and respective underlying material portions. The bottom surface of each contact via opening 85 may be a surface of an underlying insulating layer 32, or may be a surface of an underlying sacrificial material plate 42′. In one embodiment, a predominant fraction of the contact via opening 85 may be formed through a respective subset of the dielectric plates 42′ and through a respective subset of the insulating layers 32.

Subsequently, the processing steps described with reference to FIGS. 10A and 10B may be performed to form the tubular insulating spacer 82 in the peripheral portion of each contact via opening 85. Contact via cavities 85′ laterally surrounded by the tubular insulating spacers 82 are present within the volumes of the contact via openings 85.

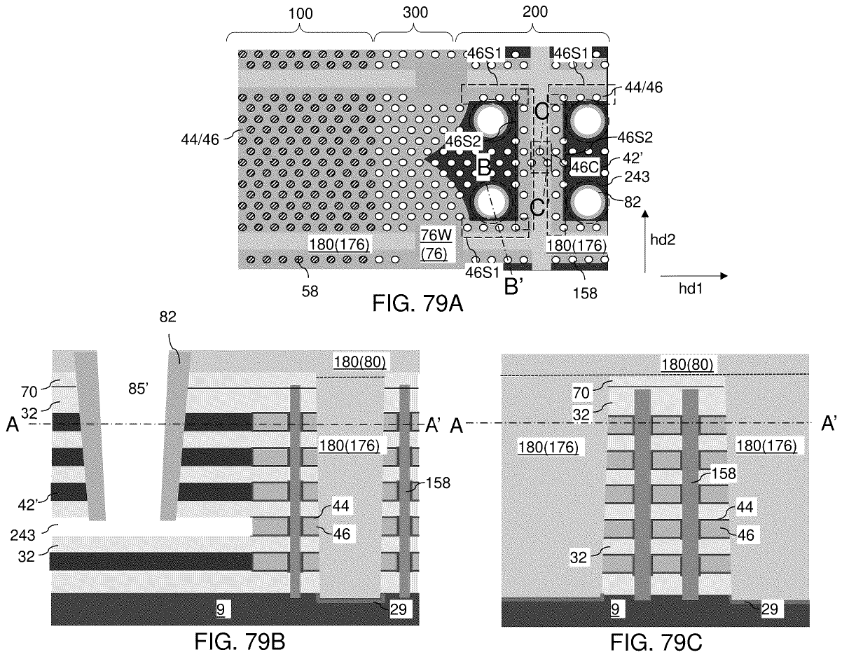

Referring to FIG. 79A-79C, a selective isotropic etch process can be performed to isotropically etch the first sacrificial material of the sacrificial material plates 42′ selectively to the materials of the insulating layers 32, the tubular insulating spacers 82, the insulating cap layer 70, the contact-level dielectric layer 80, and the electrically conductive layers 46. For example, if the sacrificial material plates 42′ comprise silicon nitride, the selective isotropic etch process may comprise a wet etch process employing hot phosphoric acid. A plate-shaped cavity 243 having a uniform thickness (which equals the thickness of the dielectric plates 42') may be formed underneath each contact via cavity 85′. The duration of the selective isotropic etch process is selected such that a sidewall of a backside blocking dielectric layer 44 is exposed after the selective isotropic etch process. Subsequently, an additional selective isotropic etch process can be performed to remove physically exposed portions of the backside blocking dielectric layers 44. A sidewall of the respective first electrically conductive layer 46 can be physically exposed around each plate-shaped cavity 243. The lateral extents of the plate-shaped cavities 243 are illustrated in dotted lines in FIG. 79A.

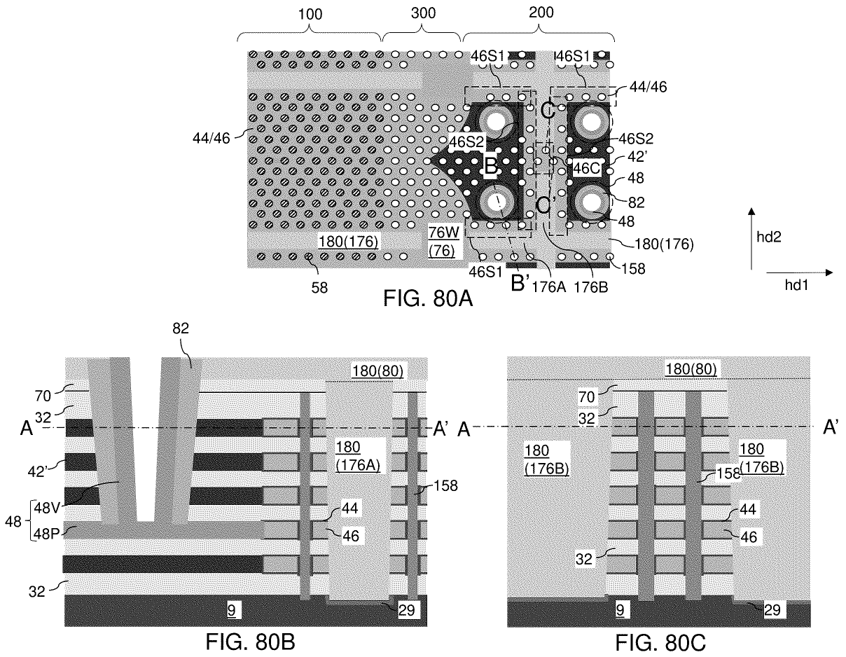

Referring to FIG. 80A-80C, at least one electrically conductive material can be conformally deposited to form a conformal electrically conductive material layer. In one embodiment, the conformal electrically conductive material layer comprises a metallic barrier liner and a metal layer. The metallic barrier liner may comprise metallic barrier material such as TiN, TaN, WN, or MoN, and may have a thickness in a range from 3 nm to 30 nm, although lesser or greater thicknesses may also be employed. The metal layer comprises a metal such as W, Co, Mo, Ru, etc. The thickness of the metal layer may be in a range from 50 nm to 300 nm, although lesser or greater thicknesses may also be employed.

The conformal electrically conductive material layer can be patterned, for example, by applying and patterning a photoresist layer over the conformal electrically conductive material layer, and by transferring the pattern in the patterned photoresist layer into the conformal electrically conductive material layer by performing an etch process. Patterned portions of the conformal electrically conductive material layer constitute the integrated plate-and-via structures 48.

Each integrated plate-and-via structure 48 comprises an electrically conductive plate 48P and the vertically-extending portion 48V extending upward from the electrically conductive plate 48P. Each electrically conductive plate 48P is in contact with a sidewall of a respective first electrically conductive layer 46 of the electrically conductive layers 46 at an interface.

In one embodiment, each of the integrated plate-and-via structures 48 is formed through a respective subset of the dielectric plates 42′. Each integrated plate-and-via structures 48 is located in a contact region 200, and comprises the respective electrically conductive plate 48P and a respective vertically-extending portion 48V extending upward from the respective electrically conductive plate. Each of the electrically conductive plates 48P is in contact with a respective one of the electrically conductive layers 46. In one embodiment, each of the electrically conductive layers 46 comprises a respective set of at least two through-conductive-layer holes 46H in the contact region in a plan view along a vertical direction in the contact region 200.

In one embodiment, each of the integrated plate-and-via structure 48 is laterally surrounded by a respective tubular insulating spacer 82. In one embodiment, each through-conductive-layer hole 46H in a topmost electrically conductive layer 46 laterally surrounds a respective subset of (e.g., a plurality of) the integrated plate-and-via structures 48. In one embodiment, each dielectric plate 42′ laterally surrounded by the topmost electrically conductive layer 46 comprises a respective plurality of openings laterally surrounding a respective plurality of the integrated plate-and-via structures 48.

Referring to FIG. 81, cavities inside the integrated plate-and-via structures 48 may be filled with a dielectric material to form the dielectric cores 183. In the fourth embodiment, the semiconductor structure comprises a vertically alternating sequence (32, 46) of insulating layers 32 and electrically conductive layers 46; first memory openings 49 located in a first memory array region (e.g., first memory plane) 110A and vertically extending through the vertically alternating sequence (32, 46); first memory opening fill structures 58 located in the first memory openings 49, wherein each of the first memory opening fill structures 58 comprises a respective vertical stack of memory elements (e.g., portions of the memory film 50) and a vertical semiconductor channel 60; and integrated plate-and-via structures 48 located in a contact region 200 and comprising a respective electrically conductive plate 48P and a respective vertically-extending portion 48V extending upward from the respective electrically conductive plate, wherein each of the electrically conductive plates 48P is in contact with a respective one of the electrically conductive layers 46. Each of the electrically conductive layers 46 comprises a respective set of at least two through-conductive-layer holes 46H in the contact region in a plan view along a vertical direction in the contact region 200. The semiconductor structure of the fourth embodiment also includes second memory openings 49 located in a second memory array region (e.g., second memory plane) 100B that is laterally spaced from the first memory array region 100A by the contact region 200. The second memory openings 49 vertically extend through the vertically alternating sequence (32, 46); and second memory opening fill structures 58 located in the second memory openings 49. Each of the second memory opening fill structures 58 comprises a respective vertical stack of memory elements and a vertical semiconductor channel 60.

An electrically conductive path ECP extends from each of the integrated plate-and-via structures (e.g., word line contact via structures) 48 to the respective first electrically conductive layer 46 in the first and second memory array regions (100A, 100B) through the electrically conductive strips 46S1, 46S2 and 46C. The plural electrically conductive strips 46S1, 46S2 and 46C reduce the resistance of the electrically conductive path ECP and improve device performance by forming an electrically conductive shunt 46S2 and 46C extending in the bit line direction hd2 between parallel electrically conductive strips 46S1 extending the word line direction hd1 between the memory planes (100A, 100B). Thus, the current can flow from the word line contact via structure 48 to the word lines 46 in adjacent memory planes (100A, 100B) along plural parallel portions of the electrically conductive path ECP.

Referring to FIG. 67A-81 and according to the fourth embodiment of the present disclosure, a memory device is provided comprises: a vertically alternating sequence (32, 46) of insulating layers 32 and electrically conductive layers 46; first memory openings 49 located in a first memory array region 100A and vertically extending through the vertically alternating sequence (32, 46); first memory opening fill structures 58 located in the first memory openings 49, wherein each of the first memory opening fill structures 58 comprises a respective vertical stack of memory elements (comprising portions of a respective memory film 50) located at levels of the electrically conductive layers 46 and a vertical semiconductor channel 60; and integrated plate-and-via structures 48 located in a contact region 200 and comprising a respective electrically conductive plate 48P and a respective vertically-extending portion 48V extending upward from the respective electrically conductive plate 48P. Each of the electrically conductive plates 48P is in contact with a respective one of the electrically conductive layers 46. Each of the electrically conductive layers 46 comprises first electrically conductive strips 46S1 that laterally extend along a first horizontal direction hd1, second electrically conductive strips 46S2 that laterally extend along a second horizontal direction and adjoined to a respective pair of first electrically conductive strips 46S1 among the first electrically conductive strips 46S1, and at least one connection strip 46C each laterally extending along the first horizontal direction hd1 and connecting a respective pair of second electrically conductive strips 46S2 among the second electrically conductive strips 46S2.

In one embodiment, the first electrically conductive strips 46S1 and the second electrically conductive strips 46S2 have a uniform width. In one embodiment, the at least one connection strip 46C has a width along a horizontal direction that is perpendicular to the first horizontal direction hd1 which is greater than the uniform width.

In one embodiment, each of the electrically conductive layers 46 comprises a respective set of at least two through-conductive-layer holes 46H in the contact region in a plan view along a vertical direction in the contact region 200. Each through-conductive-layer hole 46H in a topmost electrically conductive layer 46 of the electrically conductive layers 46 laterally surrounds a respective subset of the integrated plate-and-via structures 48. In one embodiment, the respective subset of the integrated plate-and-via structures 48 comprises a respective plurality of integrated plate-and-via structures 48 of the integrated plate-and-via structures 48.

In one embodiment, the memory device also comprises multiple vertical stacks of dielectric plates 42′, wherein each dielectric plate 42′ of the multiple vertical stacks of dielectric plates 42′ is located within a respective through-conductive-layer hole 46H. In one embodiment, each dielectric plate 42′ laterally surrounded by a topmost electrically conductive layer 46 of the electrically conductive layers 46 comprises a respective plurality of openings laterally surrounding a respective plurality of the integrated plate-and-via structures 48. In one embodiment, each of the dielectric plates 42′ comprises a respective pair of first sidewalls 42F that are parallel to the first horizontal direction hd1 and a second sidewall 42S that is parallel to the second horizontal direction hd2. In one embodiment, each dielectric plate 42′ within a first subset of the dielectric plates 42′ comprises a respective pair of laterally concave and vertically straight sidewalls 42C that are adjoined to each other. In one embodiment, each dielectric plate 42′ within a second subset of the dielectric plates 42′ comprises an additional second sidewall 42S that is parallel to the second horizontal direction hd2.

In one embodiment, the memory device also comprises lateral isolation trench fill material portions 176 contacting a respective set of sidewall segments of the vertically alternating sequence (32, 46), wherein two first lateral isolation trench fill material portions 176 of the lateral isolation trench fill material portions 176 comprises a respective first portion 176A laterally extending along the first horizontal direction hd1 and a respective second portion 176B laterally extending along the second horizontal direction hd2. In one embodiment, the respective first portion 176A contacts sidewalls of a respective subset of the first electrically conductive strips 46S1 of the electrically conductive layers 46; and the respective second portion 176B contacts sidewalls of a respective subset of the second electrically conductive strips 46S2 and the connection strips 46C of the electrically conductive layers 46.

In one embodiment, each of the integrated plate-and-via structure 48 is laterally surrounded by a respective tubular insulating spacer 82. In one embodiment, the memory device also comprises a continuous dielectric material portion 180 that comprises: a contact-level dielectric layer 80 overlying the vertically alternating sequence (32, 46); and lateral isolation trench fill material portions 176 contacting a respective subset of sidewall segments of the vertically alternating sequence (32, 46).

In one embodiment, the memory device also comprises: second memory openings 49 located in a second memory array region 100B that is laterally spaced from the first memory array region 100A by the contact region 200, wherein the second memory openings 49 vertically extend through the vertically alternating sequence (32, 46); and second memory opening fill structures 58 located in the second memory openings 49, wherein each of the second memory opening fill structures 58 comprises a respective vertical stack of memory elements located at the levels of the electrically conductive layers 46 and a vertical semiconductor channel 60.

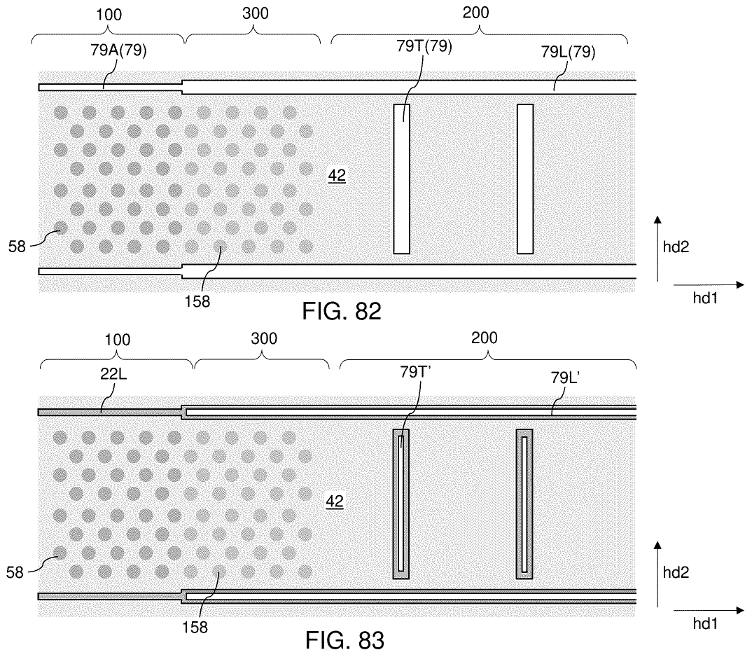

Referring to FIG. 82, a fifth exemplary structure according to the fifth embodiment of the present disclosure may be derived from the fourth exemplary structure illustrated in FIGS. 44A and 44B by modifying the pattern of the transverse lateral isolation trench segments 79T that laterally extend along the second horizontal direction hd2. Specifically, the transverse lateral isolation trench segments 79T are not connected to the longitudinal lateral isolation trench segments 79L, but are laterally spaced from a nearest neighboring pair of longitudinal lateral isolation trench segments 79L by a lateral spacing. The lateral spacing is not greater than twice the lateral recess distance of a second selective isotropic etch process that is subsequently performed to form strip-shaped cavities.

The fifth exemplary structure illustrated in FIG. 82 may be provided by forming an alternating stack of insulating layers 32 and sacrificial material layers 42 over a substrate; forming memory openings 49 through the alternating stack in at least one memory array region 100 (which may be two memory regions 100 laterally spaced apart from each other along the first horizontal direction hd1 by a combination of two connection regions 300 and a contact region 200); and forming memory opening fill structures 58 in the memory openings 49. In one embodiment, the sacrificial material layers 42 comprise a first sacrificial material which is a dielectric material (such as silicon nitride). Each of the memory opening fill structures 58 comprises a respective vertical stack of memory elements (comprising portions of a respective memory film 50) and a vertical semiconductor channel 60.

The at least one lateral isolation trench 79 employed in the fifth exemplary structure may comprise a plurality of lateral isolation trenches 79. In one embodiment, the lateral isolation trenches 79 may comprise array-region lateral isolation trench segments 79A that are formed in a respective memory array region 100 adjacent to the memory opening fill structures 58; longitudinal lateral isolation trenches 79L each laterally extending along the first horizontal direction hd1 and laterally spaced apart from each other along the second horizontal direction hd2; and transverse lateral isolation trench segments 79T that are formed in the contact region 200 and laterally extending along the second horizontal direction hd2 and each located between, and not connected to, a respective neighboring pair of longitudinal lateral isolation trench segments 79L. The transverse lateral isolation trench segments 79T are laterally spaced apart from each other along the first horizontal direction hd1. In one embodiment, the second horizontal direction hd2 may be perpendicular to the first horizontal direction hd1.

In one embodiment, a continuous lateral isolation trench 79 may comprise a combination of at least one array-region lateral isolation trench segment 79A, and a longitudinal lateral isolation trench segment 79L. In one embodiment, the at least one transverse lateral isolation trench segment 79T may comprise a two-dimensional array of transverse lateral isolation trench segments 79T that are repeated along the first horizontal direction hd1 and along the second horizontal direction hd2. The array-region lateral isolation trench segments 79A may have widths that are comparable to the width of the narrow lateral isolation trench segments 79N described above, and the longitudinal lateral isolation trench segments 79L and the transverse lateral isolation trench segments 79T may have a width that are comparable to the width of the wide lateral isolation trench segments 79W described above. Thus, the array-region lateral isolation trench segments 79A may be narrower than the longitudinal lateral isolation trench segments 79L and the transverse lateral isolation trench segments 79T.

Referring to FIG. 83, an optional sacrificial barrier liner (not illustrated) and a sacrificial fill material layer 22L may be formed by performing the processing steps described with reference to FIGS. 6A and 6B. A respective cavity 79L′ and 79T′ may be present in each longitudinal lateral isolation trench 79L and in each transverse lateral isolation trench 79T.

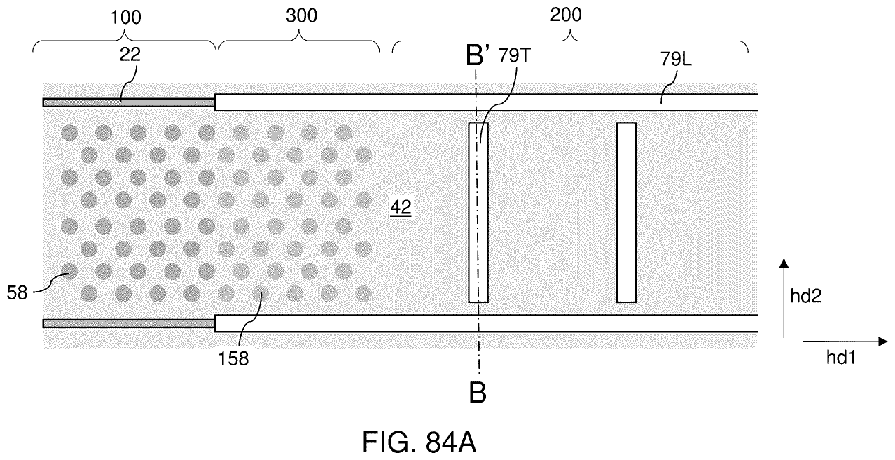

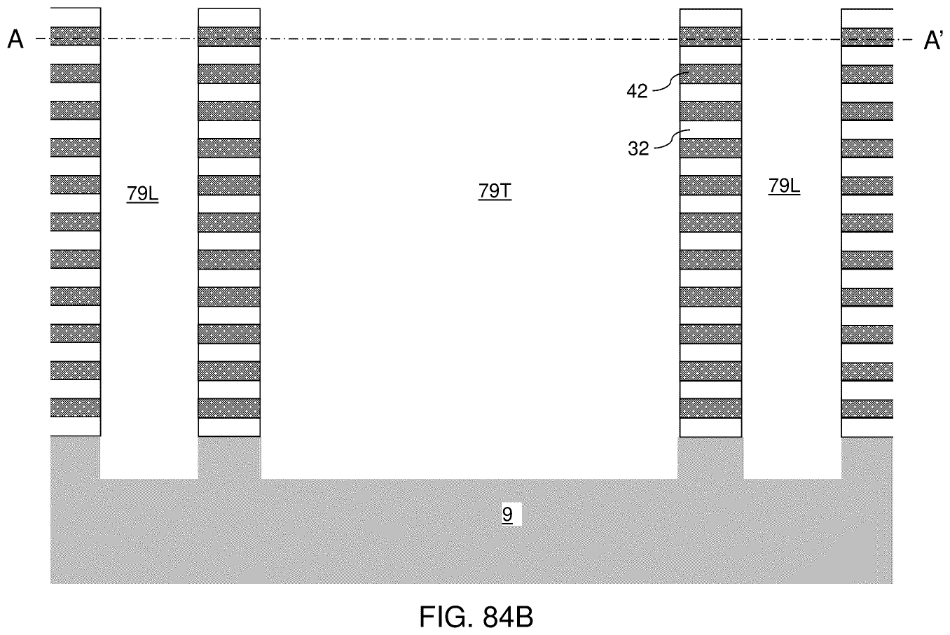

Referring to FIGS. 84A and 84B, portions of the sacrificial barrier liner (if present) and the sacrificial fill material layer 22L located within the volumes of the longitudinal lateral isolation trench segment 79L and the transverse lateral isolation trench segments 79T may be removed by performing the processing steps described with reference to FIGS. 7A and 7B. The array-region lateral isolation trench segments 79A may be filled with a respective combination of the optional sacrificial barrier liner (not illustrated) and the sacrificial lateral isolation trench fill structure 22.

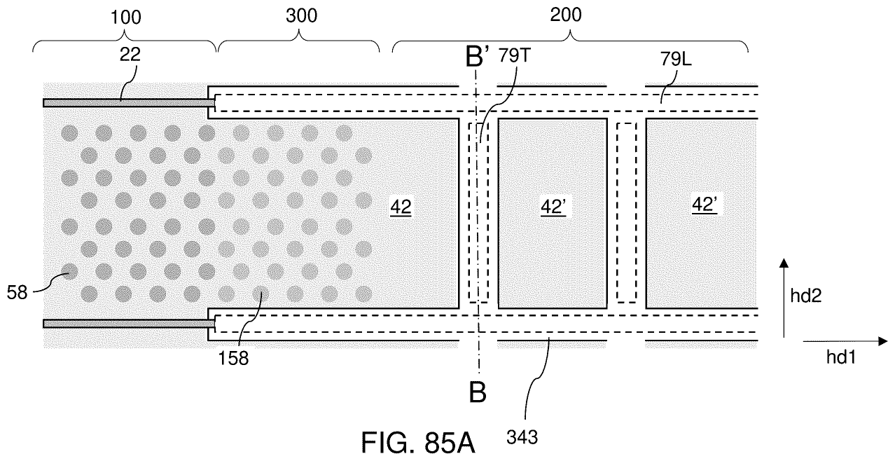

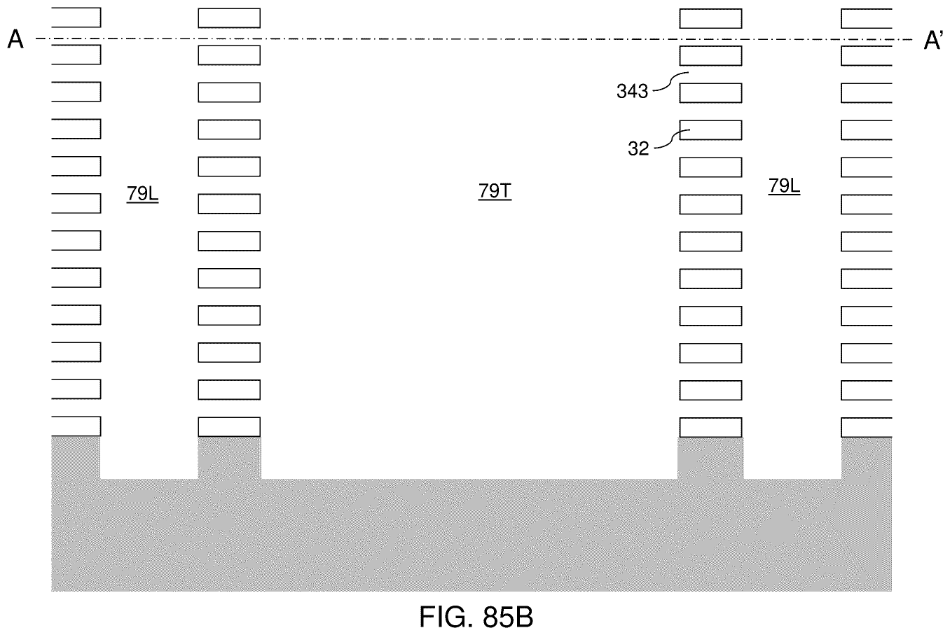

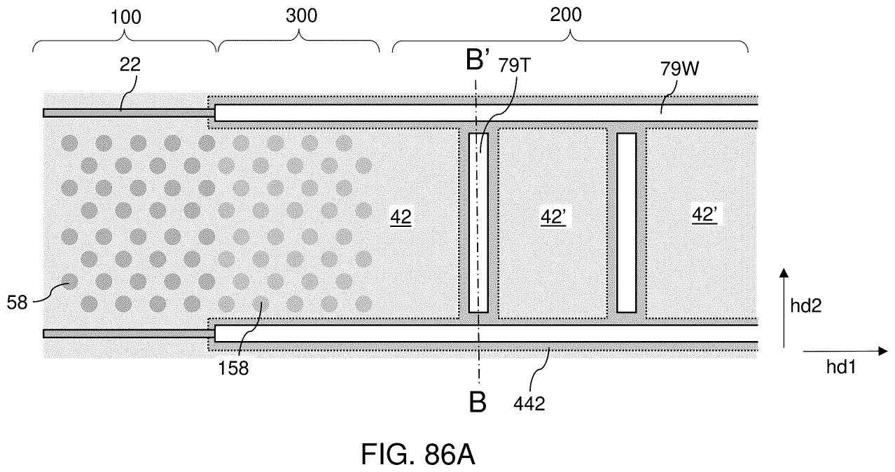

Referring to FIGS. 85A and 85B, a selective isotropic etch process can be performed to remove portions of the sacrificial material layers 42 that are proximal to the volumes of the longitudinal lateral isolation trench segments 79L or the transverse lateral isolation trench segments 79T. The sacrificial material layers 42 are laterally recessed selectively to the materials of the insulating layers 32 and the sacrificial lateral isolation trench fill structures 22. Strip-shaped cavities 343 are formed in the volumes from which portions of the sacrificial material layers 42 that are proximal to the longitudinal lateral isolation trench segments 79L or the transverse lateral isolation trench segments 79T are removed. Each strip-shaped cavity 343 is adjoined to at least one neighboring strip-shaped cavity 343 that laterally extends along a different horizontal direction. Remaining portions of the sacrificial material layers 42 that are laterally surrounded by a respective set of two longitudinal lateral isolation trench segments 79L and two transverse lateral isolation trench segments 79T comprise dielectric plates 42′. Multiple vertical stacks of dielectric plates 42′ may be formed.

In summary, strip-shaped cavities 343 may be formed by laterally recessing the sacrificial material layers 42 around the lateral isolation trench segments in the contact region 200. In one embodiment, neighboring pairs of a respective longitudinal lateral isolation trench segment 79L and a respective transverse lateral isolation trench segment 79T are laterally spaced apart from each other, but are interconnected to each other by a respective subset of the strip-shaped cavities 343.

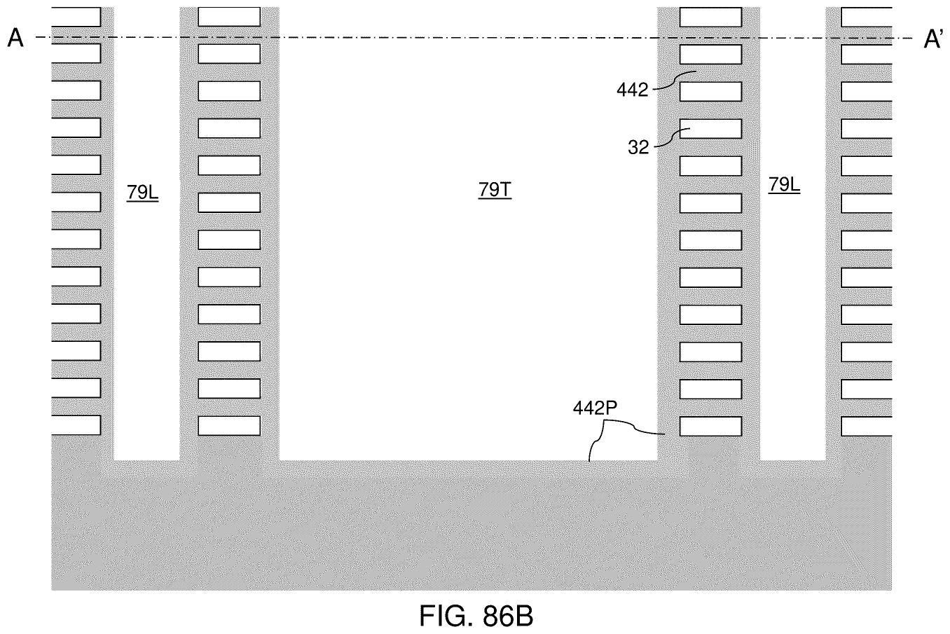

Referring to FIGS. 86A and 86B, a sacrificial edge fill material that is different from the materials of the insulating layers 32 and the sacrificial material layers 42 can be conformally deposited in the strip-shaped cavities 343. The sacrificial edge fill material may also be different from the material of the sacrificial lateral isolation trench fill structures 22. For example, the sacrificial edge fill material may comprise organosilicate glass, a polymer material, a carbon-based material (such as amorphous silicon or polysilicon), or a semiconductor material that is different from the material of the material of the sacrificial lateral isolation trench fill structures 22. An optional etch back process can be performed to remove portions of the sacrificial edge fill material that are collaterally deposited in the volumes of the longitudinal lateral isolation trench segments 79L and the transverse lateral isolation trench segments 79T. Remaining portions of the sacrificial edge fill material that fill the volumes of the strip-shaped cavities 343 comprise sacrificial edge fill structures 442. In one embodiment, physically exposed sidewalls of the sacrificial edge fill structures 442 may be vertically coincident with sidewalls of the insulating layers 32 that are exposed to the longitudinal lateral isolation trench segments 79L or the transverse lateral isolation trench segments 79T. Alternatively, the optional etch back process is omitted, and portions 442P of the sacrificial edge fill material remain on sidewalls and bottom surfaces of the longitudinal lateral isolation trench segments 79L and the transverse lateral isolation trench segments 79T, as shown in FIG. 86B.

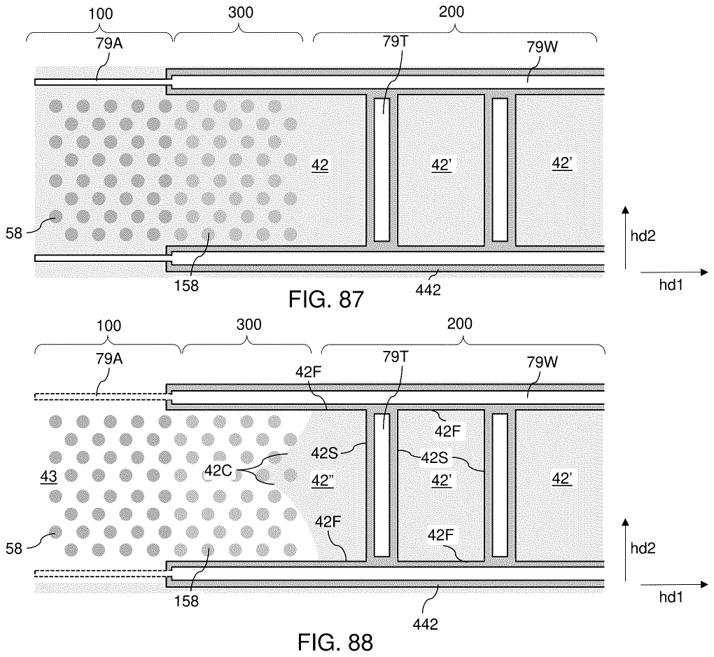

Referring to FIG. 87, any remaining portions of the sacrificial barrier liner (not shown) and the sacrificial lateral isolation trench fill structures 22 may be removed selectively to the material of the sacrificial edge fill structures 442 by performing a selective etch process. In one embodiment, if the sacrificial lateral isolation trench fill structures 22 comprise a semiconductor material, such as amorphous silicon or polysilicon, a wet etch process employing hot TMY or tetramethylammonium hydroxide may be employed to remove the sacrificial lateral isolation trench fill structures 22. Any remaining portion of the sacrificial barrier liner may be removed by performing a suitable isotropic etch process (such as a selective wet etch process) that does not etch the material of the sacrificial edge fill structures 442.

Referring to FIG. 88, the processing steps described with reference to FIG. 17A 17D may be performed to form laterally-extending cavities 43. Specifically, a selective isotropic etch process can be performed to remove portions of the sacrificial material layers 42 that are proximal to the array-region lateral isolation trench segments 79A. The array-region lateral isolation trench segments 79A may be employed as conduits for introducing an isotropic etchant that selectively etches physically exposed portions of the sacrificial material layers 42 selectively to the materials of the insulating layers 32 and the sacrificial edge fill structures 442. Remaining portions of the sacrificial material layers 42 constitute additional dielectric plates 42″. Each of the additional dielectric plates 42″ may comprise a respective pair of laterally concave and vertically straight sidewalls 42C that are adjoined to each other.

In one embodiment, each of the dielectric plates 42′ and 42″ comprises a respective pair of first sidewalls 42F that are parallel to the first horizontal direction hd1 and a second sidewall 42S that is parallel to the second horizontal direction hd2. In one embodiment, each dielectric plate 42″ within a first subset of the dielectric plates 42″ comprises a respective pair of laterally concave and vertically straight sidewalls 42C that are adjoined to each other. In one embodiment, each dielectric plate 42′ within a second subset of the dielectric plates 42′ comprises an additional second sidewall 42S that is parallel to the second horizontal direction hd2.

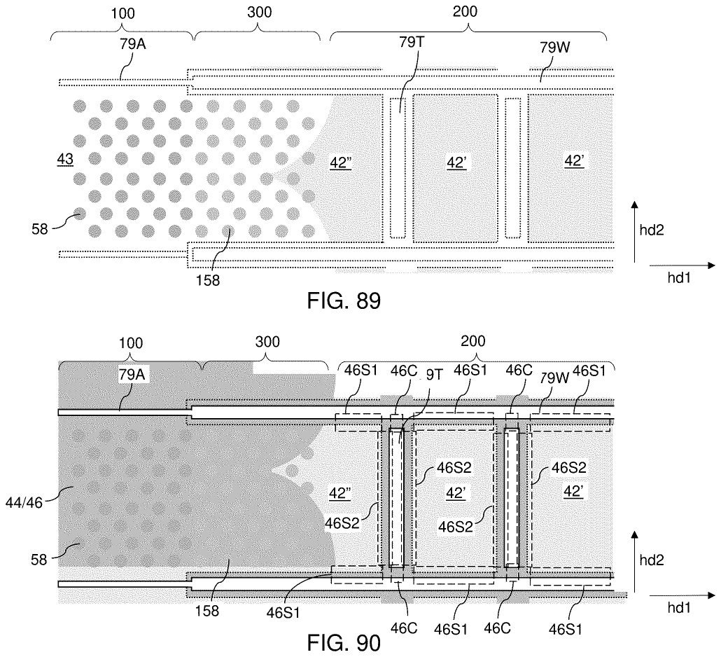

Referring to FIG. 89, the sacrificial edge fill structures 442 (and portions 442P, if present) can be removed selectively to the dielectric plates 42′ and 42″, the memory opening fill structures 58, and the dummy memory opening fill structures 158 to form the laterally-extending cavities 43. Voids are formed in the volumes of the strip-shaped cavities 343. Generally, laterally-extending cavities 43 and strip-shaped cavities 343 may be formed by removing portions of the sacrificial material layers 42 that are proximal to at least one lateral isolation trench 79 (including segments 79T which are now connected to the trench 79 by the strip-shaped cavities 343). The at least one lateral isolation trench 79 may comprise a plurality of array-region lateral isolation trench segments 79A, a plurality of longitudinal lateral isolation trench segments 79L, and a plurality of transverse lateral isolation trench segments 79T. Multiple vertical stacks of dielectric plates 42′ and 42″ can be formed at the levels of the laterally-extending cavities 43.

Referring to FIG. 90, the processing steps described with reference to FIG. 20A 20E and 21A-21E may be performed to form a combination of a backside blocking dielectric 44 and an electrically conductive layers 46 within each contiguous combination of a respective laterally-extending cavity 43 and a respective subset of the strip-shaped cavities 343. A vertically alternating sequence (32, 46) of the insulating layers 32 and the electrically conductive layers 46 is formed between each neighboring pair of array-region lateral isolation trench segments 79A.

According to an aspect of the fifth embodiment, electrically conductive layers 46 are formed in the laterally-extending cavities 43 and the strip-shaped cavities 343 during the same deposition step. Each of the electrically conductive layers 46 is formed in a respective one of the laterally-extending cavities 43 and each of the strip-shaped cavities 343 that is located at a same level as the respective one of the laterally-extending cavities 43. In one embodiment, each of the electrically conductive layers 46 comprises first electrically conductive strips 46S1 that laterally extend along a first horizontal direction hd1, second electrically conductive strips 46S2 that laterally extend along a second horizontal direction hd2 and adjoined to a respective pair of the first electrically conductive strips 46S1, and a plurality of connection strips 46C each laterally extending along the first horizontal direction hd1 and connecting a respective pair of the second electrically conductive strips 46S2.

In one embodiment, the first electrically conductive strips 46S1 and the second electrically conductive strips 46S2 have a uniform width throughout. The uniform width may be in a range from 50 nm to 600 nm, such as from 100 nm to 300 nm, although lesser or greater uniform widths may also be employed. In one embodiment, the at least one connection strip 46C has a width along a horizontal direction that is perpendicular to the first horizontal direction hd1 which is greater than the uniform width. The width of each connection strip 46C may be in a range from 1.1 times the uniform width to 2 times the uniform width.

Multiple vertical stacks of dielectric plates 42′ and 42″ are embedded within the alternating stacks (32, 46). Each hole in an electrically conductive layer 46 in which a dielectric plate 42′ or 42″ is located is herein referred to as a through-conductive-layer hole 46H. Each dielectric plate is located within a respective through-conductive-layer hole 46H. In one embodiment, each of the dielectric plates 42′ and 42″ comprises a respective pair of first sidewalls 42F that are parallel to the first horizontal direction hd1 and a second sidewall 42S that is parallel to the second horizontal direction hd2. In one embodiment, each dielectric plate 42″ within a first subset of the dielectric plates 42″ comprises a respective pair of laterally concave and vertically straight sidewalls 42C that are adjoined to each other. In one embodiment, each dielectric plate 42′ within a second subset of the dielectric plates 42′ comprises an additional second sidewall 42S that is parallel to the second horizontal direction hd2.

In one embodiment, each of the electrically conductive layers 46 comprises a respective set of at least four first electrically conductive strips 46S1 laterally extending along a first horizontal direction hd1 and at least two second electrically conductive strips 46S2 laterally extending along a second horizontal direction hd2. In one embodiment, each of the electrically conductive layers 46 further comprise at least two connection strips 46C each laterally extending along the first horizontal direction hd1 and connecting a respective pair of the second electrically conductive strips 46S2.

For each vertically alternating sequence of insulating layers 32 and electrically conductive layers 46, at least one vertical stack of dielectric plates 42′ and/or 42″, such as a plurality of vertical stacks of dielectric plates 42′ and/or 42″, may be interlaced with the insulating layers 32. Each of the dielectric plates 42′ or 42″ is located at a level of a respective one of the electrically conductive layers 46. In one embodiment, first electrically conductive strips 46S1 and the second electrically conductive strips 46S2 have a uniform width throughout. In one embodiment, the at least two connection strips 46C have a width along a horizontal direction that is perpendicular to the first horizontal direction hd1 which is greater than the uniform width.

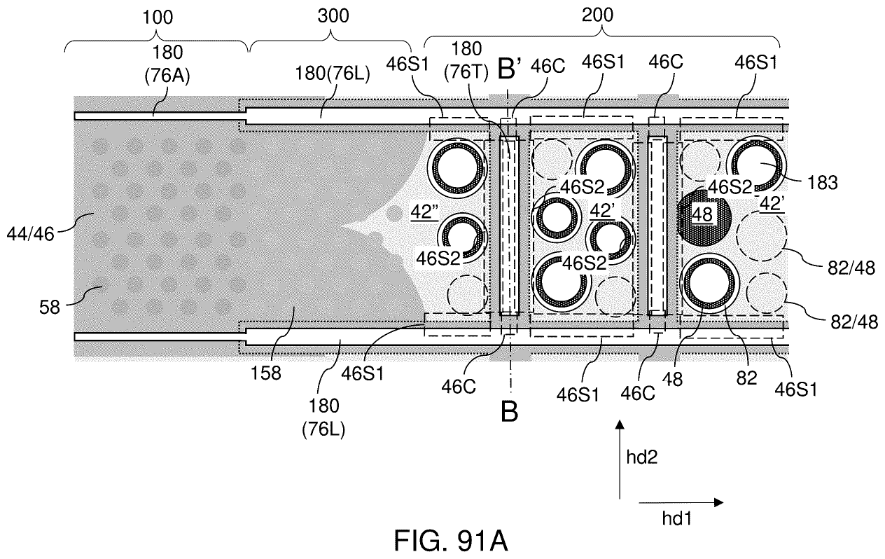

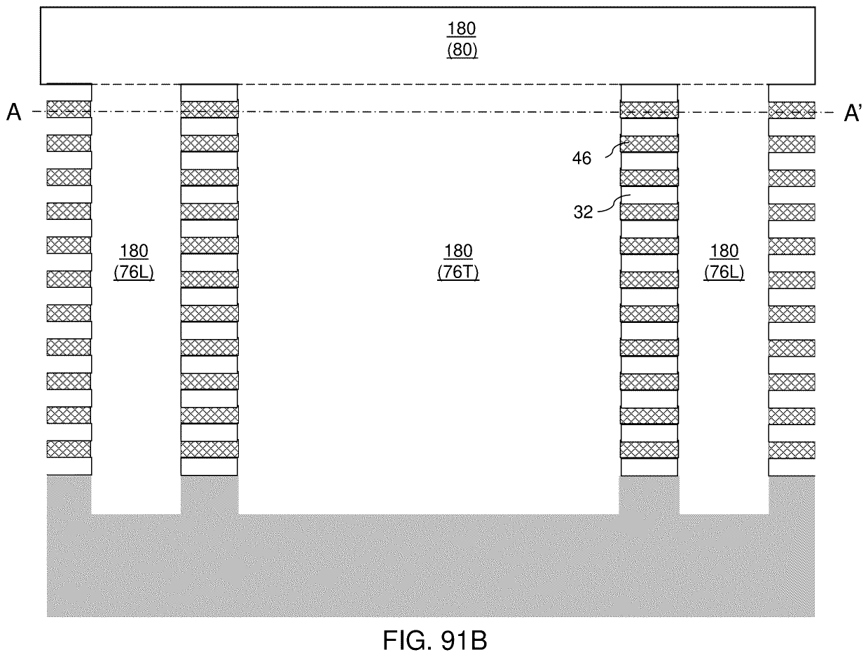

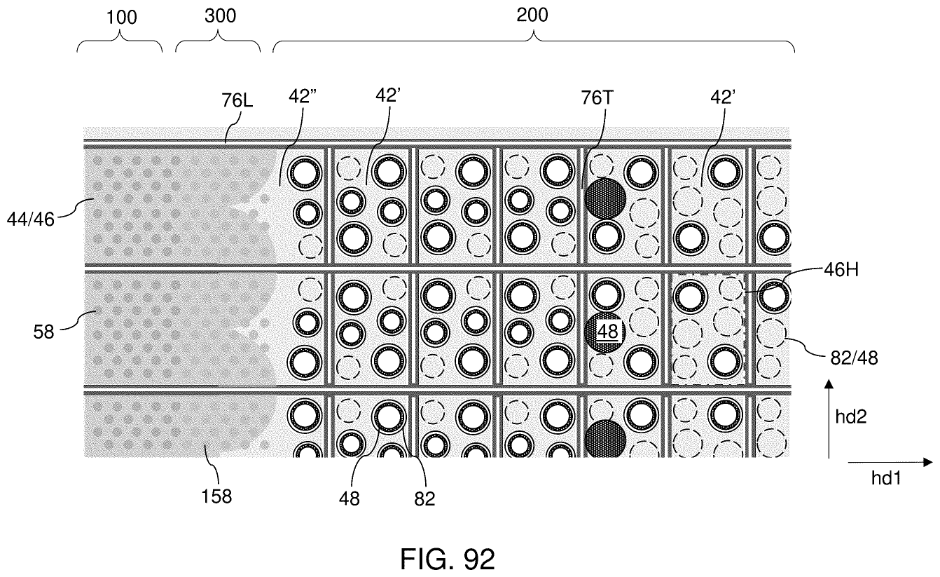

Referring to FIGS. 91A, 91B, and 92, the set of processing steps described with reference to FIG. 77A-77C, 78A-78C, 79A-79C, 80A-80C, and 81 is performed to form a continuous dielectric material portion 180. The continuous dielectric material portion 180 may comprise a contact-level dielectric layer 80 overlying the vertically alternating sequence (32, 46), and lateral isolation trench fill material portions (76A, 76L, 76T) located in a respective lateral isolation trench 79. The lateral isolation trench fill material portions (76A, 76L, 76T) may comprise array-region lateral isolation trench fill material portions 76A, longitudinal lateral isolation trench fill material portions 76L, and transverse lateral isolation trench fill material portions 76T.

Integrated plate-and-via structures 48 may be formed in the same manner as described with reference to the fourth exemplary structure. Each integrated plate-and-via structure 48 comprises an electrically conductive plate 48P and a vertically-extending portion 48V extending upward from the electrically conductive plate 48P. Each electrically conductive plate 48P is in contact with a sidewall of a respective first electrically conductive layer 46 of the electrically conductive layers 46 at an interface.

In one embodiment, each of the integrated plate-and-via structures 48 is formed through a respective subset of the dielectric plates 42′ or 42″. In one embodiment, each dielectric plate 42′ or 42″ laterally surrounded by a topmost electrically conductive layer 46 comprises a respective plurality of openings laterally surrounding a respective plurality of the integrated plate-and-via structures 48. In one embodiment, each of the electrically conductive layers 46 comprises a respective set of at least two through-conductive-layer holes in the contact region in a plan view along a vertical direction in the contact region 200. In one embodiment, each of the integrated plate-and-via structure 48 is laterally surrounded by a respective tubular insulating spacer 82. In one embodiment, each through-conductive-layer hole 46H in a topmost electrically conductive layer 46 of the electrically conductive layers 46 laterally surrounds a respective subset of the integrated plate-and-via structures 48. Cavities inside the integrated plate-and-via structures 48 may be filled with a dielectric material to form dielectric cores 183.

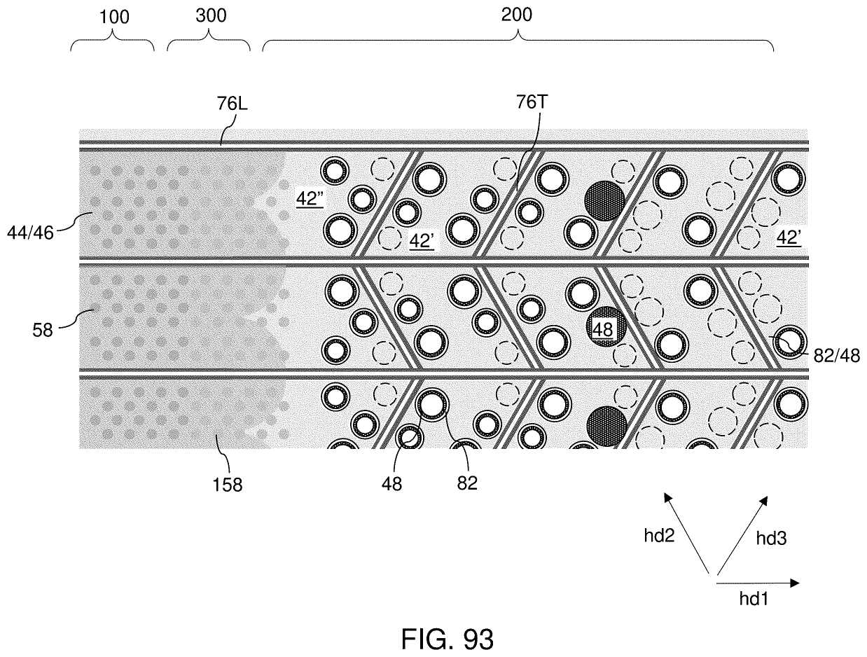

Referring to FIG. 93, a first alternative configuration of the fifth exemplary structure can be derived from the fifth exemplary structure by modifying the pattern of the transverse lateral isolation trenches 79T such that a first subset of the transverse lateral isolation trench segments 79T laterally extend along a second horizontal direction hd2 that is not perpendicular to the first horizontal direction hd1. In this case, the first subset of the transverse lateral isolation trenches 79T may have a horizontal cross-sectional shape of a parallelopiped. In one embodiment, all transverse lateral isolation trench segments 79T may be parallel to the second horizontal direction hd2. Alternatively, a second subset of the transverse lateral isolation trench segments 79T may laterally extend along a third horizontal direction hd3 that is not perpendicular to the first horizontal direction hd1 and is not parallel to the second horizontal direction hd2. In an illustrated example, the angle between the second horizontal direction hd2 and the first horizontal direction hd1 may be in a range from 20 degree to 60 degrees, such as from 25 degrees to 45 degrees. If the second subset of the transverse lateral isolation trench segments 79T laterally extend along the third horizontal direction hd3, the angle between the third horizontal direction hd3 and the first horizontal direction hd1 may be in a range from 20 degree to 60 degrees, such as from 25 degrees to 45 degrees.

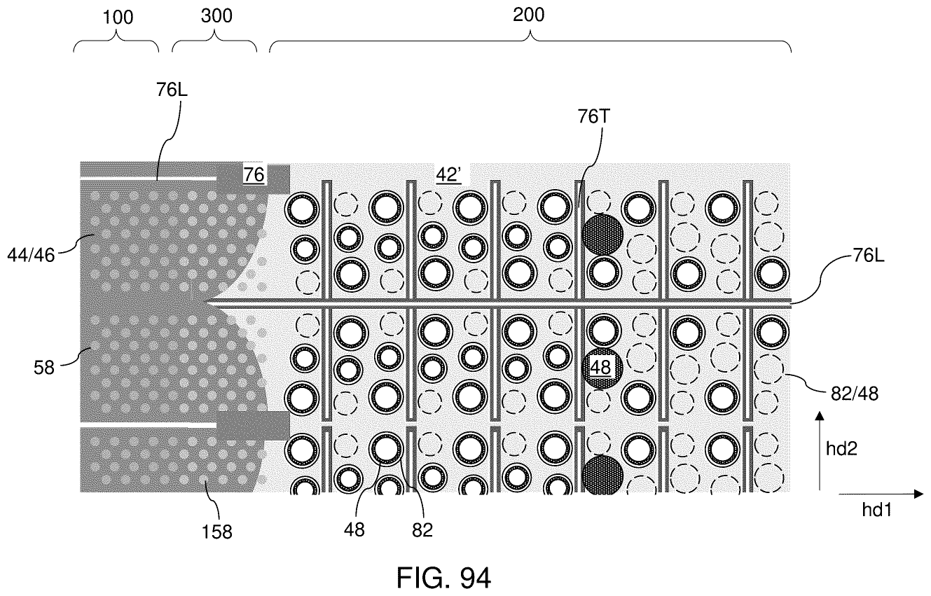

Referring to FIG. 94, a second alternative configuration of the fifth exemplary structure can be derived from the fifth exemplary structure by connecting each second electrically conductive strips 46S2 to a single first electrically conductive strip 46S1. In this case, each dielectric plate 42′ may laterally comprise a plurality of compartments each bounded by a respective pair of second electrically conductive stirps 46S2 and interconnected to each other by connecting portions of the dielectric plate 42′ located between neighboring pairs of transverse lateral isolation trench segments 79T that are laterally spaced apart among one another along the second horizontal direction hd2. In this configuration, the array-region lateral isolation trench segments 79A are laterally offset along the second horizontal direction hd2 from the plurality of longitudinal lateral isolation trench segments 79L. Thus, the isolation trench fill material portions 76L in the contact region 200 are laterally offset along the second horizontal direction hd2 from the isolation trench fill material portions 76L in the memory array region(s) 100. The wider lateral isolation trench fill material portion 76 may be located at the end of the isolation trench fill material portion 76L in the connection region 300.

In the fifth embodiment, at least a portion of the electrically conductive plates 48P is in contact with a respective one of the second electrically conductive strips 46S2 which extend non-parallel to first horizontal direction (e.g., word line direction hd1). This increases the density of the integrated plate-and-via structures 48 along the second horizontal direction hd2 and reduces the amount of empty space in the contact region 200, and may provide a reduction in the area of the contact region 200. This increases the device density and reduces the length of the connection strips between the memory array regions (e.g., memory planes) 100. Furthermore, the resistance of the electrically conductive path is reduced, similar to that described above with respect to the fourth embodiment.

Referring to the drawings of the present disclosure and according to the fifth embodiment of the present disclosure, a memory device comprises: a vertically alternating sequence (32, 46) of insulating layers 32 and electrically conductive layers 46, wherein each of the electrically conductive layers 46 extends in a first horizontal direction (e.g., word line direction) hd1 in a first memory array region 100, and comprises first electrically conductive strips 46S1 laterally extending along the first horizontal direction hd1 in a contact region 200, and second electrically conductive strips 46S2 laterally extending along a second horizontal direction hd2 different from the first horizontal direction hd1 in the contact region 200; first memory openings 49 located in a first memory array region and vertically extending through the vertically alternating sequence (32, 46); first memory opening fill structures 58 located in the first memory openings 49, wherein each of the first memory opening fill structures 58 comprises a respective vertical stack of memory elements (comprising portions of a respective memory film 50) located at levels of the electrically conductive layers 46 and a vertical semiconductor channel 60; and integrated plate-and-via structures 48 located in a contact region 200 and comprising a respective electrically conductive plate 48P and a respective vertically-extending portion 48V extending upward from the respective electrically conductive plate 48P, wherein at least a portion of the electrically conductive plates 48P is in contact with a respective one of the second electrically conductive strips 46S2.

In one embodiment, each of the electrically conductive layers 46 further comprises at least two connection strips 46C each laterally extending along the first horizontal direction hd1 in the contact region 200 and connecting a respective pair of the second electrically conductive strips 46S2. In one embodiment, each of the electrically conductive layers 46 comprises a respective set of at least four of the first electrically conductive strips 46S1 and at least two of the second electrically conductive strips 46S2.

In one embodiment, the first electrically conductive strips 46S1 and the second electrically conductive strips 46S2 have a uniform width throughout. In one embodiment, the at least two connection strips 46C have a width along a horizontal direction that is perpendicular to the first horizontal direction hd1 which is greater than the uniform width.

In one embodiment, the memory device also comprises at least one vertical stack of dielectric plates 42′ interlaced with the insulating layers 32, wherein each of the dielectric plates 42′ is located at a level of a respective one of the electrically conductive layers 46.

In one embodiment, the memory device also comprises a continuous dielectric material portion 180 that comprises: a contact-level dielectric layer 80 overlying the vertically alternating sequence (32, 46); and lateral isolation trench fill material portions (76A, 76L, 76T) contacting a respective subset of sidewall segments of the vertically alternating sequence (32, 46). In one embodiment, the lateral isolation trench fill material portions (76A, 76L, 76T) comprise longitudinal lateral isolation trench fill material portions 76L laterally extending along the first horizontal direction hd1 and contacting sidewall segments of a respective subset of the at least four first electrically conductive strips 46S1.

In one embodiment, the lateral isolation trench fill material portions (76A, 76L, 76T) also comprise transverse lateral isolation trench fill material portions 76T laterally extending along the second horizontal direction hd2 and contacting sidewall segments of a respective subset of the at least two second electrically conductive strips 46S2. In one embodiment, each of the at least two connection strips 46C is in contact with a respective one of the longitudinal lateral isolation trench fill material portions 76L and with a respective one of the transverse lateral isolation trench fill material portions 76T.

In one embodiment, the memory device comprises also multiple vertical stacks of dielectric plates 42′, wherein each dielectric plate 42′ among the multiple vertical stacks of dielectric plates 42′ is located within a respective through-conductive-layer hole 46H through a respective one of the electrically conductive layers 46. In one embodiment, each dielectric plate 42′ laterally surrounded by a topmost electrically conductive layer 46 of the electrically conductive layers 46 comprises a respective plurality of openings laterally surrounding a respective plurality of the integrated plate-and-via structures 48.

In one embodiment, each of the dielectric plates 42′ comprises a respective pair of first sidewalls 42F that are parallel to the first horizontal direction hd1 and a second sidewall 42S that is parallel to the second horizontal direction hd2. In one embodiment, each dielectric plate 42″ within a first subset of the dielectric plates 42″ comprises a respective pair of laterally concave and vertically straight sidewalls 42C that are adjoined to each other. In one embodiment, each dielectric plate 42′ within a second subset of the dielectric plates 42′ comprises an additional second sidewall 42S that is parallel to the second horizontal direction hd2.

In one embodiment, the memory device also comprises additional electrically conductive layers 46 laterally spaced apart along the second horizontal direction hd2 from and electrically isolated from the electrically conductive layers 46. The additional electrically conductive layers 46 are vertically interlaced with the insulating layers 32, and the multiple vertical stacks of dielectric plates 42′ are laterally spaced apart from along the second horizontal direction hd2 by longitudinal lateral isolation trench fill material portions 76L laterally extending along the first horizontal direction hd1. In one embodiment, each of the integrated plate-and-via structures 48 is laterally surrounded by a respective tubular insulating spacer 82.

In some embodiments illustrated in FIGS. 92 and 94, the first horizontal direction hd1 is perpendicular to the second horizontal direction hd2. In another embodiment illustrated in FIG. 93, the first horizontal direction hd1 is diagonal relative to the second horizontal direction hd2.

Although the foregoing refers to particular preferred embodiments, it will be understood that the claims are not so limited. It will occur to those of ordinary skill in the art that various modifications may be made to the disclosed embodiments and that such modifications are intended to be within the scope of the claims. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the claims may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A memory device, comprising:
a vertically alternating sequence of insulating layers and electrically conductive layers, wherein each of the electrically conductive layers extends in a first horizontal direction in a first memory array region, and comprises first electrically conductive strips laterally extending along the first horizontal direction in a contact region, and second electrically conductive strips laterally extending along a second horizontal direction different from the first horizontal direction in the contact region;
first memory openings located in the first memory array region and vertically extending through the vertically alternating sequence;
first memory opening fill structures located in the first memory openings, wherein each of the first memory opening fill structures comprises a respective vertical stack of memory elements located at levels of the electrically conductive layers and a vertical semiconductor channel; and
integrated plate-and-via structures located in the contact region and comprising a respective electrically conductive plate and a respective vertically-extending portion extending upward from the respective electrically conductive plate, wherein at least a portion of the electrically conductive plates is in contact with a respective one of the second electrically conductive strips.

2. The memory device of claim 1, wherein each of the electrically conductive layers further comprises at least two connection strips each laterally extending along the first horizontal direction in the contact region and connecting a respective pair of the second electrically conductive strips.

3. The memory device of claim 2, wherein each of the electrically conductive layers comprises a respective set of at least four of the first electrically conductive strips and at least two of the second electrically conductive strips.

4. The memory device of claim 3, wherein:
the first electrically conductive strips and the second electrically conductive strips have a uniform width throughout; and
the at least two connection strips have a width along a horizontal direction that is perpendicular to the first horizontal direction which is greater than the uniform width.

5. The memory device of claim 1, further comprising at least one vertical stack of dielectric plates interlaced with the insulating layers, wherein each of the dielectric plates is located at a level of a respective one of the electrically conductive layers.

6. The memory device of claim 3, further comprising a continuous dielectric material portion that comprises:
a contact-level dielectric layer overlying the vertically alternating sequence; and
lateral isolation trench fill structures contacting a respective subset of sidewall segments of the vertically alternating sequence.

7. The memory device of claim 6, wherein the lateral isolation trench fill structures comprise longitudinal lateral isolation trench fill structures laterally extending along the first horizontal direction and contacting sidewall segments of a respective subset of the at least four first electrically conductive strips.

8. The memory device of claim 7, wherein the lateral isolation trench fill structures comprise transverse lateral isolation trench fill structures laterally extending along the second horizontal direction and contacting sidewall segments of a respective subset of the at least two second electrically conductive strips.

9. The memory device of claim 8, wherein each of the at least two connection strips is in contact with a respective one of the longitudinal lateral isolation trench fill structures and with a respective one of the transverse lateral isolation trench fill structures.

10. The memory device of claim 1, further comprising multiple vertical stacks of dielectric plates, wherein each dielectric plate of the multiple vertical stacks of dielectric plates is located within a respective through-conductive-layer hole through a respective one of the electrically conductive layers.

11. The memory device of claim 10, wherein each dielectric plate laterally surrounded by a topmost electrically conductive layer of the electrically conductive layers comprises a respective plurality of openings laterally surrounding a respective plurality of the integrated plate-and-via structures.

12. The memory device of claim 10, wherein:
each of the dielectric plates comprises a respective pair of first sidewalls that are parallel to the first horizontal direction and a second sidewall that is parallel to the second horizontal direction;
each dielectric plate within a first subset of the dielectric plates comprises a respective pair of laterally concave and vertically straight sidewalls that are adjoined to each other; and
each dielectric plate within a second subset of the dielectric plates comprises an additional second sidewall that is parallel to the second horizontal direction.

13. The memory device of claim 10, further comprising additional electrically conductive layers laterally spaced apart along the second horizontal direction and electrically isolated from the electrically conductive layers, wherein the additional electrically conductive layers are vertically interlaced with the insulating layers, and the multiple vertical stacks of dielectric plates are laterally spaced apart from each other along the second horizontal direction by longitudinal lateral isolation trench fill structures laterally extending along the first horizontal direction.

14. The memory device of claim 1, wherein each of the integrated plate-and-via structures is laterally surrounded by a respective tubular insulating spacer.

15. The memory device of claim 1, wherein the first horizontal direction is perpendicular to the second horizontal direction.

16. The memory device of claim 1, wherein the first horizontal direction is diagonal relative to the second horizontal direction.

17. A method of forming a memory device, comprising:
forming an alternating stack of insulating layers and sacrificial material layers over a substrate;
forming memory openings through the alternating stack in a memory array region;
forming memory opening fill structures in the memory openings, wherein each of the memory opening fill structures comprises a respective vertical stack of memory elements and a vertical semiconductor channel;
forming longitudinal lateral isolation trench segments and transverse lateral isolation trench segments through the alternating stack, wherein the longitudinal lateral isolation trench segments laterally extend along a first horizontal direction and the transverse lateral isolation trench segments laterally extend along a second horizontal direction different from the first horizontal direction;
forming strip-shaped cavities by laterally recessing the sacrificial material layers around the lateral isolation trenches in the contact region, wherein neighboring pairs of a respective longitudinal lateral isolation trench segment and a respective transverse lateral isolation trench segment are interconnected by a respective subset of the strip-shaped cavities;
forming laterally-extending cavities by laterally recessing the sacrificial material layers around the longitudinal lateral isolation trench segments in the memory array region; and
forming electrically conductive layers in the laterally-extending cavities and the strip-shaped cavities.

18. The method of claim 17, further comprising forming integrated plate-and-via structures, wherein each of the integrated plate-and-via structures comprises a respective electrically conductive plate and a respective vertically-extending portion extending upward from the respective electrically conductive plate, wherein each of the electrically conductive plates contacts a respective one of the electrically conductive layers,.

19. The method of claim 17, wherein each of the electrically conductive layers is formed in a respective one of the laterally-extending cavities and each of the strip-shaped cavities that is located at a same level as the respective one of the laterally-extending cavities.

20. The method of claim 17, wherein:
remaining portions of the sacrificial material layers after formation of the strip-shaped cavities and the laterally-extending cavities constitute vertical stacks of dielectric plates; and
the method further comprises forming integrated plate-and-via structures comprising at least one electrically conductive material, wherein each of the integrated plate-and-via structures is formed through a respective subset of the dielectric plates.
